(19) United States
(12) Patent Application Publication
(10) Pub. No.: US 2025/0311291 A1
(43) Pub. Date: Oct. 2, 2025

(54) SEMICONDUCTOR DEVICE

(71) Applicant: ROHM CO., LTD., Kyoto-shi (JP)

(72) Inventors: Daisuke IIZASA, Kyoto-shi (JP); Seigo MORI, Kyoto-shi (JP); Yuki NAKANO, Kyoto-shi (JP)

(73) Assignee: ROHM CO., LTD., Kyoto-shi (JP)

(21) Appl. No.: 19/090,905

(22) Filed: Mar. 26, 2025

(30) Foreign Application Priority Data
Mar. 29, 2024 (JP) 2024-057694

(51) Int. Cl. H10D 30/66; H10D 62/10; H10D 62/40; H10D 62/60; H10D 62/832; H10D 84/00

(52) U.S. Cl. CPC H10D 30/668; H10D 30/665; H10D 62/102; H10D 62/126; H10D 62/40; H10D 62/60; H10D 62/8325; H10D 84/143

(57) ABSTRACT

A semiconductor device includes an n-type (a first conductivity type) semiconductor layer having a first main surface; a p-type (a second conductivity type) first region extending in a first direction along the first main surface within the semiconductor layer; a p-type second region formed in a region on the first main surface side relative to the first region within the semiconductor layer and extending in a second direction along the first main surface so as to intersect the first region three-dimensionally; and a p-type low-concentration region formed at least at an intersection portion of the first region and the second region within the semiconductor layer and having a concentration lower than both a maximum concentration of the first region and a maximum concentration of the second region.

### CROSS-REFERENCE TO RELATED APPLICATION

This application is based upon and claims the benefit of priority from Japanese Patent Application No. 2024-057694, filed on Mar. 29, 2024, the entire contents of which are incorporated herein by reference.

### TECHNICAL FIELD

The present disclosure relates to a semiconductor device.

### BACKGROUND

Patent Document 1 (US2015/0028351A1) discloses a semiconductor device having an impurity region introduced into a silicon carbide layer by a channeling implantation method.

### PRIOR ART DOCUMENT

### Patent Publication

[Patent document 1] US Patent Application Publication No. 2015/0028351.

### BRIEF DESCRIPTION OF THE DRAWINGS

FIG. 1 is a plan view showing a chip of a semiconductor device according to a first embodiment.

FIG. 2 is a perspective view of the chip shown in FIG. 1.

FIG. 3 is a cross-sectional perspective view showing a main part of a chip along with a pillar region according to a first example.

FIG. 4 is a graph (simulation) showing an impurity concentration of a pillar region.

FIG. 5A is a plan view showing a first layout example of the pillar region according to the first example.

FIG. 5B is a plan view showing a second layout example of the pillar region according to the first example.

FIG. 5C is a plan view showing a third layout example of the pillar region according to the first example.

FIG. 6 is a cross-sectional perspective view showing a main part of a chip along with a pillar region according to a second example.

FIG. 7A is a plan view showing a first layout example of the pillar region according to the second example.

FIG. 7B is a plan view showing a second layout example of the pillar region according to the second example.

FIG. 7C is a plan view showing a third layout example of the pillar region according to the second example.

FIG. 8 is a cross-sectional perspective view showing a main part of a chip along with a pillar region according to a third example.

FIG. 9A is a plan view showing a first layout example of the pillar region according to the third example.

FIG. 9B is a plan view showing a second layout example of the pillar region according to the third example.

FIG. 9C is a plan view showing a third layout example of the pillar region according to the third example.

FIG. 10 is a cross-sectional perspective view showing a main part of a chip along with a pillar region according to a fourth example.

FIG. 11 is a cross-sectional perspective view showing a main part of a chip along with a pillar region according to a fifth example.

FIG. 12 is a cross-sectional perspective view showing a first modification example applied to the pillar regions according to the first to fifth examples.

FIG. 13 is a cross-sectional perspective view showing a second modification example applied to the pillar regions according to the first to fifth examples.

FIG. 14 is a plan view showing a semiconductor device according to a second embodiment.

FIG. 15 is a plan view showing a layout example of a first main surface.

FIG. 16 is an enlarged plan view showing a main part of an active region.

FIG. 17 is a cross-sectional view along a line XVII-XVII shown in FIG. 16.

FIG. 18 is a cross-sectional view along a line XVIII-XVIII shown in FIG. 16.

FIG. 19 is a cross-sectional perspective view showing a main part of an active region along with a pillar region according to the first example.

FIG. 20 is a cross-sectional view along a line XX-XX shown in FIG. 14.

FIG. 21 is a cross-sectional view showing a main part of an active region of a semiconductor device according to a third embodiment.

FIG. 22 is a cross-sectional view showing another main part of an active region of a semiconductor device shown in FIG. 21.

FIG. 23 is a cross-sectional perspective view showing a main part of an active region along with a pillar region according to a first example.

FIG. 24 is an enlarged plan view showing an active region of a semiconductor device according to a fourth embodiment.

FIG. 25 is a cross-sectional view along a line XXV-XXV shown in FIG. 24.

FIG. 26 is a cross-sectional perspective view showing a main part of an active region along with a pillar region according to a first example.

FIG. 27 is an enlarged plan view showing an active region of a semiconductor device according to a fifth embodiment.

FIG. 28 is a cross-sectional view along a line XXVIII-XXVIII shown in FIG. 27.

FIG. 29 is a cross-sectional view along a line XXIX-XXIX shown in FIG. 27.

FIG. 30 is a cross-sectional perspective view showing a main part of an active region along with a pillar region according to a first example.

FIG. 31 is a cross-sectional view showing an outer region of a semiconductor device shown in FIG. 27.

FIG. 32 is a cross-sectional perspective view showing an active region of a semiconductor device according to a sixth embodiment along with a pillar region according to a first example.

FIG. 33 is a plan view showing a semiconductor device according to a seventh embodiment.

FIG. 34 is a perspective view of a chip shown in FIG. 33.

FIG. 35 is a cross-sectional view along a line XXXV-XXXV shown in FIG. 33.

FIG. 36 is a cross-sectional view showing a modification example applied to any one of the semiconductor devices according to the second to sixth embodiments.

### DETAILED DESCRIPTION OF THE EMBODIMENTS

Hereinafter, specific embodiments are described in detail with reference to the accompanying figures. The accompanying figures are all schematic views and not strictly depicted, so the relative positional relationships, scales, ratios, angles, etc., are not necessarily consistent. Corresponding structures among the accompanying figures are given the same reference numerals, and redundant descriptions are omitted or simplified. For structures where descriptions are omitted or simplified, the descriptions given before the omission or simplification apply.

In this specification, open language such as “including” or “having” is described as a concept that encompasses closed language such as “consisting of.” When the term “substantially” is used in this specification, this term includes a numerical value (form) equal to the numerical value (form) of the comparison target, and also includes a numerical error (form error) within a range of ±10% based on the numerical value (form) of the comparison target.

Terms “first,” “second,” “third,” etc., are used in this specification, but these are symbols attached to the names of each structure to clarify the order of description and are not intended to limit the names of each structure.

In this specification, the conductivity type of a semiconductor (impurity) is indicated using “p-type” or “n-type,” but “p-type” may be referred to as “first conductivity type,” and “n-type” may be referred to as “second conductivity type.” “N-type” may be referred to as “first conductivity type,” and “p-type” may be referred to as “second conductivity type.”

“P-type” is a conductivity type resulting from a trivalent element, and “n-type” is a conductivity type resulting from a pentavalent element. The trivalent element is at least one of boron, aluminum, gallium, and indium. The pentavalent element is at least one of nitrogen, phosphorus, arsenic, antimony, and bismuth.

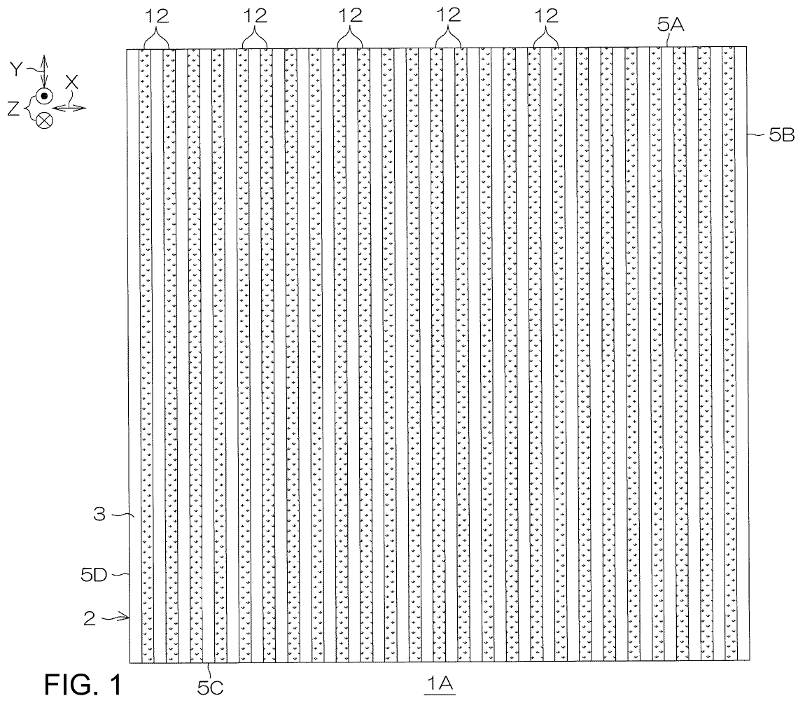

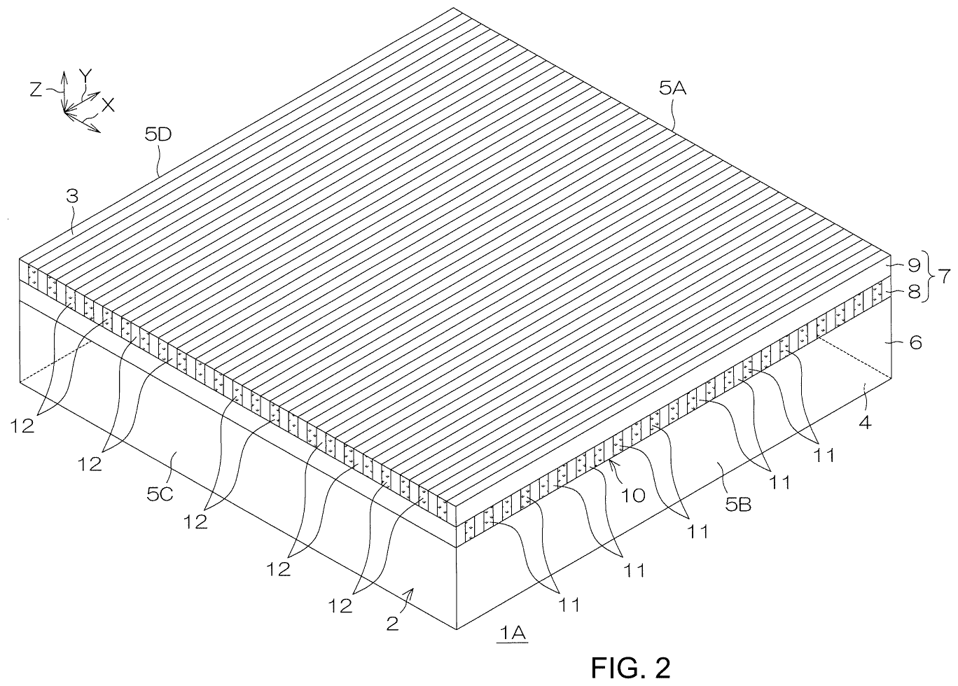

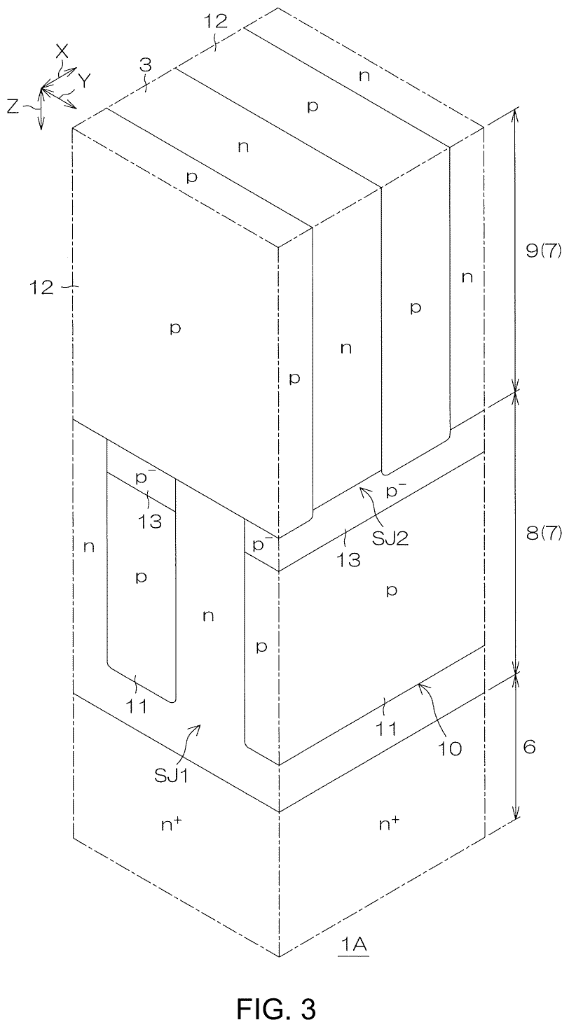

FIG. 1 is a plan view showing a chip 2 of a semiconductor device 1A according to a first embodiment. FIG. 2 is a perspective view of the chip 2 shown in FIG. 1. FIG. 3 is a cross-sectional perspective view showing a main part of the chip 2 along with a pillar region 10 according to a first example.

Referring to FIGS. 1 to 3, the semiconductor device 1A includes the chip 2 formed in a hexahedral shape (specifically, a rectangular parallelepiped shape). In this embodiment, the chip 2 includes a single crystal of a wide bandgap semiconductor. That is, the semiconductor device 1A is a “wide bandgap semiconductor device.” The chip 2 may be referred to as a “semiconductor chip”, a “wide bandgap semiconductor chip,” etc.

The wide bandgap semiconductor is a semiconductor having a bandgap exceeding the bandgap of Si (silicon). GaN (gallium nitride), SiC (silicon carbide), C (diamond), etc. are examples of wide bandgap semiconductors. In this embodiment, the chip 2 is a “SiC chip” that includes a hexagonal SiC single crystal as an example of a wide bandgap semiconductor. That is, the semiconductor device 1A is a “SiC semiconductor device.”

The hexagonal SiC single crystal has a plurality of polytypes, including a 2H (Hexagonal)-SiC single crystal, a 4H—SiC single crystal, and a 6H—SiC single crystal. In this embodiment, an example where the chip 2 includes a 4H—SiC single crystal is shown, but the chip 2 may include other polytypes. The chip 2 may include cubic crystals or polycrystals. For example, the chip 2 may include a 3C (cubic)-SiC single crystal or a 3C—SiC polycrystal.

The chip 2 has a first main surface 3 on one side, a second main surface 4 on the other side, and first to fourth side surfaces 5A to 5D connected to the first main surface 3 and the second main surface 4. The first main surface 3 and the second main surface 4 are formed in a quadrilateral shape in a plan view viewed from the vertical direction Z (hereinafter simply referred to as “plan view”). The vertical direction Z is also the thickness direction of the chip 2.

The first main surface 3 and the second main surface 4 are formed by the c-plane of the SiC single crystal. The first main surface 3 may be formed of the silicon face ((0001) face) of the SiC single crystal, and the second main surface 4 may be formed of the carbon face ((000-1) face) of the SiC single crystal.

The first side surface 5A extends in the first direction X. The second side surface 5B is connected to the first side surface 5A and extends in the second direction Y, which intersects (specifically, orthogonally) the first direction X. The third side surface 5C is connected to the second side surface 5B and extends in the first direction X. The fourth side surface 5D is connected to the first side surface 5A and the third side surface 5C and extends in the second direction Y.

In this embodiment, the first direction X is the m-axis direction ([1-100] direction) of the SiC single crystal, and the second direction Y is the a-axis direction ([11-20] direction) of the SiC single crystal. The first direction X may be the a-axis direction of the SiC single crystal, and the second direction Y may be the m-axis direction of the SiC single crystal. Hereinafter, the direction extending along the first main surface 3 may be expressed as the “horizontal direction.” The horizontal direction is also the XY plane (horizontal plane) formed of the first direction X and the second direction Y, and is orthogonal to the vertical direction Z.

The chip 2 (the first main surface 3 and the second main surface 4) has an off-angle inclined at a predetermined angle in a predetermined off-direction with respect to the c-plane of the SiC single crystal. The c-axis ((0001) axis) of the SiC single crystal is inclined by the off-angle from the vertical line along the vertical direction Z toward the off-direction. The c-plane of the SiC single crystal is inclined by the off-angle with respect to the horizontal plane.

It is preferable that the off-direction is the a-axis direction of the SiC single crystal (the second direction Y in this embodiment). The off-angle may be greater than 0° and less than or equal to 10°. The off-angle may have a value that falls within at least one of the ranges of greater than 0° and less than or equal to 1°, 1° or more and 2.5° or less, 2.5° or more and 5° or less, 5° or more and 7.5° or less, and 7.5° or more and 10° or less.

It is preferable that the off-angle is 5° or less. It is particularly preferable that the off-angle is 2° or more and 4.5° or less. Typically, the off-angle is set in the range of 4°+0.1°. This specification does not exclude the embodiment where the off-angle is 0° (the embodiment where the first main surface 3 is a just plane relative to the c-plane).

The chip 2 includes an n-type base layer 6 formed in a region on the second main surface 4 side. The base layer 6 may be referred to as a “base semiconductor layer,” “semiconductor substrate,” “drain layer (region),” etc. The base layer 6 extends in a layered form along the second main surface 4 and forms a lower layer portion of the chip 2. The base layer 6 is formed over the entire area of the second main surface 4 and forms a portion of the second main surface 4 and a portion of the first to fourth side surfaces 5A to 5D of the chip 2.

The base layer 6 includes a single crystal of a wide bandgap semiconductor. In this embodiment, the base layer 6 is a SiC substrate including a hexagonal SiC single crystal. In this embodiment, the base layer 6 includes a 4H—SiC single crystal and has the above-mentioned off-direction and off-angle. The base layer 6 may include other polytypes. The base layer 6 may include a 3C—SiC polycrystal. In this case, the second main surface 4 is formed of the 3C—SiC polycrystal.

The base layer 6 may have a substantially constant n-type impurity concentration in the thickness direction. The n-type impurity concentration of the base layer 6 may be adjusted by a single type of pentavalent element. It is preferable for the base layer 6 to include a pentavalent element other than phosphorus. In this embodiment, the concentration of the base layer 6 is adjusted by nitrogen as a pentavalent element.

The base layer 6 may have a thickness greater than 0 μm and less than or equal to 500 μm. The thickness of the base layer 6 may have a value that falls within at least one of the ranges of greater than 0 μm and less than or equal to 1 μm, 1 μm or more and 50 μm or less, 50 μm or more and 100 μm or less, 100 μm or more and 150 μm or less, 150 μm or more and 200 μm or less, 200 μm or more and 250 μm or less, 250 μm or more and 300 μm or less, 300 μm or more and 350 μm or less, 350 μm or more and 400 μm or less, 400 μm or more and 450 μm or less, and 450 μm or more and 500 μm or less.

The chip 2 includes an n-type semiconductor layer 7 formed in a region on the first main surface 3 side within the chip 2 relative to the base layer 6. The semiconductor layer 7 has a laminated structure including an n-type first layer 8 and an n-type second layer 9. The first layer 8 may be referred to as a “first semiconductor layer,” “first SiC layer,” “first drain layer (region),” “first drift layer (region),” etc., and the second layer 9 may be referred to as a “second semiconductor layer,” “second SiC layer,” “second drain layer (region),” “second drift layer (region),” etc.

The first layer 8 is laminated on the base layer 6 and forms a middle layer portion of the chip 2. The first layer 8 extends in a layered form along the first main surface 3 (the base layer 6) and forms a portion of the first to fourth side surfaces 5A to 5D of the chip 2.

The first layer 8 includes a single crystal of a wide bandgap semiconductor. In this embodiment, the first layer 8 is a SiC layer including a hexagonal SiC single crystal. In this embodiment, the first layer 8 is formed of an epitaxial layer including a 4H—SiC single crystal (hexagonal) and has the above-mentioned off-direction and off-angle. The first layer 8 may include other polytypes.

The first layer 8 has an n-type impurity concentration lower than the n-type impurity concentration of the base layer 6. The n-type impurity concentration of the first layer 8 may be substantially constant in the thickness direction. The n-type impurity concentration of the first layer 8 may have a concentration gradient that gradually increases and/or decreases in the laminating direction (crystal growth direction).

It is preferable that the n-type impurity concentration of the first layer 8 is adjusted by at least one type of pentavalent element. For example, the n-type impurity concentration of the first layer 8 may be adjusted by at least one of nitrogen, phosphorus, arsenic, antimony, and bismuth. It is preferable for the first layer 8 to include pentavalent elements other than phosphorus. It is preferable for the first layer 8 to include at least nitrogen as a pentavalent element. When the first layer 8 includes two or more pentavalent elements, it is preferable for the first layer 8 to include at least two of nitrogen, arsenic, and antimony.

The first layer 8 has a thickness less than the thickness of the base layer 6 in the thickness direction. The thickness of the first layer 8 may be greater than 0 μm and less than or equal to 10 μm. The thickness of the first layer 8 may have a value that falls within at least one of the ranges of greater than 0 μm and less than or equal to 0.5 μm, 0.5 μm or more and 1 μm or less, 1 μm or more and 2 μm or less, 2 μm or more and 3 μm or less, 3 μm or more and 4 μm or less, 4 μm or more and 5 μm or less, 5 μm or more and 6 μm or less, 6 μm or more and 7 μm or less, 7 μm or more and 8 μm or less, 8 μm or more and 9 μm or less, and 9 μm or more and 10 μm or less.

The second layer 9 is laminated on the first layer 8 and forms an upper layer portion of the chip 2. The second layer 9 extends in a layered form along the first main surface 3 (the first layer 8) and forms the first main surface 3 and a portion of the first to fourth side surfaces 5A to 5D of the chip 2.

The second layer 9 includes a single crystal of a wide bandgap semiconductor. In this embodiment, the second layer 9 is a SiC layer including a hexagonal SiC single crystal. In this embodiment, the second layer 9 is formed of an epitaxial layer including a 4H—SiC single crystal (hexagonal) and has the above-mentioned off-direction and off-angle. The second layer 9 may include other polytypes. The second layer 9 may have a different polytype from the polytype of the first layer 8.

The second layer 9 has an n-type impurity concentration lower than the n-type impurity concentration of the base layer 6. The n-type impurity concentration of the second layer 9 is substantially equal to the n-type impurity concentration of the first layer 8. The n-type impurity concentration of the second layer 9 may be higher or lower than the n-type impurity concentration of the first layer 8. The n-type impurity concentration of the second layer 9 may be substantially constant in the thickness direction. The n-type impurity concentration of the second layer 9 may have a concentration gradient that gradually increases and/or decreases in the laminating direction (crystal growth direction).

It is preferable that the n-type impurity concentration of the second layer 9 is adjusted by at least one pentavalent element. For example, the n-type impurity concentration of the second layer 9 may be adjusted by at least one of nitrogen, phosphorus, arsenic, antimony, and bismuth. It is preferable for layer 9 to include pentavalent elements other than phosphorus. It is preferable for layer 9 to include at least nitrogen as a pentavalent element. When the second layer 9 includes two or more pentavalent elements, it is preferable for the second layer 9 to include at least two of nitrogen, arsenic, and antimony.

The second layer 9 has a thickness less than the thickness of the base layer 6 in the thickness direction. The thickness of the second layer 9 may be substantially equal to the thickness of the first layer 8. The thickness of the second layer 9 may be either greater than or less than the thickness of the first layer 8. The thickness of the second layer 9 may be greater than 0 μm and less than or equal to 10 μm.

The thickness of the second layer 9 may have a value that falls within at least one of the ranges of greater than 0 μm and less than or equal to 0.5 μm, 0.5 μm or more and 1 μm or less, 1 μm or more and 2 μm or less, 2 μm or more and 3 μm or less, 3 μm or more and 4 μm or less, 4 μm or more and 5 μm or less, 5 μm or more and 6 μm or less, 6 μm or more and 7 μm or less, 7 μm or more and 8 μm or less, 8 μm or more and 9 μm or less, and 9 μm or more and 10 μm or less.

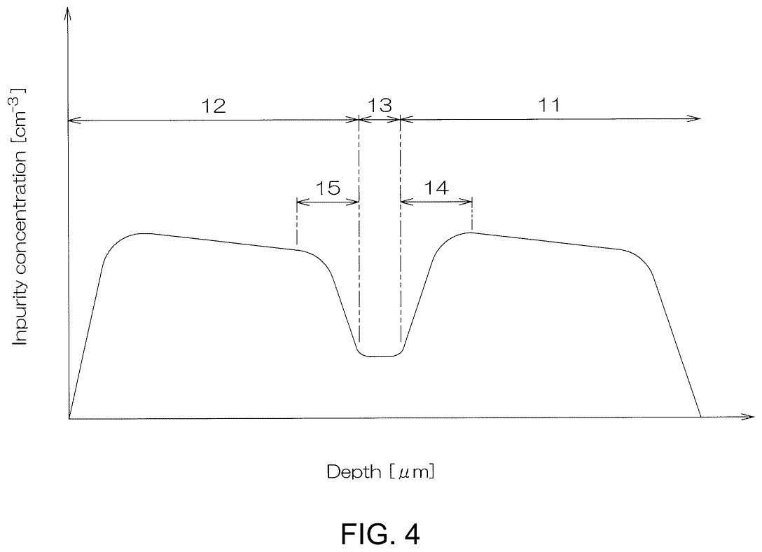

The semiconductor device 1A includes a p-type pillar region 10 formed within the semiconductor layer 7. The configuration of the pillar region 10 is described below with reference to FIG. 4. FIG. 4 is a graph (simulation) showing the impurity concentration of the pillar region 10. In FIG. 4, the vertical axis represents impurity concentration [cm⁻³], and the horizontal axis represents depth [μm]. The pillar region 10 may be referred to as an “impurity region,” “column region,” “p-type region,” etc.

The pillar region 10 includes a plurality of p-type first regions 11 formed within the semiconductor layer 7. The first regions 11 may be referred to as “first column regions (layers),” “first pillar regions (layers),” “first p-type regions (layers),” etc. The plurality of first regions 11 are formed in the semiconductor layer 7 with a spacing from the first main surface 3 in the thickness direction. Specifically, the plurality of first regions 11 are formed in the first layer 8.

The plurality of first regions 11 each extend in a strip shape in the first direction X in a plan view and are formed with a spacing in the second direction Y. The plurality of first regions 11 extend in a stripe shape in the first direction X. In this embodiment, the plurality of first regions 11 have a length from the second side surface 5B to the fourth side surface 5D in the first direction X and are exposed from both the second side surface 5B and the fourth side surface 5D. The plurality of first regions 11 may be formed with a spacing inward from either or both of the second side surface 5B and the fourth side surface 5D.

The plurality of first regions 11 are each formed in a pillar shape (column shape) extending longitudinally in the thickness direction in a cross-sectional view and each have an upper end on the first main surface 3 side (the second layer 9 side) and a lower end on the second main surface 4 side (the base layer 6 side). In this embodiment, the upper end is formed with a spacing from the second layer 9 to the second main surface 4 side and face the second layer 9 with a portion of the first layer 8 in between. In this embodiment, the plurality of first regions 11 are not formed in the second layer 9.

The lower end is formed with a spacing from the base layer 6 to the first main surface 3 side and faces the base layer 6 with a portion of the first layer 8 in between. The lower end may be positioned in the surface layer portion of the base layer 6 across the boundary portion between the base layer 6 and the first layer 8.

The first region 11 may have a width greater than 0 μm and less than or equal to 10 μm. The width of the first region 11 may be less than the thickness of the first layer 8. The width of the first region 11 may be greater than the thickness of the first layer 8.

The width of the first region 11 may have a value that falls within at least one of the ranges of greater than 0 μm and less than or equal to 0.5 μm, 0.5 μm or more and 1 μm or less, 1 μm or more and 2 μm or less, 2 μm or more and 3 μm or less, 3 μm or more and 4 μm or less, 4 μm or more and 5 μm or less, 5 μm or more and 6 μm or less, 6 μm or more and 7 μm or less, 7 μm or more and 8 μm or less, 8 μm or more and 9 μm or less, and 9 μm or more and 10 μm or less. It is preferable that the width of the first region 11 is 5 μm or less.

The first region 11 may have a depth greater than 0 μm and less than or equal to 10 μm. The depth of the first region 11 is the distance between the upper end of the first region 11 and the lower end of the first region 11. The depth of the first region 11 may be less than the thickness of the first layer 8. The depth of the first region 11 may be greater than the thickness of the first layer 8.

The depth of the first region 11 may have a value that falls within at least one of the ranges of greater than 0 μm and less than or equal to 0.5 μm, 0.5 μm or more and 1 μm or less, 1 μm or more and 2 μm or less, 2 μm or more and 3 μm or less, 3 μm or more and 4 μm or less, 4 μm or more and 5 μm or less, 5 μm or more and 6 μm or less, 6 μm or more and 7 μm or less, 7 μm or more and 8 μm or less, 8 μm or more and 9 μm or less, and 9 μm or more and 10 μm or less.

The plurality of first regions 11 may be formed with a spacing greater than 0 μm and less than or equal to 10 μm. The spacing of the first regions 11 may be substantially equal to the width of the first region 11. The spacing of the first regions 11 may be either greater than or less than the width of the first regions 11.

The spacing between the plurality of first regions 11 may have a value that falls within at least one of the ranges of greater than 0 μm and less than or equal to 0.5 μm, 0.5 μm or more and 1 μm or less, 1 μm or more and 2 μm or less, 2 μm or more and 3 μm or less, 3 μm or more and 4 μm or less, 4 μm or more and 5 μm or less, 5 μm or more and 6 μm or less, 6 μm or more and 7 μm or less, 7 μm or more and 8 μm or less, 8 μm or more and 9 μm or less, and 9 μm or more and 10 μm or less.

In this embodiment, a plurality of first regions 11 are each formed of a single p-type impurity region extending along the axis channel of the SiC single crystal (the first layer 8). The axis channel is a region having relatively wide interatomic distances with respect to the SiC single crystal and is surrounded by atomic rows that constitute the crystal axis extending in the laminating direction. That is, the axis channel is a region where the interatomic distance (atomic density) in the horizontal direction is sparse that extends in the thickness direction.

It is preferable that the axis channel is a region surrounded by atomic rows along the low-index crystal axes among the crystal axes. With respect to the Miller indices (a1, a2, a3, c), a low-index crystal axis is a crystal axis in which the absolute values of “a1”, “a2”, “a3” and “c” are all expressed as 0 or more and 2 or less (preferably 1 or less).

In this embodiment, the axis channel is formed of a region surrounded by atomic rows along the c-axis ((0001) axis) of the SiC single crystal. That is, the plurality of first regions 11 extend along the c-axis as the axis channel and have the above-mentioned off-direction and off-angle. In other words, the plurality of first regions 11 are inclined by the off-angle toward the off-direction from the vertical axis.

It is preferable that the p-type impurity concentration of the first region 11 is adjusted by at least one type of trivalent element. It is particularly preferable that the p-type impurity concentration of the first region 11 is adjusted by a trivalent element belonging to heavy elements heavier than carbon. That is, it is preferable that the first region 11 includes a trivalent element other than boron (at least one of aluminum, gallium, and indium). In this embodiment, the p-type impurity concentration of the first region 11 is adjusted by aluminum.

The first region 11 has a concentration gradient in which the p-type impurity concentration increases from the lower end to the upper end (refer to FIG. 4). It is preferable for the first region 11 to have a thickness of at least 0.5 μm or more. It is preferable for the first region 11 to include a gradual reduction section that has a concentration reduction rate of 50% or less within a thickness range of 0.5 μm. It is preferable that the gradual reduction section occupies a thickness range of 25% or more and 80% or less of the first region 11.

The plurality of first regions 11 form a first pn junction portion with the first layer 8. The plurality of first regions 11 form a first super junction structure SJ1 that has charge balance with the first layer 8. The state of having charge balance means a state where depletion layers extending from one first region 11 and another first region 11 are connected in a region between one and the other of the first regions 11.

The pillar region 10 includes a plurality of p-type second regions 12 formed in the semiconductor layer 7. The second regions 12 may be referred to as “second column regions (layers),” “second pillar regions (layers),” “second p-type regions (layers),” etc. The plurality of second regions 12 are formed in regions on the first main surface 3 side relative to the plurality of first regions 11 within the semiconductor layer 7. Specifically, the plurality of second regions 12 are formed in the second layer 9.

The plurality of second regions 12 extend in a direction different from that of the plurality of first regions 11 in the plan view and intersect the plurality of first regions 11 three-dimensionally. As a result, the plurality of second regions 12 constitute a single pillar region 10 in a three-dimensional lattice shape with the plurality of first regions 11. In this embodiment, the plurality of second regions 12 each extend in a strip shape in the second direction Y in the plan view and are formed with a spacing in the first direction X. The plurality of second regions 12 extend in a stripe shape in the second direction Y and intersect (are orthogonal to) the plurality of first regions 11.

In this embodiment, the plurality of second regions 12 have a length from the first side surface 5A to the third side surface 5C with respect to the second direction Y and are exposed from both the first side surface 5A and the third side surface 5C. The plurality of second regions 12 may be formed with a spacing inward from either or both of the first side surface 5A and the third side surface 5C.

The plurality of second regions 12 are each formed in a pillar shape (column shape) extending longitudinally in the thickness direction in a cross-sectional view and each have an upper end on the first main surface 3 side and a lower end on the second main surface 4 side (the first layer 8 side). In this embodiment, the upper end is exposed from the first main surface 3. The upper end may be formed with a spacing in the thickness direction from the first main surface 3.

In this embodiment, the lower end is positioned within the first layer 8 across the boundary portion between the first layer 8 and the second layer 9. The lower end may be formed with a spacing from the upper end of the first layer 8 toward the first main surface 3 side. That is, the plurality of second regions 12 may be formed with a spacing in the thickness direction from the plurality of first layers 8.

The second region 12 may have a width greater than 0 μm and less than or equal to 10 μm. The width of the second region 12 may be less than the thickness of the second layer 9. The width of the second region 12 may be greater than the thickness of the second layer 9. The width of the second region 12 may be substantially equal to the width of the first region 11. The width of the second region 12 may be either greater than or less than the width of the first region 11.

The width of the second region 12 may have a value that falls within at least one of the ranges of greater than 0 μm and less than or equal to 0.5 μm, 0.5 μm or more and 1 μm or less, 1 μm or more and 2 μm or less, 2 μm or more and 3 μm or less, 3 μm or more and 4 μm or less, 4 μm or more and 5 μm or less, 5 μm or more and 6 μm or less, 6 μm or more and 7 μm or less, 7 μm or more and 8 μm or less, 8 μm or more and 9 μm or less, and 9 μm or more and 10 μm or less. It is preferable for the width of the second region 12 to be 5 μm or less.

The second region 12 may have a depth greater than 0 μm and less than or equal to 10 μm. The depth of the second region 12 is the distance between the upper end of the second region 12 and the lower end of the second region 12. The depth of the second region 12 may be greater than the thickness of the second layer 9. The depth of the second region 12 may be less than the thickness of the second layer 9. The depth of the second region 12 may be substantially equal to the depth of the first region 11. The depth of the second region 12 may be either greater than or less than the depth of the first region 11.

The depth of the second region 12 may have a value that falls within at least one of the ranges of greater than 0 μm and less than or equal to 0.5 μm, 0.5 μm or more and 1 μm or less, 1 μm or more and 2 μm or less, 2 μm or more and 3 μm or less, 3 μm or more and 4 μm or less, 4 μm or more and 5 μm or less, 5 μm or more and 6 μm or less, 6 μm or more and 7 μm or less, 7 μm or more and 8 μm or less, 8 μm or more and 9 μm or less, and 9 μm or more and 10 μm or less.

The plurality of second regions 12 may be formed with a spacing greater than 0 μm and less than or equal to 10 μm. The spacing of the second regions 12 may be substantially equal to the width of the second regions 12. The spacing of the second regions 12 may be either greater than or less than the width of the second regions 12. The spacing of the second regions 12 may be substantially equal to the spacing of the first regions 11. The spacing of the second regions 12 may be either greater than or less than the spacing of the first regions 11.

The spacing between the plurality of second regions 12 may have a value that falls within at least one of the ranges of greater than 0 μm and less than or equal to 0.5 μm, 0.5 μm or more and 1 μm or less, 1 μm or more and 2 μm or less, 2 μm or more and 3 μm or less, 3 μm or more and 4 μm or less, 4 μm or more and 5 μm or less, 5 μm or more and 6 μm or less, 6 μm or more and 7 μm or less, 7 μm or more and 8 μm or less, 8 μm or more and 9 μm or less, and 9 μm or more and 10 μm or less.

In this embodiment, the plurality of second regions 12 are each formed by a single p-type impurity region extending along the axis channel of the SiC single crystal (the second layer 9), similar to the plurality of first regions 11. That is, the plurality of second regions 12 extend along the c-axis as the axis channel and have the above-mentioned off-direction and off-angle. That is, the plurality of second regions 12 are inclined by the off-angle toward the off-direction from the vertical axis.

It is preferable that the p-type impurity concentration of the second regions 12 is adjusted by at least one type of trivalent element. It is particularly preferable that the p-type impurity concentration of the second region 12 is adjusted by a trivalent element belonging to heavy elements heavier than carbon. That is, it is preferable that the second region 12 includes a trivalent element other than boron (at least one of aluminum, gallium, and indium).

In this embodiment, the p-type impurity concentration of the second region 12 is adjusted by aluminum. The trivalent element of the second region 12 is of the same type as the trivalent element of the first region 11. The trivalent element of the second region 12 may differ from the trivalent element of the first region 11. In this embodiment, the p-type impurity concentration of the second region 12 is substantially equal to the p-type impurity concentration of the first region 11. The p-type impurity concentration of the second region 12 may be either higher or lower than the p-type impurity concentration of the first region 11.

The second region 12 has a concentration gradient in which the p-type impurity concentration increases from the lower end to the upper end (refer to FIG. 4). It is preferable for the second region 12 to have a thickness of at least 0.5 μm or more. It is preferable for the second region 12 to include a gradual reduction section that has a concentration reduction rate of 50% or less within a thickness range of 0.5 μm. It is preferable that the gradual reduction section occupies a thickness range of 25% or more and 80% or less of the second region 12.

The plurality of second regions 12 form a second pn junction portion with the second layer 9. The plurality of second regions 12 form a second super junction structure SJ2 that has charge balance with the second layer 9. The state of charge balance means a state where depletion layers diffusing from one second region 12 and another second region 12 are connected in a region between one and the other of the second regions 12.

The pillar region 10 includes a plurality of p-type low-concentration regions 13 formed in the semiconductor layer 7. The low-concentration regions 13 may be referred to as “connection regions (layers),” “boundary regions (layers),” etc. The plurality of low-concentration regions 13 are interposed at the intersection portions of the plurality of first regions 11 and the plurality of second regions 12, respectively.

The plurality of low-concentration regions 13 have a p-type impurity concentration that is lower than both the maximum value of the p-type impurity concentration of the first region 11 and the maximum value of the p-type impurity concentration of the second region 12 (refer to FIG. 4). The p-type impurity concentration of the low-concentration regions 13 is lower than both the p-type impurity concentration at the thickness position of the middle portion of the first region 11 and the p-type impurity concentration at the thickness position of the middle portion of the second region 12 (refer to FIG. 4).

The p-type impurity concentration of the low-concentration regions 13 is adjusted by at least one type of trivalent element. The trivalent element in the low-concentration regions 13 may be of the same type or a different type from the trivalent element in the first region 11. The trivalent element in the low-concentration regions 13 may be of the same type or a different type from the trivalent element in the second region 12. The trivalent element in the low-concentration regions 13 may be either or both of boron and aluminum.

In this embodiment, the plurality of low-concentration regions 13 are each formed of a single p-type impurity region. The plurality of low-concentration regions 13 may be formed of a plurality of p-type impurity regions formed along the thickness direction.

The concentration ratio of the maximum value of the p-type impurity concentration of the low-concentration regions 13 to the maximum value of the p-type impurity concentration of the first region 11 may be greater than 0 and less than 1. The concentration ratio may have a value that falls within at least one of the ranges of greater than 0 and less than or equal to 0.01, 0.01 or more and 0.05 or less, 0.05 or more and 0.1 or less, 0.1 or more and 0.2 or less, 0.2 or more and 0.3 or less, 0.3 or more and 0.4 or less, 0.4 or more and 0.5 or less, 0.5 or more and 0.6 or less, 0.6 or more and 0.7 or less, 0.7 or more and 0.8 or less, 0.8 or more and 0.9 or less, and 0.9 or more and 1 or less.

The plurality of low-concentration regions 13 only need to be disposed respectively at least at the intersection portions and may be led out into regions other than the intersection portions. The plurality of low-concentration regions 13 may be disposed in either or both of the first layer 8 and the second layer 9 at the intersection portions. In this embodiment, the plurality of low-concentration regions 13 are disposed in the first layer 8 and are formed in the intersection portions and regions other than the intersection portions.

Specifically, the plurality of low-concentration regions 13 are provided in a one-to-one correspondence with the plurality of first regions 11 in a region on the second layer 9 side with respect to the first regions 11. The plurality of low-concentration regions 13 each extends in a strip shape in the first direction X in the plan view and are formed with a spacing in the second direction Y. The plurality of low-concentration regions 13 extend in a stripe shape in the first direction X and intersect (are orthogonal to) the plurality of second regions 12.

In this embodiment, the plurality of low-concentration regions 13 have a length from the second side surface 5B to the fourth side surface 5D with respect to the first direction X and are exposed from both the second side surface 5B and the fourth side surface 5D. The plurality of low-concentration regions 13 may be formed with a spacing inward from either or both of the second side surface 5B and the fourth side surface 5D. The plurality of low-concentration regions 13 may be formed in a one-to-many correspondence with the corresponding first regions 11 and may be formed with a spacing in the first direction X following the extending direction of the corresponding first regions 11.

The plurality of low-concentration regions 13 have an upper end on the first main surface 3 side and a lower end on the second main surface 4 side (the first layer 8 side). The upper end is connected to the corresponding second region 12. In this embodiment, the upper end is connected to the corresponding second region 12 within the first layer 8. The upper end may cross the boundary portion between the first layer 8 and the second layer 9 and may be connected to the second region 12 within the second layer 9.

The lower end is positioned within the first layer 8 and is connected to the corresponding first region 11 within the first layer 8. This allows the plurality of low-concentration regions 13 to electrically connect the corresponding first region 11 to the corresponding second region 12. It is preferable that the lower end is formed with a spacing from the depth position of the middle portion of the first layer 8 toward the upper end side of the first layer 8.

The low-concentration region 13 may have a width greater than 0 μm and less than or equal to 10 μm. The width of the low-concentration region 13 may have a value that falls within at least one of the ranges of greater than 0 μm and less than or equal to 0.5 μm, 0.5 μm or more and 1 μm or less, 1 μm or more and 2 μm or less, 2 μm or more and 3 μm or less, 3 μm or more and 4 μm or less, 4 μm or more and 5 μm or less, 5 μm or more and 6 μm or less, 6 μm or more and 7 μm or less, 7 μm or more and 8 μm or less, 8 μm or more and 9 μm or less, and 9 μm or more and 10 μm or less. It is preferable for the width of the low-concentration region 13 to be 5 μm or less.

The low-concentration region 13 may have a depth greater than 0 μm and less than or equal to 2 μm. The depth of the low-concentration region 13 is defined by the distance between the upper end of the low-concentration region 13 (the lower end of the second region 12) and the lower end of the low-concentration region 13 (the upper end of the first region 11). It is preferable that the depth of the low-concentration region 13 is less than both the depth of the first region 11 and the depth of the second region 12.

The depth of the low-concentration region 13 may fall within at least one of the ranges of greater than 0 μm and less than or equal to 0.25 μm, 0.25 μm or more and 0.5 μm or less, 0.5 μm or more and 0.75 μm or less, 0.75 μm or more and 1 μm or less, 1 μm or more and 1.25 μm or less, 1.25 μm or more and 1.5 μm or less, 1.5 μm or more and 1.75 μm or less, and 1.75 μm or more and 2 μm or less.

The low-concentration region 13 forms a first concentration transition portion 14 where the p-type impurity concentration gradually decreases from the first region 11 at the intersection portion (refer to FIG. 4). The depth of the first concentration transition portion 14 may be less than the depth of the low-concentration region 13. The depth of the first concentration transition portion 14 may be greater than the depth of the low-concentration region 13.

The low-concentration region 13 forms a second concentration transition portion 15 where the p-type impurity concentration gradually increases toward the second region 12 (refer to FIG. 4) at the intersection portion. The depth of the second concentration transition portion 15 may be less than the depth of the low-concentration region 13. The depth of the second concentration transition portion 15 may be greater than the depth of the low-concentration region 13.

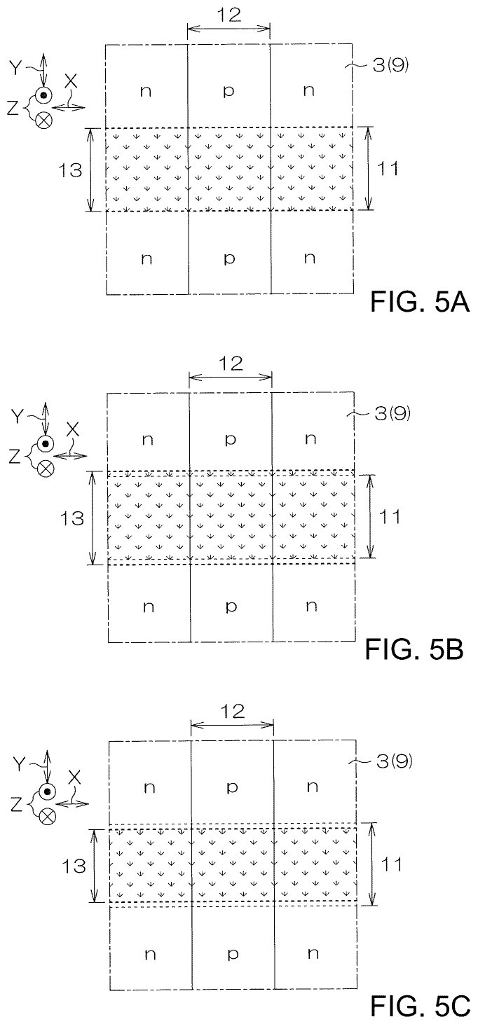

First to third layout examples of the pillar region 10 according to the first example are shown below. FIGS. 5A to 5C are plan views showing the first to third layout examples of the pillar region 10 according to the first example. In FIGS. 5A to 5C, the low-concentration regions 13 are indicated by dotted hatching.

Referring to FIG. 5A (the first layout example), the low-concentration region 13 may have a width substantially equal to the width of the first region 11. The width of the low-concentration region 13 may be substantially equal to the width of the second region 12. The width of the low-concentration region 13 may be either greater than or less than the width of the second region 12.

Referring to FIG. 5B (the second layout example), the low-concentration region 13 may have a width greater than the width of the first region 11. The width of the low-concentration region 13 may be substantially equal to the width of the second region 12. The width of the low-concentration region 13 may be either greater than or less than the width of the second region 12.

Referring to FIG. 5C (the third layout example), the low-concentration region 13 may have a width smaller than the width of the first region 11. The width of the low-concentration region 13 may be substantially equal to the width of the second region 12. The width of the low-concentration region 13 may be either greater than or less than the width of the second region 12.

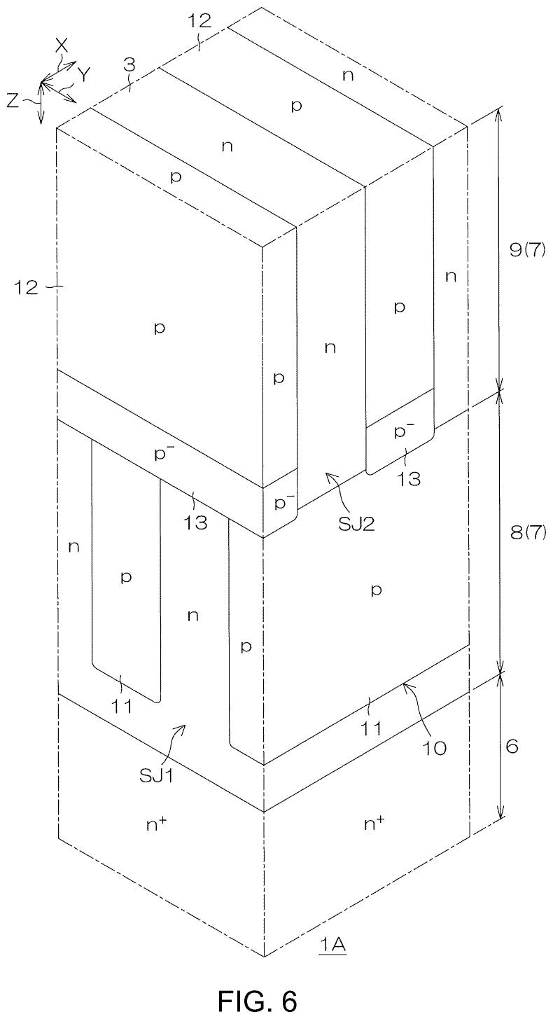

The low-concentration region 13 may have the form shown in FIG. 6. FIG. 6 is a cross-sectional perspective view showing the main part of the chip 2 along with the pillar region 10 according to a second example. Referring to FIG. 6, the pillar region 10 according to the second example includes the plurality of low-concentration regions 13 interposed at the intersection portions of the plurality of first regions 11 and the plurality of second regions 12, respectively, similar to the pillar region 10 according to the first example.

In this embodiment, the plurality of low-concentration regions 13 are disposed in the second layer 9. The plurality of low-concentration regions 13 only need to be disposed at least at the intersection portions, and may be led out into regions other than the intersection portions. In this embodiment, the plurality of low-concentration regions 13 are formed in the intersection portions and regions other than the intersection portions within the second layer 9.

The plurality of low-concentration regions 13 are provided in a one-to-one correspondence with the plurality of second regions 12 in regions of the first layer 8 side with respect to the second regions 12. The plurality of low-concentration regions 13 each extends in a strip shape in the second direction Y in the plan view and are formed with a spacing in the first direction X. The plurality of low-concentration regions 13 extend in a stripe shape in the second direction Y and intersect (are orthogonal to) the plurality of first regions 11.

In this embodiment, the plurality of low-concentration regions 13 have a length from the first side surface 5A to the third side surface 5C with respect to the second direction Y and are exposed from both the first side surface 5A and the third side surface 5C. The plurality of low-concentration regions 13 may be formed with a spacing inward from either or both of the first side surface 5A and the third side surface 5C. The plurality of low-concentration regions 13 may be formed in a one-to-many correspondence with the corresponding second regions 12 and may be formed with a spacing in the second direction Y following the extending direction of the corresponding second regions 12.

The plurality of low-concentration regions 13 have an upper end on the first main surface 3 side and a lower end on the second main surface 4 side (the first layer 8 side). The upper end is disposed within the second layer 9 and is connected to the corresponding second region 12 within the second layer 9. In this embodiment, the lower end is positioned within the first layer 8 across the boundary portion between the first layer 8 and the second layer 9. The lower end is connected to the corresponding first region 11 within the first layer 8.

As a result, the plurality of low-concentration regions 13 electrically connect the corresponding first region 11 to the corresponding second region 12. When the first region 11 has an upper end positioned within the second layer 9, the lower end may be connected to the first region 11 within the second layer 9.

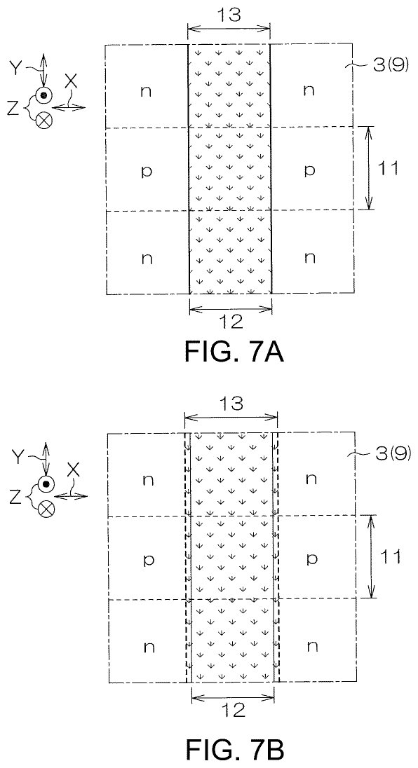

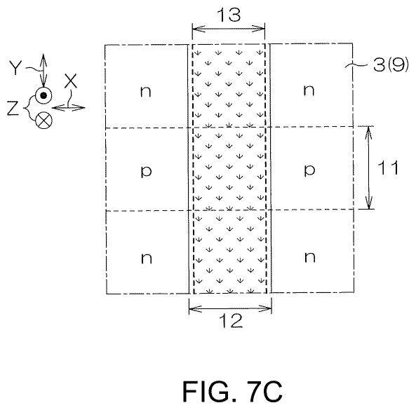

First to third layout examples of the pillar region 10 according to the second example are shown below. FIGS. 7A to 7C are plan views showing the first to third layout examples of the pillar region 10 according to the second example. In FIGS. 7A to 7C, the low-concentration regions 13 are indicated by dotted hatching.

Referring to FIG. 7A (the first layout example), the low-concentration region 13 may have a width substantially equal to the width of the second region 12. The width of the low-concentration region 13 may be substantially equal to the width of the first region 11. The width of the low-concentration region 13 may be either greater than or less than the width of the first region 11.

Referring to FIG. 7B (the second layout example), the low-concentration region 13 may have a width larger than the width of the second region 12. The width of the low-concentration region 13 may be substantially equal to the width of the first region 11. The width of the low-concentration region 13 may be either greater than or less than the width of the first region 11.

Referring to FIG. 7C (the third layout example), the low-concentration region 13 may have a width smaller than the width of the second region 12. The width of the low-concentration region 13 may be substantially equal to the width of the first region 11. The width of the low-concentration region 13 may be either greater than or less than the width of the first region 11.

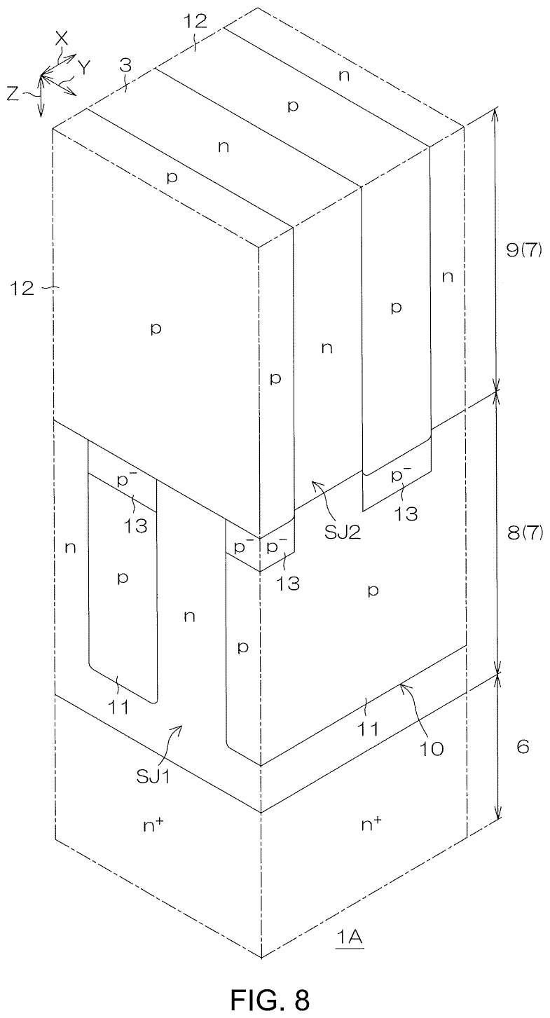

The low-concentration region 13 may have the form shown in FIG. 8. FIG. 8 is a cross-sectional perspective view showing the main part of the chip 2 along with the pillar region 10 according to the third example. Referring to FIG. 8, the pillar region 10 according to the third example includes the plurality of low-concentration regions 13 interposed at the intersection portions of the plurality of first regions 11 and the plurality of second regions 12, respectively, similar to the pillar region 10 according to the first example.

In this embodiment, the plurality of low-concentration regions 13 are provided with a spacing within the first layer 8 in a one-to-one correspondence with the plurality of intersection portions. The plurality of low-concentration regions 13 may each have sides extending in the first direction X following the extending direction of the first region 11, and sides extending in the second direction Y following the extending direction of the second region 12. In this embodiment, the plurality of low-concentration regions 13 are formed in a polygonal shape (quadrilateral shape) in the plan view. The plurality of low-concentration regions 13 may be formed in a circular shape in the plan view.

The plurality of low-concentration regions 13 have an upper end on the first main surface 3 side (the second layer 9 side) and a lower end on the second main surface 4 side (the base layer 6 side). In this embodiment, the upper end is connected to the corresponding second region 12 within the first layer 8. The upper end may cross the boundary portion between the first layer 8 and the second layer 9 and may be connect to the second region 12 within the second layer 9.

The lower end is connected to the corresponding first region 11 within the first layer 8. As a result, the plurality of low-concentration regions 13 electrically connect the corresponding first regions 11 to the corresponding second regions 12. It is preferable that the lower end is formed with a spacing from the depth position of the middle portion of the first layer 8 toward the upper end side of the first layer 8.

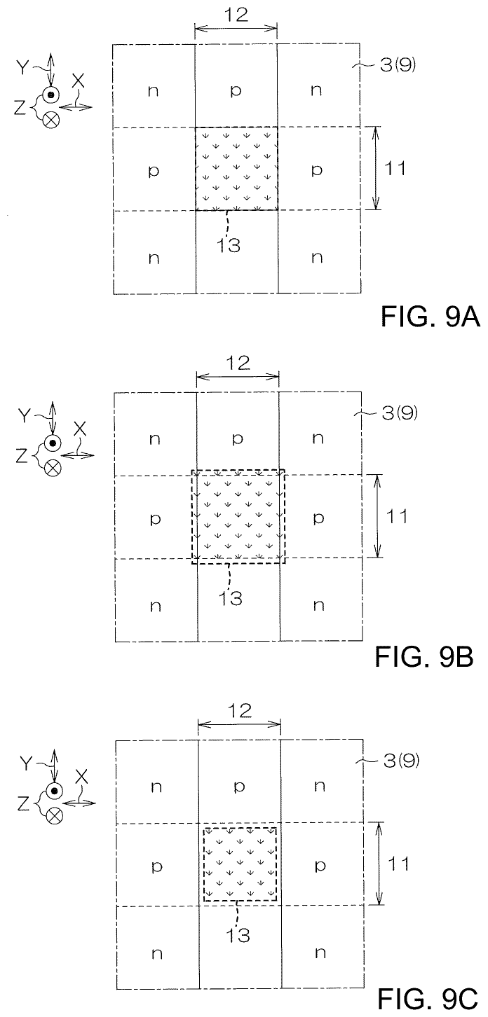

First to third layout examples of the pillar region 10 according to the third example are shown below. FIGS. 9A to 9C are plan views showing the first to third layout examples of the pillar region 10 according to the third example. In FIGS. 9A to 9C, the low-concentration regions 13 are indicated by dotted hatching.

Referring to FIG. 9A (the first layout example), the low-concentration region 13 may have a planar area that is substantially equal to the planar area of the corresponding intersection portion.

Referring to FIG. 9B (the second layout example), the low-concentration region 13 may have a planar area that is larger than the planar area of the corresponding intersection portion. That is, the low-concentration region 13 may be formed at and around the corresponding intersection portion.

A portion of the periphery of the low-concentration region 13 may extend outward from the intersection portion toward the first direction X following the first region 11. Additionally, a portion of the periphery of the low-concentration region 13 may extend outward from the intersection portion toward the second direction Y following the second region 12. The periphery of the low-concentration region 13 may surround the periphery of the corresponding intersection portion in the plan view.

Referring to FIG. 9C (the third layout example), the low-concentration region 13 may have a planar area that is smaller than the planar area of the corresponding intersection portion. In this case, the low-concentration region 13 may be surrounded by the periphery of the corresponding intersection portion in the plan view.

A portion of the periphery of the low-concentration region 13 may extend outward from the intersection portion toward the first direction X following the first region 11. Additionally, a portion of the periphery of the low-concentration region 13 may extend outward from the intersection portion toward the second direction Y following the second region 12.

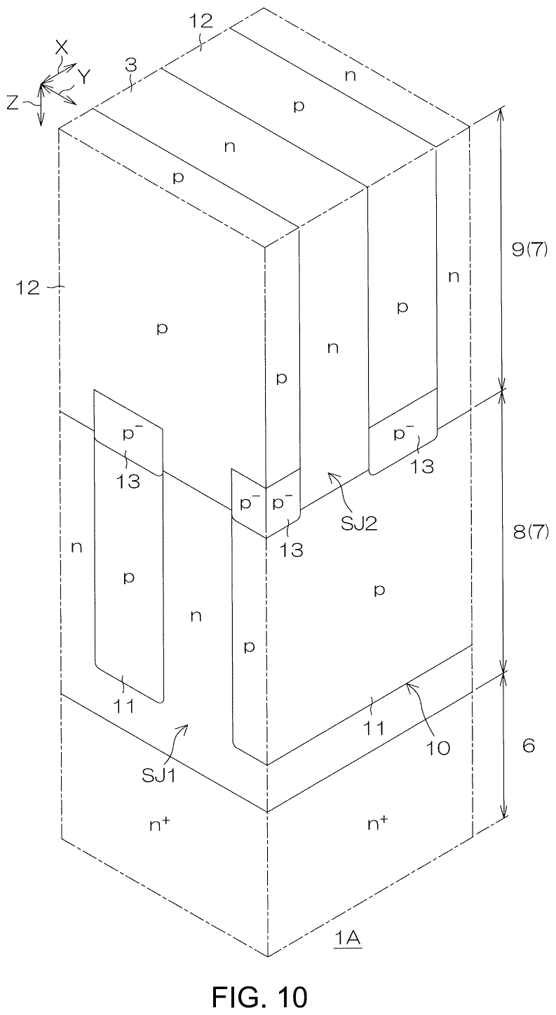

The low-concentration region 13 may have the form shown in FIG. 10. FIG. 10 is a cross-sectional perspective view showing a main part of the chip 2 along with the pillar region 10 according to a fourth example. Referring to FIG. 10, the pillar region 10 according to the fourth example includes the plurality of low-concentration regions 13 interposed at the intersection portions of the plurality of first regions 11 and the plurality of second regions 12, respectively, similar to the pillar region 10 according to the first example.

In this embodiment, the plurality of low-concentration regions 13 are provided with a spacing within the second layer 9 in a one-to-one correspondence with the plurality of intersection portions. The plurality of low-concentration regions 13 may each have sides extending in the first direction X following the extending direction of the first region 11, and sides extending in the second direction Y following the extending direction of the second region 12. In this embodiment, the plurality of low-concentration regions 13 are formed in a polygonal shape (quadrilateral shape) in the plan view. The plurality of low-concentration regions 13 may be formed in a circular shape in the plan view.

The plurality of low-concentration regions 13 have an upper end on the first main surface 3 side (the second layer 9 side) and a lower end on the second main surface 4 side (the first layer 8 side). The upper end is connected to the corresponding second region 12 within the second layer 9. In this embodiment, the lower end crosses the boundary portion between the first layer 8 and the second layer 9 and is connected to the corresponding first region 11 within the first layer 8.

As a result, the plurality of low-concentration regions 13 electrically connect the corresponding first region 11 to the corresponding second region 12. When the first region 11 has an upper end positioned within the second layer 9, the lower end may connect to the first region 11 within the second layer 9.

The low-concentration region 13 according to the fourth example may have the first to third layout examples shown in FIGS. 9A to 9C, similar to the low-concentration region 13 according to the third example.

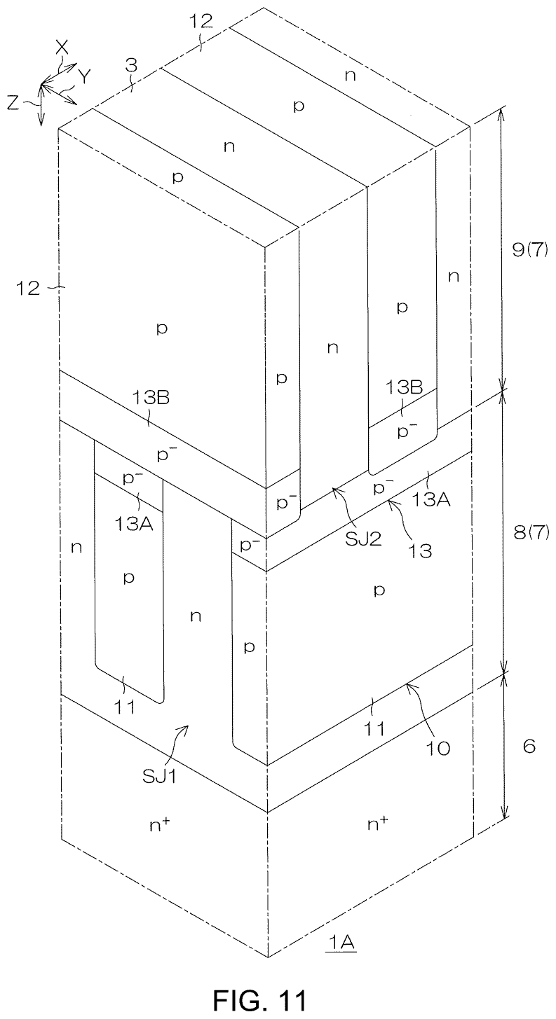

The low-concentration region 13 may have the form shown in FIG. 11. FIG. 11 is a cross-sectional perspective view showing the main part of the chip 2 along with the pillar region 10 according to a fifth example. The pillar region 10 according to the fifth example includes a plurality of low-concentration regions 13 interposed at the intersection portions of a plurality of first regions 11 and a plurality of second regions 12, respectively, similar to the pillar region 10 according to the first example. In this embodiment, the plurality of low-concentration regions 13 include a plurality of first low-concentration regions 13A and a plurality of second low-concentration regions 13B.

The plurality of first low-concentration regions 13A are interposed at the intersection portions of the plurality of first regions 11 and the plurality of second regions 12, respectively. The plurality of first low-concentration regions 13A only need to be respectively disposed at the intersection portions, and may be led out into regions other than the intersection portions. The plurality of first low-concentration regions 13A are disposed in the first layer 8 at the intersection portions and are formed in the intersection portion and regions other than the intersection portion.

In this embodiment, the plurality of first low-concentration regions 13A are provided in a one-to-one correspondence with the plurality of first regions 11 in a region on the second layer 9 side with respect to the first regions 11. The plurality of first low-concentration regions 13A extend in a stripe shape in the first direction X in the plan view and are formed with a spacing in the second direction Y. The plurality of first low-concentration regions 13A extend in a stripe shape in the first direction X and intersect (are orthogonal to) the plurality of second regions 12.

In this embodiment, the plurality of first low-concentration regions 13A have a length from the second side surface 5B to the fourth side surface 5D with respect to the first direction X and are exposed from both the second side surface 5B and the fourth side surface 5D. The plurality of first low-concentration regions 13A may be formed with a spacing inward from either or both of the second side surface 5B and the fourth side surface 5D. The plurality of first low-concentration regions 13A may be formed in a one-to-many correspondence with the corresponding first regions 11 and may be formed with a spacing in the first direction X following the extending direction of the corresponding first regions 11.

The plurality of first low-concentration regions 13A have an upper end on the first main surface 3 side (second layer 9 side) and a lower end on the second main surface 4 side (the first layer 8 side). The upper end may be disposed in the first layer 8 or the second layer 9. The lower end is positioned within the first layer 8 and is connected to the corresponding first region 11 within the first layer 8.

As such, the plurality of first low-concentration regions 13A have a layout similar to the low-concentration region 13 according to the first example (refer to FIG. 3). The first low-concentration region 13A may have the first to third layout examples shown in FIGS. 5A to 5C. The plurality of first low-concentration regions 13A may have a layout similar to the low-concentration region 13 according to the third example (refer to FIG. 8).

The plurality of second low-concentration regions 13B are interposed at the intersection portions of the plurality of first low-concentration regions 13A (the plurality of first regions 11) and the plurality of second regions 12, respectively. The plurality of second low-concentration regions 13B only need to be respectively disposed at least at the intersection portions and may be led out into a region other than the intersection portions. The plurality of second low-concentration regions 13B are disposed in the second layer 9 at the intersection portions and are formed in the intersection portions and regions other than the intersection portions.

The plurality of second low-concentration regions 13B are provided in a one-to-one correspondence with the plurality of second regions 12 in a region on the first layer 8 side with respect to the second regions 12. The plurality of second low-concentration regions 13B extend in a stripe shape in the second direction Y in the plan view and are formed with a spacing in the first direction X. The plurality of second low-concentration regions 13B extend in a stripe shape in the second direction Y and intersect (are orthogonal to) the plurality of first regions 11 and the plurality of first low-concentration regions 13A.

In this embodiment, the plurality of second low-concentration regions 13B have a length from the first side surface 5A to the third side surface 5C with respect to the second direction Y and are exposed from both the first side surface 5A and the third side surface 5C. The plurality of second low-concentration regions 13B may be formed with a spacing inward from either or both of the first side surface 5A and the third side surface 5C. The plurality of second low-concentration regions 13B may be formed in a one-to-many correspondence with the corresponding second regions 12 and may be formed with a spacing in the second direction Y following the extending direction of the corresponding second regions 12.

The plurality of second low-concentration regions 13B have an upper end on the first main surface 3 side (the second layer 9 side) and a lower end on the second main surface 4 side (the first layer 8 side). The upper end is connected to the corresponding second region 12 within the second layer 9. In this embodiment, the lower end crosses the boundary portion between the first layer 8 and the second layer 9 and is connected to the corresponding first low-concentration region 13A within the first layer 8.

When the first low-concentration region 13A has an upper end positioned within the second layer 9, the lower end may be connected to the first low-concentration region 13A within the second layer 9. This allows the plurality of low-concentration regions 13 to electrically connect the plurality of first regions 11 to the plurality of second regions 12 via the plurality of first low-concentration regions 13A and the plurality of second low-concentration regions 13B.

As such, the plurality of second low-concentration regions 13B have a layout similar to the low-concentration region 13 according to the second example (refer to FIG. 6). The second low-concentration regions 13B may have the first to third layout examples shown in FIGS. 7A to 7C. The plurality of second low-concentration regions 13B may have a layout similar to the low-concentration region 13 according to the fourth example (refer to FIG. 10).

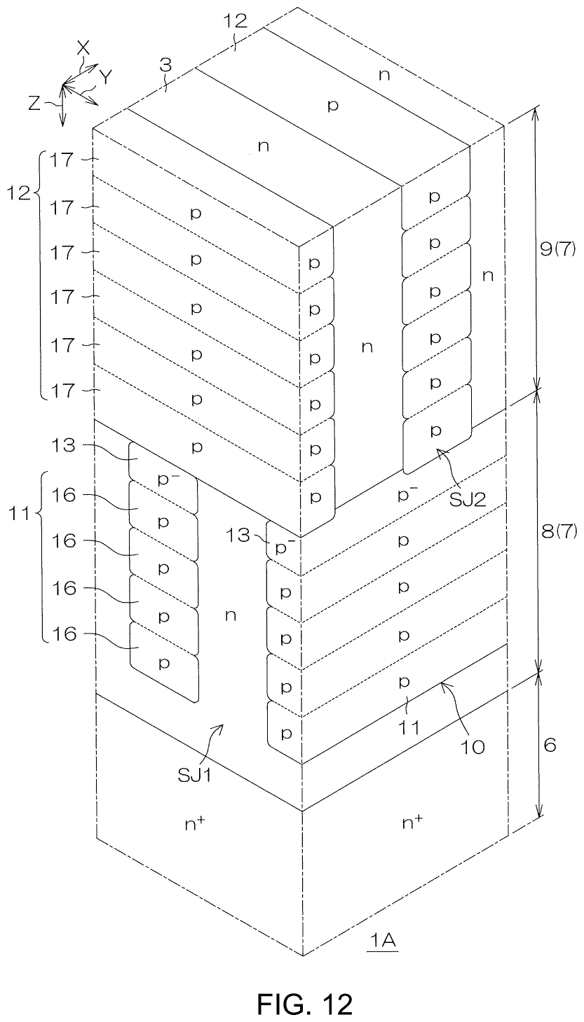

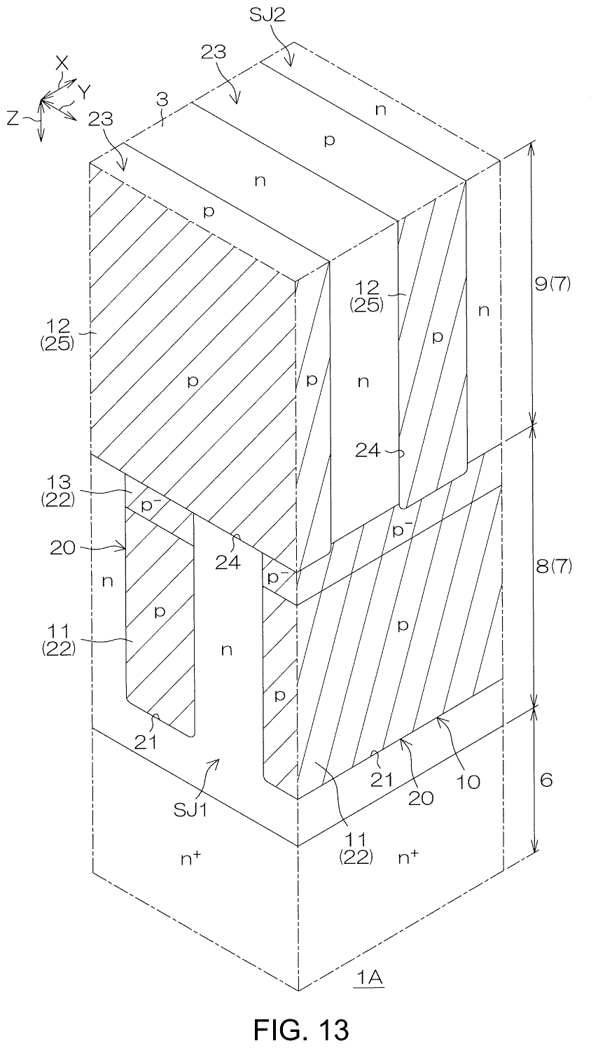

The pillar regions 10 according to the first to fifth examples may have the configurations shown in FIGS. 12 and 13. FIG. 12 is a cross-sectional perspective view showing a first modification example applied to the pillar regions 10 according to the first to fifth examples. FIG. 13 is a cross-sectional perspective view showing a second modification example applied to the pillar regions 10 according to the first to fifth examples.

Referring to FIG. 12 (the first modification example), the plurality of first regions 11 may each include a plurality of p-type first impurity regions 16 disposed in a pillar shape in the thickness direction. The plurality of first impurity regions 16 are disposed to be connected to each other in the thickness direction. The number of first impurity regions 16 may be 2 or more and 10 or less. The number of first impurity regions 16 may be 2, 3, 4, 5, 6, 7, 8, 9, or 10.

Similarly, the plurality of second regions 12 may each include a plurality of p-type second impurity regions 17 disposed in a pillar shape in the thickness direction. The plurality of second impurity regions 17 are disposed to be connected to each other in the thickness direction. The number of second impurity regions 17 may be 2 or more and 10 or less. The number of second impurity regions 17 may be 2, 3, 4, 5, 6, 7, 8, 9, or 10. The number of second impurity regions 17 may be the same as or different from the number of first impurity regions 16.

In this embodiment, the plurality of low-concentration regions 13 are each interposed in regions between the plurality of first impurity regions 16 and the plurality of second impurity regions 17. The plurality of low-concentration regions 13 are disposed within the first layer 8, similar to the low-concentration region 13 according to the first example (refer to FIG. 3), and are each connected to the corresponding first impurity region 16 and the corresponding second impurity region 17.

In this case, the plurality of low-concentration regions 13 may have the first to third layout examples shown in FIGS. 5A to 5C. Of course, the plurality of low-concentration regions 13 may have a layout similar to the low-concentration region 13 according to the third example (refer to FIG. 8).

The plurality of low-concentration regions 13 may be disposed within the second layer 9, similar to the low-concentration region 13 according to the second example (refer to FIG. 6), and may each be connected to the corresponding first impurity region 16 and the corresponding second impurity region 17.

In this case, the plurality of low-concentration regions 13 may have the first to third layout examples shown in FIGS. 7A to 7C. Of course, the plurality of second low-concentration regions 13B may have a layout similar to the low-concentration region 13 according to the fourth example (refer to FIG. 10).

In this embodiment, an example where the plurality of first regions 11 include the plurality of first impurity regions 16 and the plurality of second regions 12 include the plurality of second impurity regions 17 is shown. However, either the plurality of first regions 11 or the plurality of second regions 12 may be formed by a single impurity region.

Referring to FIG. 13 (the second modification example), the semiconductor device 1A includes a plurality of first trench structures 20 formed in the semiconductor layer 7. The plurality of first trench structures 20 are structures that partition the formation portions of the plurality of first regions 11. The plurality of first trench structures 20 are formed within the semiconductor layer 7 with a spacing in the thickness direction from the first main surface 3. Specifically, the plurality of first trench structures 20 extend in a strip shape in the first direction X in the upper end of the first layer 8 and are formed with a spacing in the second direction Y.

The plurality of first trench structures 20 are formed with a spacing in the thickness direction from the lower end of the first layer 8 (the base layer 6) and face the base layer 6 with a portion of the first layer 8 in between. The plurality of first trench structures 20 may cross the boundary portion between the base layer 6 and the first layer 8 and may have a portion positioned in the base layer 6. The spacing, width, and depth of the plurality of first trench structures 20 correspond to the spacing, width, and depth of the plurality of first regions 11 described above, respectively.

The plurality of first trench structures 20 include a first trench 21 and a non-insulating first buried material 22. The first trench 21 is excavated from the upper end of the first layer 8 toward the lower end of the first layer 8 and has sidewalls and a bottom wall that expose the first layer 8. The bottom wall of the first trench 21 may be positioned within the base layer 6 and may expose the base layer 6.

The first buried material 22 includes either or both of a semiconductor single crystal and a semiconductor polycrystal. The first buried material 22 may include at least one of Si single crystal, Si polycrystal, SiC single crystal, and SiC polycrystal. In this embodiment, the first buried material 22 includes a SiC single crystal.

The first buried material 22 is directly buried in the first trench 21 and is in contact with the first layer 8 within the first trench 21. The first buried material 22 may have a flat upper end that forms a flat surface with the upper end of the first layer 8. When the first trench 21 exposes the base layer 6, the first buried material 22 is in contact with the base layer 6 and the first layer 8 within the first trench 21.

The first buried material 22 may be integrated with the first layer 8. The first buried material 22 may be an epitaxial layer grown from the first layer 8 starting from the wall surface of the first trench 21. The first buried material 22 may include a portion grown starting from the base layer 6.

The semiconductor device 1A includes a plurality of second trench structures 23 formed in the semiconductor layer 7. The plurality of trench structures are structures that partition the formation portions of the plurality of second regions 12. The plurality of second trench structures 23 are formed in a region of the first main surface 3 side relative to the plurality of first trench structures 20. Specifically, the plurality of second trench structures 23 each extend in a strip shape in the second direction Y at the upper end of the second layer 9 (the first main surface 3) and are formed with a spacing in the first direction X.

The plurality of second trench structures 23 penetrate the second layer 9 to expose the first layer 8 and the plurality of first trench structures 20. The spacing, width, and depth of the plurality of second trench structures 23 correspond to the spacing, width, and depth of the plurality of second regions 12 described above, respectively.

The plurality of second trench structures 23 include a second trench 24 and a non-insulating second buried material 25. The second trench 24 is excavated from the upper end of the second layer 9 (the first main surface 3) toward the lower end of the second layer 9. The second trench 24 has sidewalls that expose the second layer 9 and a bottom wall that exposes the first layer 8 and the plurality of first trench structures 20.

The second buried material 25 includes either or both of a semiconductor single crystal and a semiconductor polycrystal. The second buried material 25 may include at least one of Si single crystal, Si polycrystal, SiC single crystal, and SiC polycrystal. In this embodiment, the second buried material 25 includes a SiC single crystal.

The second buried material 25 is directly buried in the second trench 24, is in contact with the second layer 9 at the sidewalls of the second trench 24, and is in contact with the second layer 9 and the plurality of first trench structures 20 at the bottom wall of the second trench 24. The second buried material 25 may have a flat upper end that forms a flat surface with the upper end of the second layer 9.

The second buried material 25 may be integrated with the first layer 8 and the second layer 9. The second buried material 25 may be an epitaxial layer grown from the first layer 8 and the second layer 9 starting from the wall surface of the second trench 24. The second buried material 25 may include a portion grown starting from the first buried material 22.

In this embodiment, the plurality of first regions 11 are each formed in the plurality of first trench structures 20. Specifically, the plurality of first regions 11 are each formed in the plurality of first buried materials 22. That is, each of the plurality of first regions 11 is formed of a region where a p-type conductivity is given to the first buried material 22 by a trivalent element. The plurality of first regions 11 may have a uniform p-type impurity concentration. The plurality of first regions 11 may have a concentration gradient that decreases from the opening side of the first trench 21 toward the bottom wall side.

The plurality of first regions 11 form the first pn junction portion with the first layer 8 via the sidewalls and bottom wall of the corresponding first trench 21. When the base layer 6 is exposed from the bottom wall of the first trench 21, the plurality of first regions 11 may be electrically connected to the base layer 6 at the bottom wall of the corresponding first trench 21. The plurality of first regions 11 are formed with a spacing from the upper end of the corresponding first buried material 22 toward the bottom wall side of the first trench 21.

In this embodiment, the plurality of second regions 12 are each formed in the plurality of second trench structures 23. Specifically, the plurality of second regions 12 are each formed in the plurality of second buried materials 25. That is, each of the plurality of second regions 12 is formed of a region where a p-type conductivity is given to the second buried material 25 by a trivalent element. The plurality of second regions 12 may have a uniform p-type impurity concentration. The plurality of second regions 12 may have a concentration gradient that decreases from the opening side of the second trench 24 toward the bottom wall side.

The plurality of second regions 12 form the second pn junction portion with the first layer 8 and the second layer 9 via the sidewalls and bottom wall of the corresponding second trench 24. The plurality of second regions 12 are electrically connected to the plurality of first buried materials 22 (the plurality of first regions 11) via the bottom wall of the corresponding second trench 24. The plurality of second regions 12 may be formed over the entire area of the plurality of second buried materials 25. The plurality of second regions 12 may be formed with a spacing from the upper end of the plurality of second buried materials 25 toward the bottom wall side of the second trench 24.

In this embodiment, the plurality of low-concentration regions 13 are each formed in the plurality of first trench structures 20. Specifically, the plurality of low-concentration regions 13 are each formed in the corresponding first buried materials 22. That is, each of the plurality of low-concentration regions 13 is formed of a region where a p-type conductivity is given to the first buried material 22 by a trivalent element.

The plurality of low-concentration regions 13 are formed at the upper ends of a plurality of first buried materials 22, respectively. The plurality of low-concentration regions 13 may be formed with a spacing from the depth position of the middle portion of the corresponding first trench 21 toward the opening side of the corresponding first trench 21. The plurality of low-concentration regions 13 have an upper end on the first main surface 3 side and a lower end on the second main surface 4 side.

The upper end is electrically connected to the second region 12 within the first trench 21. The lower end is electrically connected to the first region 11 within the first trench 21. As a result, the plurality of first regions 11 are electrically connected to the corresponding second regions 12 within the corresponding first trenches 21.

The plurality of low-concentration regions 13 may be formed in a plurality of second trench structures 23, respectively. That is, the plurality of low-concentration regions 13 may be formed in the corresponding second buried materials 25, respectively. In this case, each of the plurality of low-concentration regions 13 is formed of a region where a p-type conductivity is given to the second buried material 25 by a trivalent element.

The plurality of low-concentration regions 13 may be formed at the lower ends of the corresponding second buried materials 25. The plurality of low-concentration regions 13 may be formed with a spacing from the depth position of the middle portion of the corresponding second trench 24 toward the bottom wall side of the corresponding second trench 24. The plurality of low-concentration regions 13 may have an upper end on the first main surface 3 side and a lower end on the second main surface 4 side.

The upper end may be electrically connected to the second region 12 within the second trench 24. The lower end may be electrically connected to the first region 11 within the second trench 24. As a result, the plurality of low-concentration regions 13 electrically connect the corresponding first region 11 to the corresponding second region 12 within the corresponding second trench 24.

In this embodiment, an example where the plurality of first regions 11 are formed in the plurality of first trench structures 20 and the plurality of second regions 12 are formed in the plurality of second trench structures 23 is shown. However, a configuration where either the plurality of first trench structures 20 or the plurality of second trench structures 23 is not formed may be adopted.

That is, it may be that while the plurality of first regions 11 are formed in the first layer 8, the plurality of second regions 12 are formed in the plurality of second trench structures 23. Additionally, it may be that while the plurality of first regions 11 are formed in the plurality of first trench structures 20, the plurality of second regions 12 are formed in the second layer 9.

The configuration where the plurality of first regions 11 are formed in the plurality of first trench structures 20 can be combined with all the above-mentioned configurations (refer to FIGS. 1 to 12). Additionally, the configuration where the plurality of second regions 12 are formed in the plurality of second trench structures 23 can be combined with all the above-mentioned configurations (refer to FIGS. 1 to 12).

As described above, the semiconductor device 1A may include the n-type semiconductor layer 7, the p-type first region 11, the p-type second region 12, and the p-type low-concentration region 13. The semiconductor layer 7 may have the first main surface 3. The first region 11 may extend in the first direction X along the first main surface 3 within the semiconductor layer 7. The second region 12 may be formed in the semiconductor layer 7 in a region of the first main surface 3 side relative to the first region 11.

The second region 12 may extend in the second direction Y along the first main surface 3 so as to intersect the first region 11 three-dimensionally. The low-concentration region 13 may be formed at least at the intersection portion of the first region 11 and the second region 12 within the semiconductor layer 7. The low-concentration region 13 may have a concentration lower than both the maximum concentration of the first region 11 and the maximum concentration of the second region 12.

According to this configuration, a novel semiconductor device 1A is provided. For example, in this semiconductor device 1A, the increase in concentration at the intersection portion of the first region 11 and the second region 12 is suppressed by the low-concentration region 13, and the electric field concentration at that intersection portion is alleviated by the low-concentration region 13. This improves electrical reliability due to enhanced withstand voltage.

The semiconductor layer 7 may include SiC. According to this configuration, the semiconductor device 1A is provided as a novel SiC semiconductor device. According to this semiconductor device 1A, the electrical characteristics are appropriately enhanced by the physical properties of SiC. In particular, in the case of SiC semiconductor devices, since they are used in relatively high voltage environments, the electric field relaxation effect due to the low-concentration region 13 is effective in improving the electrical characteristics.

SiC may be hexagonal. The first direction X may be one of the a-axis direction and m-axis direction of SiC. The second direction Y may be the other of the a-axis direction and m-axis direction of SiC. The first direction X may be a direction that intersects both the a-axis direction and m-axis direction. The second direction Y may be a direction that intersects both the a-axis direction and m-axis direction. The semiconductor layer 7 may have an off-angle. The second direction Y may be orthogonal to the first direction X.

The concentration of the low-concentration region 13 may be lower than both the concentration of the depth position of the middle portion of the first region 11 and the concentration of the depth position of the middle portion of the second region 12. According to this configuration, the increase in concentration at the intersection portion is appropriately suppressed by the low-concentration region 13.

The low-concentration region 13 may form a first concentration transition portion 14 where the concentration gradually decreases from the first region 11 at the intersection portion. According to this configuration, the increase in concentration at the intersection portion caused by the concentration of the first region 11 is appropriately suppressed by the low-concentration region 13. The low-concentration region 13 may form a second concentration transition portion 15 where the concentration gradually increases toward the second region 12. According to this configuration, the increase in concentration at the intersection portion caused by the concentration of the second region 12 is appropriately suppressed by the low-concentration region 13.

The low-concentration region 13 may also be formed in regions other than the intersection portion. According to this configuration, the low-concentration region 13 is appropriately overlapped by the intersection portion. This provides the low-concentration region 13 that is resistant to misalignment with respect to the intersection portion.

The low-concentration region 13 may have a portion extending in the first direction X following the first region 11. According to this configuration, the increase in concentration at the intersection portion is appropriately suppressed by the low-concentration region 13 extending along the first region 11. The low-concentration region 13 may have a portion extending in the second direction Y following the second region 12. According to this configuration, the increase in concentration at the intersection portion is appropriately suppressed by the low-concentration region 13 extending along the second region 12.

The first region 11 may extend longitudinally in the thickness direction of the semiconductor layer 7. The second region 12 may extend longitudinally in the thickness direction of the semiconductor layer 7. The first region 11 may have a width of 10 μm or less. The second region 12 may have a width of 10 μm or less.

The plurality of first regions 11 may be formed in a stripe shape extending in the first direction X. The plurality of second regions 12 may be formed in a stripe shape extending in the second direction Y to intersect the plurality of first regions 11. The plurality of low-concentration regions 13 may be formed at the plurality of intersection portions.

The plurality of first regions 11 may form a first super junction structure SJ1 with the semiconductor layer 7. In this case, the electric field concentration at the first super junction structure SJ1 is alleviated by the low-concentration region 13. This improves the electrical characteristics of the first super junction structure SJ1.

The plurality of second regions 12 may form a second super junction structure SJ2 with the semiconductor layer 7. In this case, the electric field concentration at the second super junction structure SJ2 is alleviated by the low-concentration region 13. This improves the electrical characteristics of the second super junction structure SJ2.

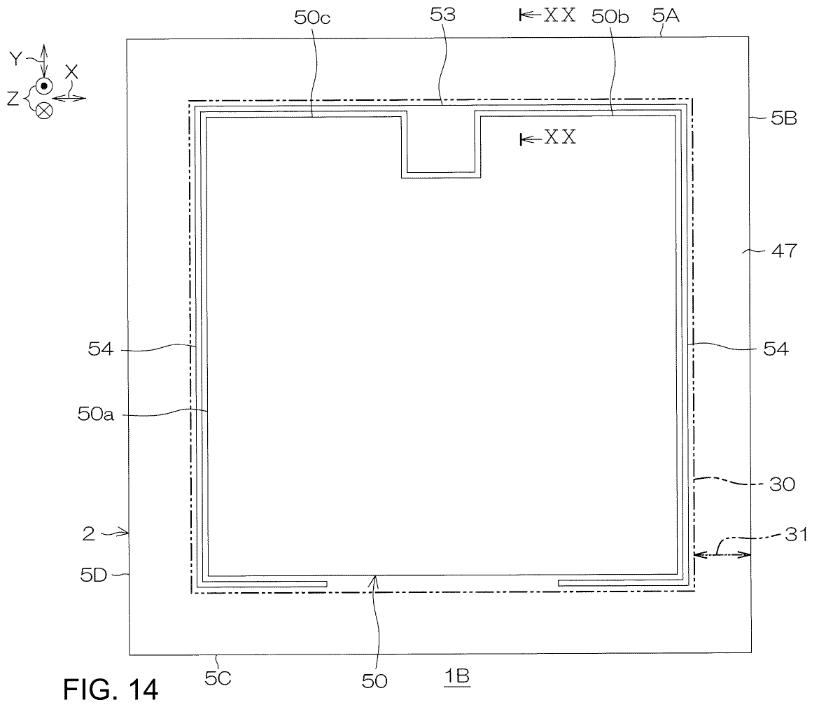

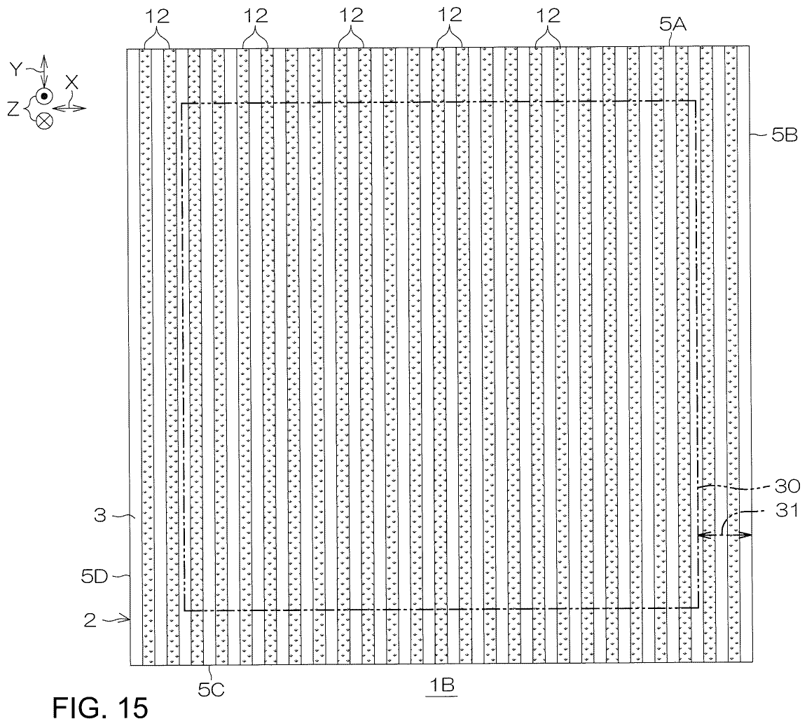

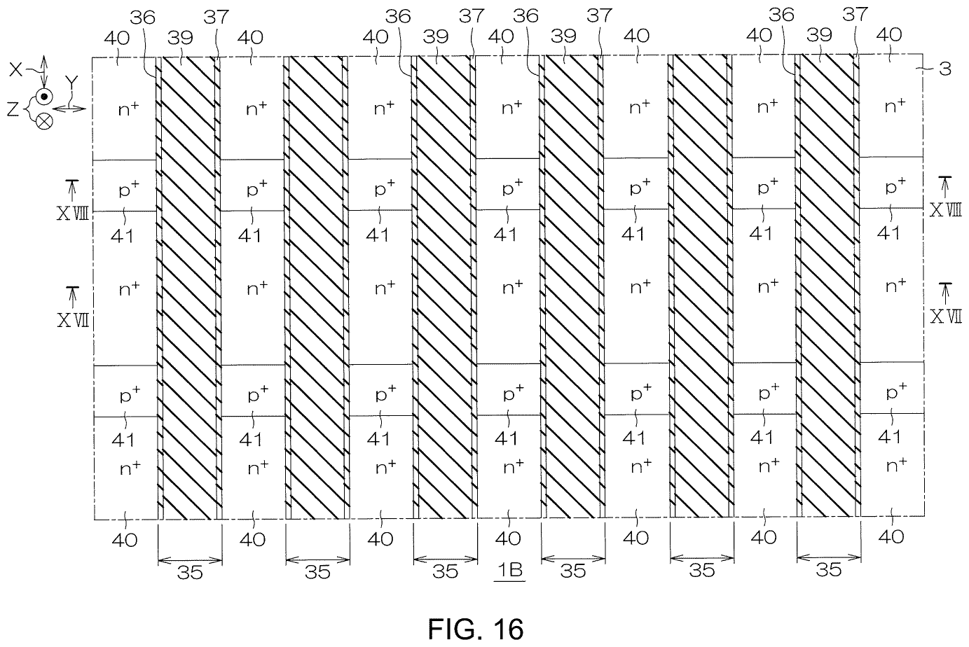

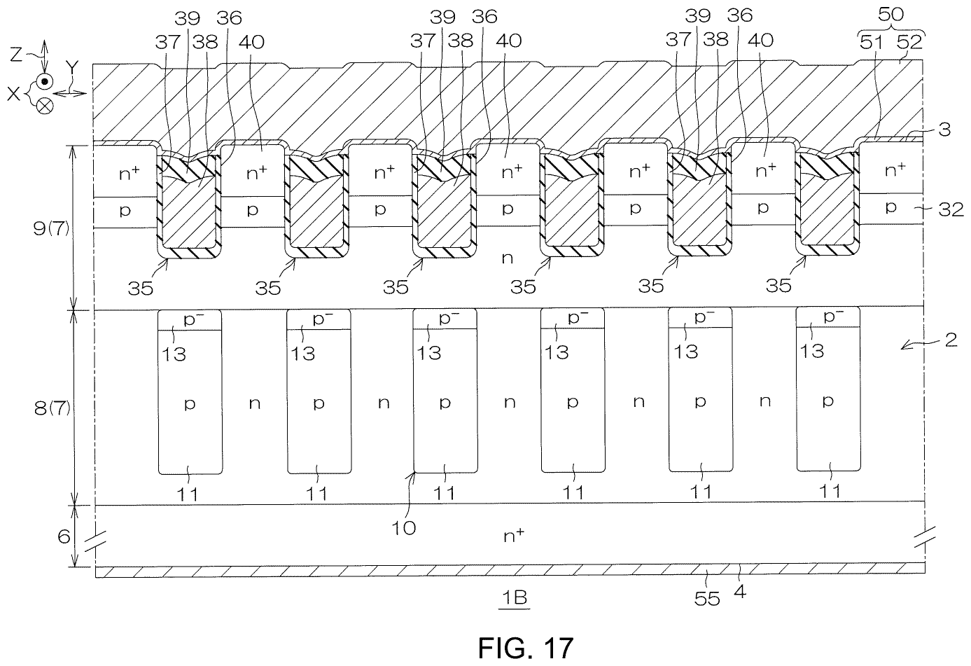

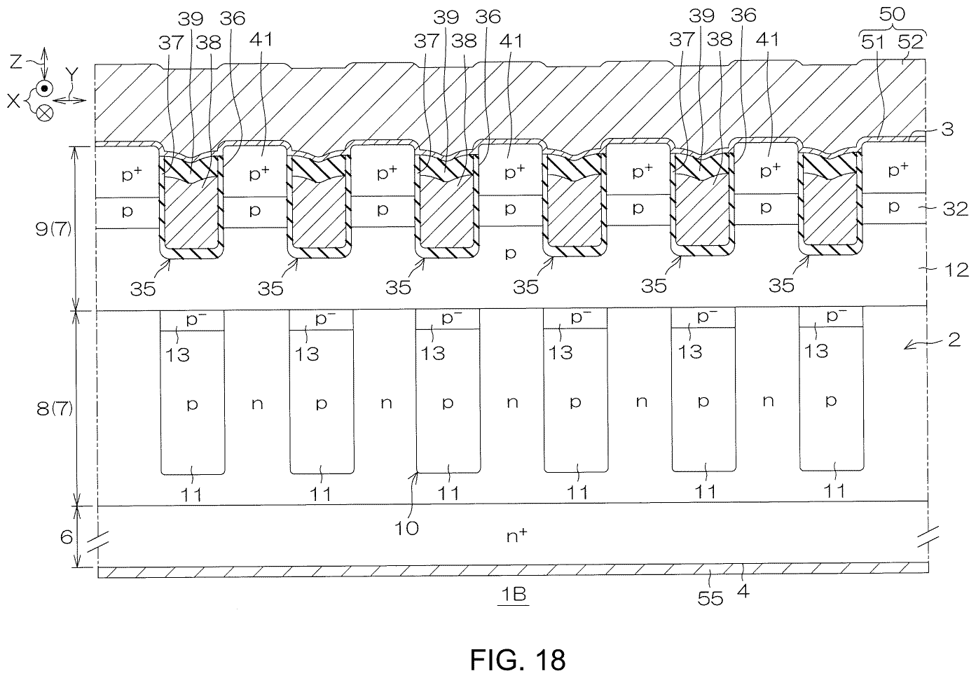

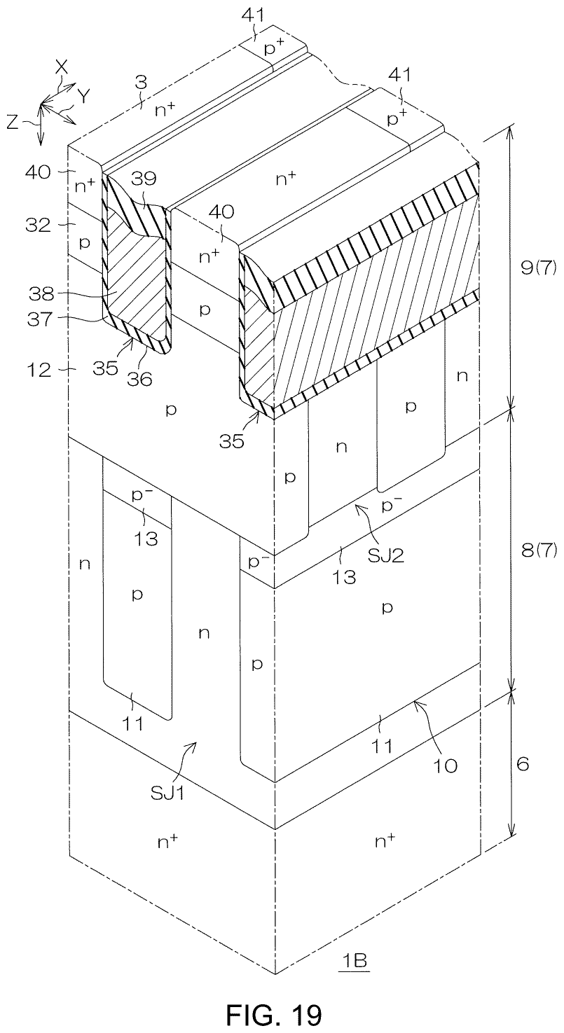

FIG. 14 is a plan view showing a semiconductor device 1B according to a second embodiment. FIG. 15 is a plan view showing a layout example of the first main surface 3. FIG. 16 is an enlarged plan view showing a main part of an active region 30. FIG. 17 is a cross-sectional view along a line XVII-XVII shown in FIG. 16. FIG. 18 is a cross-sectional view along a line XVIII-XVIII shown in FIG. 16. FIG. 19 is a cross-sectional perspective view showing a main part of the active region 30 along with the pillar region 10 according to the first example.

Referring to FIGS. 14 to 19, the semiconductor device 1B is a semiconductor switching device that has an insulated gate type transistor structure as an example of a device structure (functional device). The transistor structure has a trench gate type vertical structure.

The semiconductor device 1B has the chip 2 and the pillar region 10 according to the semiconductor device 1A as its basic form. In this embodiment, the semiconductor device 1B has a pillar region 10 according to the first embodiment example (refer to FIG. 3 and FIGS. 5A to 5C).

The semiconductor device 1B may have any one of the pillar regions 10 according to the second to fifth embodiments (refer to FIGS. 6 to 10). Additionally, the semiconductor device 1B may have the pillar region 10 according to the first modification example (refer to FIG. 11) or the pillar region 10 according to the second modification example (refer to FIG. 12).

The semiconductor device 1B includes an active region 30 set on the first main surface 3. The active region 30 includes a device structure (transistor structure) and is the area where output current (drain current) is generated. The active region 30 is set in an inner portion of the first main surface 3 and with a spacing from the periphery of the first main surface 3 (the first to fourth side surfaces 5A to 5D). The active region 30 is set to a polygonal shape (a quadrilateral shape in this embodiment) having four sides parallel to the periphery of the first main surface 3 in the plan view.

The ratio (area ratio) of the planar area of the active region 30 to the planar area of the first main surface 3 may be 0.5 or more and less than 1. The area ratio may have a value that falls within at least one of the ranges of 0.5 or more and 0.6 or less, 0.6 or more and 0.7 or less, 0.7 or more and 0.8 or less, 0.8 or more and 0.9 or less, 0.9 or more and 0.95 or less, and 0.95 or more and less than 1.

The semiconductor device 1B includes an outer region 31 set outside the active region 30 on the first main surface 3. The outer region 31 is a region that does not include a device structure (transistor structure). The outer region 31 is set at the peripheral portion of the first main surface 3. The outer region 31 is provided in a region between the periphery of the first main surface 3 and the active region 30. The outer region 31 extends in a strip shape along the active region 30 in the plan view, and is set in a polygonal ring shape (a quadrilateral ring shape in this embodiment) surrounding the active region 30.

The semiconductor device 1B includes a p-type body region 32 formed in the surface layer portion of the first main surface 3 within the active region 30. The body region 32 may have a source potential applied to it. The source potential may serve as a reference potential for circuit operation. The reference potential may be a ground potential.

The body region 32 may have a higher p-type impurity concentration than the p-type impurity concentration of the first region 11 (the second region 12). The p-type impurity concentration of the body region 32 may be lower than the p-type impurity concentration of the first region 11 (the second region 12).

The body region 32 is formed in the active region 30 with a spacing from the periphery of the first main surface 3 (the first to fourth side surfaces 5A to 5D), and is not formed in the outer region 31. In this embodiment, the body region 32 is formed over the entire area of the active region 30. The body region 32 is formed in the surface layer portion of the second layer 9 and extends in a layer form along the first main surface 3. The body region 32 may be connected to the plurality of second regions 12. In this case, the p-type impurity concentration of the body region 32 is increased by the plurality of second regions 12.

The body region 32 is formed with a spacing from the lower end of the second layer 9 (the first layer 8) toward the first main surface 3 side, and has a portion that face the first layer 8 and the plurality of first regions 11 with a portion of the second layer 9 in between. The body region 32 is formed with a spacing from the lower end of the second region 12 toward the first main surface 3 side. The body region 32 may be formed with a spacing from the depth position of the middle portion of the second layer 9 toward the first main surface 3 side. The body region 32 may have a portion positioned on the first layer 8 side relative to the depth position of the middle portion of the second layer 9.

The semiconductor device 1B includes a plurality of gate structures 35, which are trench-type (trench electrode type), formed in the inner portion of the first main surface 3. The gate structures 35 may be referred to as “first trench structures,” “trench gate structures,” etc. A gate potential (gate signal) is applied to the plurality of gate structures 35 as a control potential.

The plurality of gate structures 35 are formed in the active region 30 with a spacing from the periphery of the first main surface 3, and are not formed in the outer region 31. In this embodiment, the plurality of gate structures 35 each extend in a strip shape in the first direction X in the plan view and are arranged with a spacing in the second direction Y. The plurality of gate structures 35 are arranged in a stripe shape extending in the first direction X.

In this embodiment, the plurality of gate structures 35 extend in the same direction as the extending direction of the plurality of first regions 11 and in a different direction from the extending direction of the plurality of second regions 12. The plurality of gate structures 35 intersect (specifically, orthogonally) the plurality of second regions 12. This layout is effective in alleviating the restrictions of the design rules for the plurality of gate structures 35 with respect to the plurality of second regions 12.

In this embodiment, the plurality of gate structures 35 are arranged with a spacing substantially equal to the spacing of the plurality of first regions 11, overlapping the plurality of first regions 11 in a one-to-one correspondence in the laminating direction. The spacing of the plurality of gate structures 35 may differ from the spacing of the plurality of first regions 11.

In this case, the plurality of gate structures 35 may include gate structures 35 that face the first region 11 in the laminating direction and gate structures 35 that do not face the first region 11 in the laminating direction. All gate structures 35 may face regions between the plurality of first regions 11 in the laminating direction (that is, the first layer 8).

The spacing of the plurality of gate structures 35 may be greater than 0 μm and less than or equal to 10 μm. The spacing of the gate structures 35 may be less than the width of the gate structures 35. The spacing of the gate structures 35 may be greater than the width of the gate. The spacing of the gate structures 35 may be substantially equal to the spacing of the second regions 12. The spacing of the gate structures 35 may be either greater than or less than the spacing of the second regions 12.

The spacing of the gate structures 35 may have a value that falls within at least one of the ranges of greater than 0 μm and less than or equal to 0.5 μm, 0.5 μm or more and 1 μm or less, 1 μm or more and 2 μm or less, 2 μm or more and 3 μm or less, 3 μm or more and 4 μm or less, 4 μm or more and 5 μm or less, 5 μm or more and 6 μm or less, 6 μm or more and 7 μm or less, 7 μm or more and 8 μm or less, 8 μm or more and 9 μm or less, and 9 μm or more and 10 μm or less.

The plurality of gate structures 35 penetrate through the body region 32. The plurality of gate structures 35 each have sidewalls and a bottom wall connected to the plurality of second regions 12. The plurality of gate structures 35 are formed with a spacing from the bottom portion of the second layer 9 toward the first main surface 3 side and face the first layer 8 with a portion of the second layer 9 in between. The plurality of gate structures 35 are formed with a spacing from the lower end of the plurality of second regions 12 toward the first main surface 3 side and face the first layer 8 with a portion of the plurality of second regions 12 in between.

The plurality of gate structures 35 are formed substantially vertical to the first main surface 3. The plurality of gate structures 35 may be formed in a tapered shape toward the bottom portion of the second layer 9. The sidewalls (long sides) of the plurality of gate structures 35 are formed of the m-plane ((1-100) plane) of the SiC single crystal. The sidewalls (long sides) of the plurality of gate structures 35 may be formed of the a-plane ((11-20) plane) of the SiC single crystal, depending on the extending direction of the gate structure 35.

The sidewalls of the plurality of gate structures 35, along with the first main surface 3, partition an opening end that is curved in an arc shape (circular arc shape). The bottom walls of the plurality of gate structures 35 are formed of the c-plane (Si plane) of the SiC single crystal. It is preferable that the bottom walls of the plurality of gate structures 35 extend substantially flat in the horizontal direction. The bottom walls of the plurality of gate structures 35 may be curved in an arc shape toward the second main surface 4 side.

The inclination angle (absolute value) of the sidewalls (long sides) of the gate structure 35 with respect to the vertical line may be 85° or more and 95° or less. The inclination angle may have a value that falls within at least one of the ranges of 85° or more and 87.5° or less, 87.5° or more and 90° or less, 90° or more and 92.5° or less, and 92.5° or more and 95° or less. It is preferable that the inclination angle is 87° or more and 93° or less.

The gate structure 35 may have a width greater than 0 μm and less than or equal to 10 μm. The width of the gate structure 35 may be less than the thickness of the second layer 9. The width of the gate structure 35 may be greater than the thickness of the second layer 9. The width of the gate structure 35 may be substantially equal to the width of the second region 12. The width of the gate structure 35 may be either greater than or less than the width of the second region 12. The width of the gate structure 35 may be substantially equal to the width of the first region 11. The width of the gate structure 35 may be either greater than or less than the width of the first region 11.

The width of the gate structure 35 may have a value that falls within at least one of the ranges of greater than 0 μm and less than or equal to 0.5 μm, 0.5 μm or more and 1 μm or less, 1 μm or more and 2 μm or less, 2 μm or more and 3 μm or less, 3 μm or more and 4 μm or less, 4 μm or more and 5 μm or less, 5 μm or more and 6 μm or less, 6 μm or more and 7 μm or less, 7 μm or more and 8 μm or less, 8 μm or more and 9 μm or less, and 9 μm or more and 10 μm or less. It is preferable that the width of the gate structure 35 is less than or equal to 5 μm.

The gate structure 35 may have a depth greater than 0 μm and less than or equal to 3 μm. The depth of the gate structure 35 is less than the thickness of the second layer 9. The depth of the gate structure 35 is less than the depth of the second region 12. The depth of the gate structure 35 is less than the depth of the first region 11. The depth of the gate structure 35 may be either greater than or less than the depth of the first region 11.

The depth of the gate structure 35 may have a value that falls within at least one of the ranges of greater than 0 μm and less than or equal to 0.25 μm, 0.25 μm or more and 0.5 μm or less, 0.5 μm or more and 0.75 μm or less, 0.75 μm or more and 1 μm or less, 1 μm or more and 1.25 μm or less, 1.25 μm or more and 1.5 μm or less, 1.5 μm or more and 1.75 μm or less, 1.75 μm or more and 2 μm or less, 2 μm or more and 2.25 μm or less, 2.25 μm or more and 2.5 μm or less, 2.5 μm or more and 2.75 μm or less, and 2.75 μm or more and 3 μm or less.

The gate structure 35 may have an aspect ratio of 1 or more and 3 or less. The aspect ratio of the gate structure 35 is the ratio of the depth of the gate structure 35 to the width of the gate structure 35. The aspect ratio may have a value that falls within at least one of the ranges of 1 or more and 1.5 or less, 1.5 or more and 2 or less, 2 or more and 2.5 or less, and 2.5 or more and 3 or less.

The plurality of gate structures 35 each include a gate trench 36, an insulating film 37, a buried electrode 38, and a buried insulator 39. The gate trench 36 is formed on the first main surface 3 and partitions the wall surfaces (sidewalls and bottom wall) of the gate structure 35.

The insulating film 37 may include at least one of a silicon oxide film, a silicon nitride film, and a silicon oxynitride film. The insulating film 37 may include a silicon oxide film that includes an oxide of the chip 2 (the second layer 9). The insulating film 37 may include a silicon oxide film that includes an oxide other than that of the chip 2.

The insulating film 37 covers the wall surfaces of the gate trench 36. In this embodiment, the insulating film 37 has an upper end positioned on the bottom wall side of the gate trench 36 relative to the height position of the first main surface 3 and exposes a portion of the chip 2 from the wall surface at the opening end of the gate trench 36.

It is preferable for the upper end of the insulating film 37 to be positioned on the opening side of the gate trench 36 relative to the depth position of the middle portion of the gate trench 36. The thickness of the portion of the insulating film 37 that covers the sidewalls of the gate trench 36 may be greater than the thickness of the portion that covers the bottom wall of the gate trench 36.

The thickness of the insulating film 37 may be 10 nm or more and 250 nm or less. The thickness of the insulating film 37 may have a value that falls within at least one of the ranges of 10 nm or more and 25 nm or less, 25 nm or more and 50 nm or less, 50 nm or more and 75 nm or less, 75 nm or more and 100 nm or less, 100 nm or more and 125 nm or less, 125 nm or more and 150 nm or less, 150 nm or more and 175 nm or less, 175 nm or more and 200 nm or less, 200 nm or more and 225 nm or less, and 225 nm or more and 250 nm or less.

The buried electrode 38 may include either or both of a metallic and a non-metallic conductor. The buried electrode 38 may include conductive polysilicon as an example of a non-metallic conductor. In this case, the buried electrode 38 may include either or both of p-type conductive polysilicon and n-type conductive polysilicon. It is preferable for the buried electrode 38 to be formed of n-type conductive polysilicon.

The buried electrode 38 is buried in the gate trench 36 via the insulating film 37 and faces the second layer 9, the plurality of second regions 12, and the body region 32 via the insulating film 37. The buried electrode 38 has an electrode surface exposed from the gate trench 36. The electrode surface is formed with a spacing from the height position of the first main surface 3 toward the bottom wall side of the gate trench 36.

The electrode surface is positioned on the first main surface 3 side relative to the depth position of the middle portion of the gate trench 36. The electrode surface may be positioned on the bottom wall side of the gate trench 36 relative to the depth position of the middle portion of the gate trench 36. The electrode surface may have a recess that is concave toward the bottom wall side of the gate trench 36.

The buried insulator 39 may include at least one of a silicon oxide film, a silicon nitride film, and a silicon oxynitride film. The buried insulator 39 may include the same or a different type of insulating material from the insulating material of the insulating film 37. In this embodiment, the buried insulator 39 includes a silicon oxide film that has properties different from the properties of the insulating film 37.

The buried insulator 39 may have a single-layer structure or a laminated structure that includes at least one of an NSG film (Nondoped Silicate Glass film), a PSG film (Phosphorus Silicon Glass film), and a BPSG film (Boron Phosphorus Silicon Glass film). The NSG film is a silicon oxide film without added impurities, the PSG film is a silicon oxide film containing phosphorus, and the BPSG film is a silicon oxide film containing both phosphorus and boron.

It is preferable for the buried insulator 39 to have a single-layer structure or a laminated structure that includes at least an NSG film. The buried insulator 39 may have a laminated structure that includes an NSG film and a PSG film laminated in this order from the chip 2 side. The buried insulator 39 may have a laminated structure that includes an NSG film, a PSG film, and a BPSG film laminated in this order from the chip 2 side. The buried insulator 39 may have a single-layer structure or a laminated structure that includes a silicon oxide film including an oxide of the buried electrode 38.

The buried insulator 39 covers the buried electrode 38 within the gate trench 36. In this embodiment, the buried insulator 39 is buried in the gate trench 36 via the insulating film 37 and is in contact with the insulating film 37 and the buried electrode 38 within the gate trench 36. That is, the buried insulator 39 has a portion that faces the chip 2 in the horizontal direction via the insulating film 37.

The buried insulator 39 has an insulating surface exposed from the gate trench 36. The insulating surface is formed with a spacing from a height position of the first main surface 3 to the bottom wall side of the gate trench 36 and exposes a portion of the chip 2 from the opening end of the gate trench 36. The insulating surface is positioned on the opening side of the gate trench 36 relative to the depth position of the middle portion of the gate trench 36. The insulating surface may be positioned on the bottom wall side of the gate trench 36 relative to the depth position of the middle portion of the gate trench 36.

The insulating surface exposes the upper end of the insulating film 37. In this embodiment, the insulating surface is flatly continuous with the upper end of the insulating film 37. That is, the insulating surface is formed flush with the upper end of the insulating film 37. The insulating surface may be positioned closer to the first main surface 3 side or the bottom wall side of the gate trench 36 than the upper end of the insulating film 37.

The insulating surface may be formed flush with the first main surface 3 along with the upper end of the insulating film 37. The buried insulator 39 may cover the upper end of the insulating film 37 and be in direct contact with the chip 2 at the sidewall of the gate trench 36. In this embodiment, the insulating surface has a recessed portion that is sunk from the sidewall of the gate trench 36 toward the inside of the gate trench 36. The insulating surface may have a raised portion rising from the sidewall of the gate trench 36 toward the inside of the gate trench 36.

In this embodiment, the buried insulator 39 has a thickness greater than the thickness of the insulating film 37. It is preferable that the thickness of the buried insulator 39 is less than the thickness of the buried electrode 38. The ratio of the thickness of the buried insulator 39 to the depth of the gate trench 36 may be greater than 0 and less than or equal to 0.5. The thickness ratio may have a value that falls within at least one of the ranges of greater than 0 and less than or equal to 0.1, 0.1 or more and 0.2 or less, 0.2 or more and 0.3 or less, 0.3 or more and 0.4 or less, and 0.4 or more and 0.5 or less.

The semiconductor device 1B includes a plurality of n-type source regions 40 formed in the surface layer portion of the first main surface 3 within the active region 30. The source regions 40 have an n-type impurity concentration higher than the n-type impurity concentration of the second layer 9 (the first layer 8). The n-type impurity concentration of the source regions 40 is higher than the p-type impurity concentration of the body region 32.

The plurality of source regions 40 are each formed in regions between the plurality of gate structures 35 in the surface layer portion of the body region 32. The plurality of source regions 40 are formed with a spacing in the first direction X following the extending direction of the plurality of gate structures 35, and are adjacent to two corresponding gate structures 35 in the second direction Y.

In this embodiment, the plurality of source regions 40 extend in a strip shape in the first direction X following the extending direction of the corresponding plurality of gate structures 35. The plurality of source regions 40 may intersect one or more second regions 12. With respect to the first direction X, the length of the source regions 40 is greater than the spacing between the plurality of gate structures 35.

With respect to the plurality of source regions 40 on one side and the other side formed on both sides of the plurality of gate structures 35, the plurality of source regions 40 on the other side face the plurality of source regions 40 on the one side in the second direction Y. The plurality of source regions 40 on the other side may face a region between the plurality of source regions 40 on one side in the second direction Y.

The plurality of source regions 40 are formed with a spacing from the bottom portion of the body region 32 toward the first main surface 3 side and face the second layer 9 via a portion of the body region 32. The plurality of source regions 40 are formed with a spacing from a depth position of the middle portion of the plurality of gate structures 35 toward the first main surface 3 side. The plurality of source regions 40 may have a portion positioned on the bottom wall side of the plurality of gate structures 35 relative to the depth position of the middle portion of the plurality of gate structures 35.

In this embodiment, the plurality of source regions 40 have a portion positioned on the first main surface 3 side relative to the electrode surface of the buried electrode 38, and a portion positioned on the bottom wall side of the gate structure 35 relative to the electrode surface of the buried electrode 38. The plurality of source regions 40 have a portion positioned on the first main surface 3 side relative to the insulating surface of the buried insulator 39, and a portion positioned on the bottom wall side of the gate structure 35 relative to the insulating surface of the buried insulator 39.

The plurality of source regions 40 have a portion facing the corresponding buried electrode 38 and a portion facing the corresponding buried insulator 39 in the horizontal direction. The plurality of source regions 40 face the corresponding buried electrode 38 and the corresponding buried insulator 39 via the corresponding insulating film 37. In this embodiment, the plurality of source regions 40 have a portion exposed from the opening end of the gate trench 36.

The depth of the plurality of source regions 40 is greater than the thickness between the bottom portion of the body region 32 and the bottom portion of the plurality of source regions 40. The depth of the plurality of source regions 40 may be less than the thickness between the bottom portion of the body region 32 and the bottom portion of the plurality of source regions 40.

The plurality of source regions 40 partition a channel that serves as a current path along with the second layer 9 in a region on the bottom portion side of the body region 32. The channel may have a channel length greater than 0 nm and less than or equal to 500 nm. The channel length is the distance between the bottom portion of the body region 32 and the bottom portion of the source region 40.

The channel length may have a value that falls within at least one of the ranges of greater than 0 nm and less than or equal to 50 nm, 50 nm or more and 100 nm or less, 100 nm or more and 150 nm or less, 150 nm or more and 200 nm or less, 200 nm or more and 250 nm or less, 250 nm or more and 300 nm or less, 300 nm or more and 350 nm or less, 350 nm or more and 400 nm or less, 400 nm or more and 450 nm or less, and 450 nm or more and 500 nm or less. It is preferable for the channel length to be 300 nm or less.

The semiconductor device 1B includes a plurality of p-type contact regions 41 formed in the surface layer portion of the first main surface 3 in the active region 30. The contact regions 41 have a p-type impurity concentration higher than the p-type impurity concentration of the second region 12 (the first region 11). The p-type impurity concentration of the contact regions 41 is higher than the p-type impurity concentration of the body region 32. The p-type impurity concentration of the contact regions 41 may be either higher or lower than the n-type impurity concentration of the source region 40.

The plurality of contact regions 41 are each formed in a region between the plurality of gate structures 35 in the surface layer portion of the body region 32, and increase the p-type impurity concentration of the body region 32. The plurality of contact regions 41 extend in a layered form along the first main surface 3. The plurality of contact regions 41 are formed with a spacing in the first direction X following the extending direction of the plurality of gate structures 35 and are adjacent to two corresponding gate structures 35 in the second direction Y. The plurality of contact regions 41 may intersect one or more second regions 12.

The plurality of contact regions 41 are each interposed in regions between the plurality of source regions 40 with respect to the first direction X. The plurality of contact regions 41 may be connected to the plurality of source regions 40 in the first direction X. The plurality of contact regions 41 are formed with a spacing from the plurality of source regions 40 in the first direction X and may face the plurality of source regions 40 via a portion of the body region 32.

With respect to the plurality of contact regions 41 formed on one side and the other side of the plurality of gate structures 35, the plurality of contact regions 41 on the other side face the plurality of contact regions 41 on one side in the second direction Y. The plurality of contact regions 41 on the other side may face a region between the plurality of contact regions 41 (the plurality of source regions 40) on one side in the second direction Y.

The plurality of contact regions 41 are formed with a spacing from the bottom portion of the body region 32 toward the first main surface 3 side and face the second layer 9 via a portion of the body region 32. The plurality of contact regions 41 are formed with a spacing from the depth position of the middle portion of the plurality of gate structures 35 toward the first main surface 3 side. The plurality of contact regions 41 may have a portion positioned on the bottom wall side of the plurality of gate structures 35 with respect to the depth position of the middle portion of the plurality of gate structures 35.

In this embodiment, the plurality of contact regions 41 have a portion positioned on the first main surface 3 side with respect to the electrode surface of the buried electrode 38, and a portion positioned on the bottom wall side of the gate structure 35 with respect to the electrode surface of the buried electrode 38. The plurality of contact regions 41 have a portion positioned on the first main surface 3 side with respect to the insulating surface of the buried insulator 39, and a portion positioned on the bottom wall side of the gate structure 35 with respect to the insulating surface of the buried insulator 39.

The plurality of contact regions 41 have a portion facing the corresponding buried electrode 38 and a portion facing the corresponding buried insulator 39 in the horizontal direction. The plurality of contact regions 41 face the corresponding buried electrode 38 and the corresponding buried insulator 39 via the corresponding insulating film 37. In this embodiment, the plurality of contact regions 41 have a portion exposed from the opening end of the gate trench 36.

The contact region 41 may have a depth greater than the depth of the source region 40. The depth of the contact region 41 may be less than the depth of the source region 40. The depth of the contact region 41 is greater than the thickness between the bottom portion of the body region 32 and the bottom portion of the contact region 41. The depth of the contact region 41 may be less than the thickness between the bottom portion of the body region 32 and the bottom portion of the contact region 41.

The length of the plurality of contact regions 41 in the first direction X is adjusted in accordance with the channel area to be formed. The channel area is the total planar area of the plurality of source regions 40. In other words, the channel area decreases or increases in accordance with the increase or decrease in the ratio of the total planar area of the plurality of contact regions 41. It is preferable that the total planar area of the plurality of contact regions 41 is less than the channel area.

The plurality of contact regions 41 may extend in a strip shape in the first direction X following the extending direction of the plurality of gate structures 35 in the plan view. The lengths of the plurality of contact regions 41 in the first direction X may be equal to or different from each other. The length of the contact region 41 may be either greater than or less than the width of the gate structure 35. The length of the contact region 41 may be either greater than or less than the spacing between the plurality of gate structures 35.

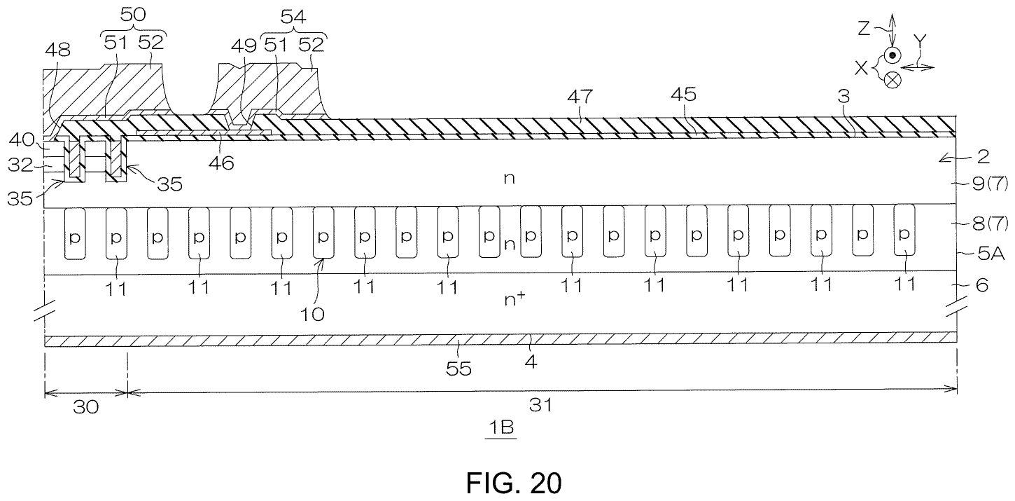

FIG. 20 is a cross-sectional view along a line XX-XX shown in FIG. 14. Referring to FIG. 20, the semiconductor device 1B includes a main surface insulating film 45 that selectively covers the first main surface 3. The main surface insulating film 45 may be referred to as a “surface insulating film,” “outer insulating film,” etc. The main surface insulating film 45 may include at least one of a silicon oxide film, a silicon nitride film, and a silicon oxynitride film.

The main surface insulating film 45 may include a silicon oxide film including an oxide of the chip 2 (the second layer 9). The main surface insulating film 45 may include a silicon oxide film that includes an oxide other than that of the chip 2. The main surface insulating film 45 may include an insulator of the same type as the insulating film 37.

The main surface insulating film 45 selectively covers the first main surface 3 in the active region 30 and the outer region 31. The main surface insulating film 45 covers the first main surface 3 in a film form at the peripheral portion of the active region 30 and exposes a plurality of gate structures 35. Specifically, the main surface insulating film 45 is connected to a plurality of insulating films 37 and exposes a plurality of buried insulators 39.

The main surface insulating film 45 covers the first main surface 3 (the plurality of second regions 12) in the outer region 31. The main surface insulating film 45 is continuous with the first to fourth side surfaces 5A to 5D. The main surface insulating film 45 may be formed with a spacing inward from the first to fourth side surfaces 5A to 5D and may expose the peripheral portion of the first main surface 3. The main surface insulating film 45 may have a thickness substantially equal to the thickness of the plurality of insulating films 37.

The thickness of the main surface insulating film 45 may be 10 nm or more and 250 nm or less. The thickness of the main surface insulating film 45 may have a value that falls within at least one of the ranges of 10 nm or more and 25 nm or less, 25 nm or more and 50 nm or less, 50 nm or more and 75 nm or less, 75 nm or more and 100 nm or less, 100 nm or more and 125 nm or less, 125 nm or more and 150 nm or less, 150 nm or more and 175 nm or less, 175 nm or more and 200 nm or less, 200 nm or more and 225 nm or less, and 225 nm or more and 250 nm or less.

The semiconductor device 1B includes one or more (in this embodiment, one) gate wirings 46 that are selectively routed on the first main surface 3 in the outer region 31. The gate wiring 46 may include either or both of p-type conductive polysilicon and n-type conductive polysilicon. It is preferable that the gate wiring 46 has the same conductive material as the conductive material of the buried electrode 38.

The gate wiring 46 is electrically connected to the plurality of gate structures 35 and applies a gate potential to the plurality of gate structures 35. The gate wiring 46 is disposed on the main surface insulating film 45 with a spacing from the periphery of the first main surface 3 toward the active region 30 and faces the first main surface 3 via the main surface insulating film 45.

The gate wiring 46 has a portion extending in a strip shape in the first direction X and a portion extending in a strip shape in the second direction Y and intersects (specifically, orthogonally) at the ends of the plurality of gate structures 35. In this embodiment, the gate wiring 46 is formed as an endless polygonal ring shape (for example, a quadrilateral ring shape) having four sides parallel to the periphery of the first main surface 3 and surrounds the active region 30 (a plurality of gate structures 35).

The gate wiring 46 may be formed in a strip shape including ends. The gate wiring 46 may have an edge portion that connects a portion extending in a strip shape in the first direction X and a portion extending in a strip shape in the second direction Y in an arc shape (preferably a quarter-arc shape) in the plan view.

The gate wiring 46 has an inner edge on the inner side of the first main surface 3 and an outer edge on the periphery side of the first main surface 3, respectively. The inner edge of the gate wiring 46 is mechanically and electrically connected to the ends of the plurality of gate structures 35. Specifically, the inner edge of the gate wiring 46 is mechanically and electrically connected to a plurality of buried electrodes 38 within a plurality of gate trenches 36. In this embodiment, the gate wiring 46 is integrally formed with the plurality of buried electrodes 38 as a lead-out portion of the plurality of buried electrodes 38.

The semiconductor device 1B includes an insulating interlayer film 47 that covers the first main surface 3. The interlayer film 47 may include at least one of a silicon oxide film, a silicon nitride film, and a silicon oxynitride film. The interlayer film 47 may have a single-layer structure or a laminated structure that includes at least one of an NSG film, a PSG film, and a BPSG film.

It is preferable that the interlayer film 47 has a single-layer structure or a laminated structure that includes at least an NSG film. The interlayer film 47 may have a laminated structure that includes an NSG film and a PSG film laminated in this order from the chip 2 side. The interlayer film 47 may have a laminated structure that includes an NSG film, a PSG film, and a BPSG film laminated in this order from the chip 2 side. The interlayer film 47 may include an insulator of the same type as the buried insulator 39.

The interlayer film 47 covers the main surface insulating film 45 in the active region 30 and the outer region 31 in a film form. The interlayer film 47 covers a plurality of gate structures 35 at the peripheral portion of the active region 30. Specifically, the interlayer film 47 enters the plurality of gate trenches 36 from above the main surface insulating film 45 and covers the plurality of buried electrodes 38 within the plurality of gate trenches 36.

The interlayer film 47 is connected to a plurality of buried insulators 39 within the gate trenches 36. In this embodiment, the interlayer film 47 is integrally formed with the plurality of buried insulators 39. The connection portion of the interlayer film 47 to the plurality of buried insulators 39 may be regarded as a portion of the plurality of buried insulators 39 or as a portion of the interlayer film 47.

The interlayer film 47 covers the first main surface 3 (the plurality of second regions 12) via the main surface insulating film 45 in the outer region 31. The interlayer film 47 covers the gate wiring 46 in the outer region 31. The interlayer film 47 is continuous with the first to fourth side surfaces 5A to 5D. The outer edge of the interlayer film 47 is formed with a spacing inward from the first to fourth side surfaces 5A to 5D, and may expose either or both of the peripheral portion of the first main surface 3 and the main surface insulating film 45.

The interlayer film 47 has a thickness greater than the thickness of the main surface insulating film 45. The thickness of the interlayer film 47 may be 0.1 μm or more and 5 μm or less. The thickness of the interlayer film 47 may have a value that falls within at least one of the ranges of 0.1 μm or more and 0.5 μm or less, 0.5 μm or more and 1 μm or less, 1 μm or more and 1.5 μm or less, 1.5 μm or more and 2 μm or less, 2 μm or more and 2.5 μm or less, 2.5 μm or more and 3 μm or less, 3 μm or more and 3.5 μm or less, 3.5 μm or more and 4 μm or less, 4 μm or more and 4.5 μm or less, and 4.5 μm or more and 5 μm or less.

The semiconductor device 1B includes a source opening 48 formed in the interlayer film 47 in the active region 30. The source opening 48 penetrates through the main surface insulating film 45 and the interlayer film 47 and exposes a plurality of gate structures 35. Specifically, the source opening 48 exposes the plurality of buried insulators 39, the body region 32, the plurality of source regions 40, and the plurality of contact regions 41.

The semiconductor device 1B includes one or more (in this embodiment, a plurality of) gate openings 49 formed in the interlayer film 47. The plurality of gate openings 49 penetrate through the interlayer film 47 and selectively expose the gate wiring 46. In this embodiment, the plurality of gate openings 49 extend in a strip shape following the extending direction of the gate wiring 46.

The plurality of gate openings 49 may be formed with a spacing along the extending direction of the gate wiring 46. The plurality of gate openings 49 may each extend in a strip shape following the extending direction of the gate wiring 46. The plurality of gate openings 49 may have a portion extending in a strip shape in the first direction X and a portion extending in a strip shape in the second direction Y in the plan view.

The plurality of gate openings 49 may have an edge portion that connects a portion extending in a first direction X and a portion extending in a second direction Y in an arc shape (preferably in a quarter-arc shape). The plurality of gate openings 49 may be formed in polygonal or circular shapes in the plan view. For example, the plurality of gate openings 49 may be formed in quadrilateral or hexagonal shapes in the plan view. When a single gate opening 49 is formed, the gate opening 49 may extend in a strip shape following the extending direction of the gate wiring 46.

The semiconductor device 1B includes a source electrode 50 disposed on the first main surface 3. The source electrode 50 may be referred to as a “first main electrode,” “first terminal (electrode),” “first pad (electrode),” “source pad electrode,” etc. The source electrode 50 is disposed on the interlayer film 47.

In this embodiment, the source electrode 50 has a first pad portion 50a, a second pad portion 50b, and a third pad portion 50c. The first pad portion 50a has a relatively large planar area and forms the main body of the source electrode 50. In this embodiment, the first pad portion 50a is formed in a polygonal shape (in this embodiment, a quadrilateral shape) having four sides parallel to the periphery of the first main surface 3 in the plan view, and is biased toward the third side surface 5C side relative to the center of the first main surface 3.

The second pad portion 50b has a planar area smaller than the planar area of the first pad portion 50a and is led out in a strip shape (quadrilateral shape) from one end of the first pad portion 50a in the first direction X (the end on the second side surface 5B side) toward the first side surface 5A. The third pad portion 50c has a planar area smaller than the planar area of the first pad portion 50a and is led out in a strip shape (quadrilateral shape) from the other end of the first pad portion 50a in the first direction X (the end on the fourth side surface 5D side) toward the first side surface 5A, and faces the second pad portion 50b in the first direction X.

The planar area of the third pad portion 50c may be substantially equal to the planar area of the second pad portion 50b. The planar area of the third pad portion 50c may be either greater than or less than the planar area of the second pad portion 50b. Either or both of the second pad portion 50b and the third pad portion 50c may be used as terminal portions for current monitoring.

The source electrode 50 does not necessarily need to have both the second pad portion 50b and the third pad portion 50c at the same time; it may have only one of the second pad portion 50b and the third pad portion 50c. The source electrode 50 may be formed of only the first pad portion 50a and may not necessarily have both the second pad portion 50b and the third pad portion 50c.

In this embodiment, the source electrode 50 has a laminated structure that includes a base electrode 51 and a main body electrode 52. The base electrode 51 extends from above the interlayer film 47 into the source opening 48 and covers the entire area within the source opening 48 in a film form. The base electrode 51 has a portion that covers the interlayer film 47 in a film form, a portion that covers the wall surfaces of the source opening 48 in a film form, and a portion that covers the first main surface 3 in a film form.

The base electrode 51 collectively covers a plurality of gate structures 35 within the source opening 48. The base electrode 51 is mechanically and electrically connected to the body region 32, the plurality of source regions 40, and the plurality of contact regions 41 on the first main surface 3. The base electrode 51 covers the insulating surfaces of a plurality of buried insulators 39 within the plurality of gate trenches 36 and is electrically isolated from the plurality of buried electrodes 38.

The base electrode 51 has a peripheral portion that face the ends of a plurality of gate structures 35 via the interlayer film 47. The peripheral portion of the base electrode 51 is led out from the active region 30 to the outer region 31 and faces a portion of the gate wiring 46 via the interlayer film 47. The peripheral portion of the base electrode 51 is formed with a spacing from the outer edge of the gate wiring 46 to the inner edge side of the gate wiring 46. The peripheral portion of the base electrode 51 may be positioned inward relative to the intermediate portion of the gate wiring 46.

The base electrode 51 may have a laminated structure having a plurality of metal films or a single-layer structure formed of a single metal film. For example, the base electrode 51 may have a laminated structure that includes a Ti film and a TiN film laminated in this order on the first main surface 3 side. For example, the base electrode 51 may have a single-layer structure that includes either a Ti film or a TiN film.

The thickness of the base electrode 51 may be greater than 0 nm and 500 nm or less. The thickness of the base electrode 51 may have a value that falls within at least one of the ranges of 0 nm or more and 50 nm or less, 50 nm or more and 100 nm or less, 100 nm or more and 150 nm or less, 150 nm or more and 200 nm or less, 200 nm or more and 250 nm or less, 250 nm or more and 300 nm or less, 300 nm or more and 350 nm or less, 350 nm or more and 400 nm or less, 400 nm or more and 450 nm or less, and 450 nm or more and 500 nm or less.

The main electrode 52 is formed of a conductor different from the base electrode 51. In this embodiment, the main electrode 52 is formed of an aluminum alloy. The aluminum alloy may include at least one of AlSi alloy, AlCu alloy, and AlSiCu alloy.

The main electrode 52 covers the base electrode 51 in a film form and extends into the source opening 48 from above the interlayer film 47. The main electrode 52 has a portion that covers the interlayer film 47 in a film form via the base electrode 51, a portion that covers the wall surface of the source opening 48 in a film form via the base electrode 51, and a portion that covers the first main surface 3 in a film form via the base electrode 51.

The main electrode 52 collectively covers a plurality of gate structures 35 via the base electrode 51 within the source opening 48. The main electrode 52 is electrically connected to the body region 32, the plurality of source regions 40, and the plurality of contact regions 41 via the base electrode 51.

The main electrode 52 has a peripheral portion that faces the ends of the plurality of gate structures 35 via the interlayer film 47. The peripheral portion of the main electrode 52 is led out from the active region 30 to the outer region 31 and faces a portion of the gate wiring 46 via the interlayer film 47. The peripheral portion of the main electrode 52 is formed with a spacing from the outer edge of the gate wiring 46 to the inner edge side of the gate wiring 46. The peripheral portion of the main electrode 52 may be positioned inward from the middle portion of the gate wiring 46.

The main electrode 52 has a thickness greater than the thickness of the base electrode 51. In this embodiment, the thickness of the main electrode 52 is greater than the thickness of the interlayer film 47. The thickness of the main electrode 52 may be less than the thickness of the interlayer film 47.

The thickness of the main electrode 52 may be greater than 0 μm and 5 μm or less. The thickness of the main electrode 52 may have a value that falls within at least one of the ranges of greater than 0 μm and less than or equal to 0.5 μm, 0.5 μm or more and 1 μm or less, 1 μm or more and 1.5 μm or less, 1.5 μm or more and 2 μm or less, 2 μm or more and 2.5 μm or less, 2.5 μm or more and 3 μm or less, 3 μm or more and 3.5 μm or less, 3.5 μm or more and 4 μm or less, 4 μm or more and 4.5 μm or less, and 4.5 μm or more and 5 μm or less.

The semiconductor device 1B includes a gate electrode 53 disposed on the first main surface 3. The gate electrode 53 may be referred to as a “second main electrode,” “second terminal (electrode),” “second pad (electrode),” “gate pad electrode,” etc. The gate electrode 53 is disposed on the interlayer film 47 and with a spacing from the source electrode 50.

The gate electrode 53 is disposed in a region on the first side surface 5A side relative to the first pad portion 50a and faces the central portion of the first side surface 5A and the first pad portion 50a in the second direction Y. The gate electrode 53 is interposed in a region between the second pad portion 50b and the third pad portion 50c and faces both the second pad portion 50b and the third pad portion 50c in the first direction X.

The gate electrode 53 is formed in a polygonal shape (in this case, a quadrilateral shape) having four sides parallel to the periphery of the first main surface 3 in the plan view. The plane area of the gate electrode 53 is less than the plane area of the source electrode 50. The plane area of the gate electrode 53 is less than the plane area of the first pad portion 50a. The plane area of the gate electrode 53 may be either larger or smaller than the plane area of the second pad portion 50b (the third pad portion 50c).

In this embodiment, the gate electrode 53 does not have a direct electrical connection portion to the gate wiring 46. The gate electrode 53 may be mechanically and electrically connected to the gate wiring 46 via one or more gate openings 49. Although not shown, the gate electrode 53 includes a base electrode 51 and a main body electrode 52, which are laminated in this order from the interlayer film 47 side, similar to the source electrode 50.

The semiconductor device 1B includes a gate finger electrode 54 led out from the gate electrode 53 onto the first main surface 3. The gate finger electrode 54 may be referred to as a “gate wiring 46,” “gate finger,” etc. The gate finger electrode 54 transmits the gate potential applied to the gate electrode 53 to another region.

The gate finger electrode 54 is led out from the gate electrode 53 onto the interlayer film 47 and is routed in a strip shape along the source electrode 50. The gate finger electrode 54 has a portion extending in a strip shape in the first direction X and a portion extending in a strip shape in the second direction Y. In this embodiment, the gate finger electrode 54 is formed in a strip shape including ends having four sides parallel to the periphery of the first main surface 3 and surrounds the source electrode 50.

The gate finger electrode 54 is disposed closer to the periphery side of the first main surface 3 than both ends of the multiple gate structures 35. The gate finger electrode 54 may have an edge portion that connects a portion extending in the first direction X and a portion extending in the second direction Y in an arc shape (preferably a quarter-arc shape).

The gate finger electrode 54 enters a plurality of gate openings 49 from above the interlayer film 47 and is mechanically and electrically connected to the gate wiring 46 within the plurality of gate openings 49. As a result, the gate potential applied to the gate electrode 53 is applied to the plurality of gate structures 35 via the gate wiring 46 and the gate finger electrode 54.

The gate finger electrode 54 has an inner edge on the inner side of the first main surface 3 and an outer edge on the periphery side of the first main surface 3. The inner edge of the gate finger electrode 54 is formed with a spacing from the ends of the plurality of gate structures 35 to the periphery side of the first main surface 3 and faces the first main surface 3 in the laminating direction. That is, the gate finger electrode 54 does not face the plurality of gate structures 35 in the laminating direction.

The inner edge of the gate finger electrode 54 is disposed on the gate wiring 46. The inner edge of the gate finger electrode 54 faces the peripheral edge of the source electrode 50 on the gate wiring 46 in the horizontal direction. The inner edge of the gate finger electrode 54 is positioned closer to the periphery side of the first main surface 3 than the middle portion of the gate wiring 46. The outer edge of the gate finger electrode 54 is led out from above the gate wiring 46 to the periphery side of the first main surface 3 and faces the first main surface 3 in the laminating direction.

Similar to the gate electrode 53, the gate finger electrode 54 has a laminated structure that includes the base electrode 51 and the main body electrode 52 which are laminated in this order from the first main surface 3 side. The base electrode 51 collectively covers regions of the interlayer film 47 where a plurality of gate openings 49 are formed in a film form and extends into the plurality of gate openings 49 from above the interlayer film 47.

The base electrode 51 has a portion that covers the insulating surface of the interlayer film 47 in a film form, a portion that covers the walls of the plurality of gate openings 49 in a film form, and a portion that covers the gate wiring 46 in a film form within the plurality of gate openings 49. The base electrode 51 is mechanically and electrically connected to the gate wiring 46 within the plurality of gate openings 49.

The main electrode 52 collectively covers regions of the interlayer film 47 where the plurality of gate openings 49 are formed in a film form via the base electrode 51 and extends into the plurality of gate openings 49 from above the interlayer film 47.

The main electrode 52 has a portion that covers the interlayer film 47 in a film form via the base electrode 51, a portion that covers the wall surfaces of the plurality of gate openings 49 in a film form via the base electrode 51, and a portion that covers the gate wiring 46 in a film form via the base electrode 51 within the plurality of gate openings 49. The main electrode 52 is electrically connected to the gate wiring 46 via the base electrode 51 within the plurality of gate openings 49.

The semiconductor device 1B includes a drain electrode 55 that covers the second main surface 4. The drain electrode 55 may be referred to as a “third main electrode,” “third terminal (electrode),” “third pad (electrode),” “drain pad electrode,” etc. The drain electrode 55 is mechanically and electrically connected to the base layer 6 and forms an ohmic contact with the base layer 6.

The drain electrode 55 covers the entire area of the second main surface 4 and may be continuous with the periphery of the second main surface 4 (the first to fourth side surfaces 5A to 5D). The drain electrode 55 may partially cover the second main surface 4 to expose the peripheral portion of the second main surface 4.

The breakdown voltage that can be applied between the source electrode 50 and the drain electrode 55 (between the first main surface 3 and the second main surface 4) may be in the range of 500 V to 3000 V. The breakdown voltage may have a value that falls within at least one of the ranges of 500 V or more and 750 V or less, 750 V or more and 1000 V or less, 1000 V or more and 1250 V or less, 1250 V or more and 1500 V or less, 1500 V or more and 1750 V or less, 1750 V or more and 2000 V or less, 2000 V or more and 2250 V or less, 2250 V or more and 2500 V or less, and 2500 V or more and 3000 V or less.

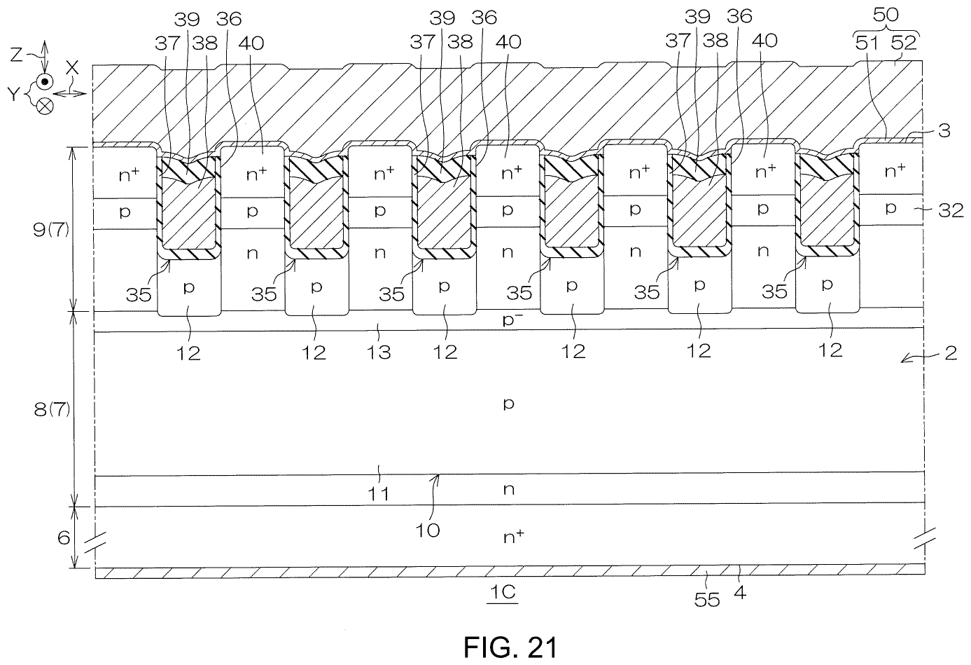

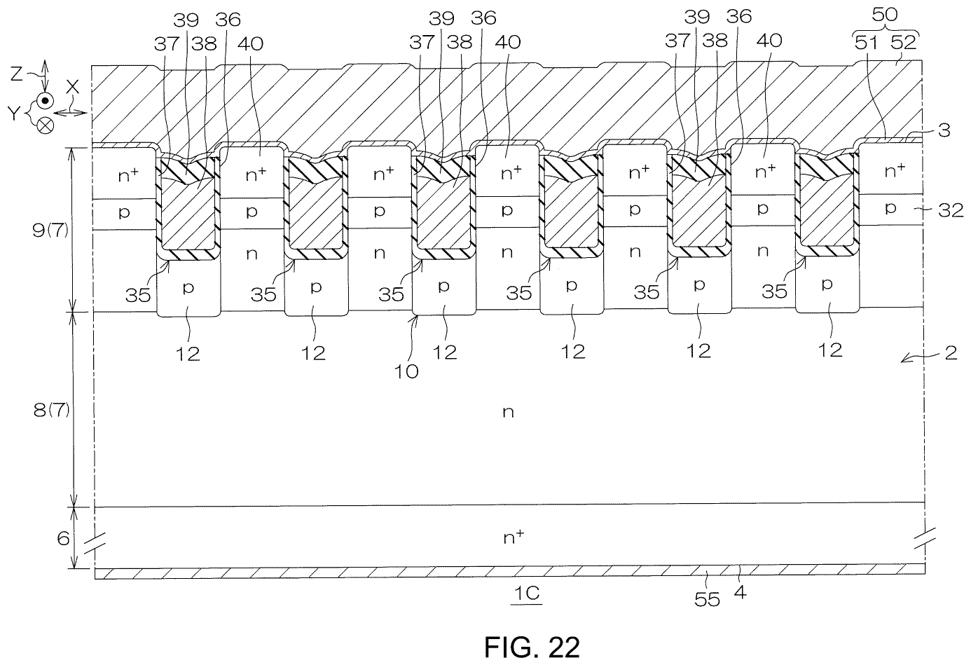

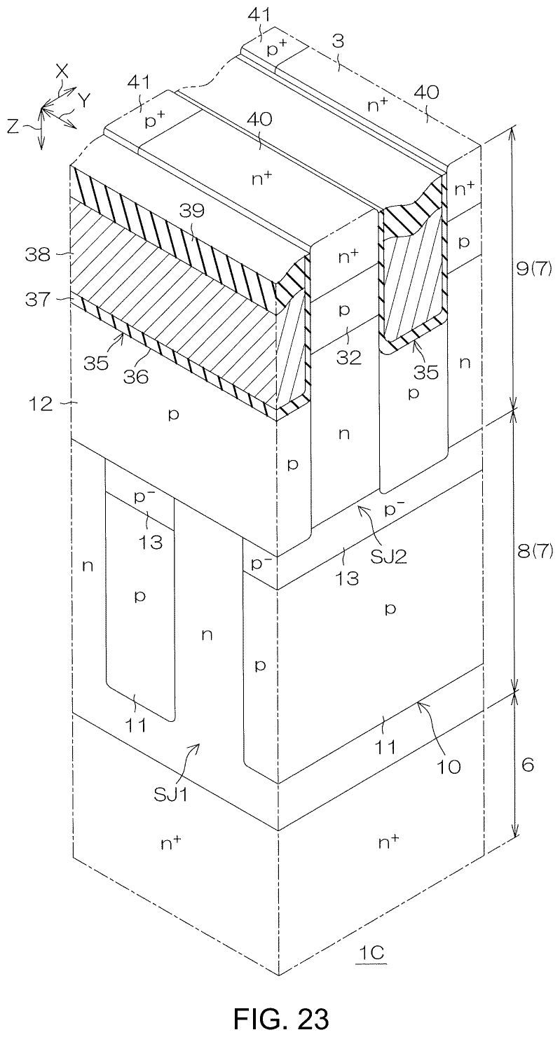

FIG. 21 is a cross-sectional view showing a main part of the active region 30 of a semiconductor device 1C according to a third embodiment. FIG. 22 is a cross-sectional view showing another main part of the active region 30 of the semiconductor device 1C shown in FIG. 21. FIG. 23 is a cross-sectional perspective view showing a main part of the active region 30 along with the pillar region 10 according to a first example.

Referring to FIGS. 21 to 23, the semiconductor device 1C has the chip 2 and the pillar region 10 according to the semiconductor device 1A as its basic form. In this embodiment, the semiconductor device 1C has the pillar region 10 according to the first embodiment (refer to FIG. 3 and FIGS. 5A to 5C).

The semiconductor device 1C may have any one of the pillar regions 10 according to the second to fifth embodiments (refer to FIGS. 6 to 10). Additionally, the semiconductor device 1C may have the pillar region 10 according to the first modification example (refer to FIG. 11) or the pillar region 10 according to the second modification example (refer to FIG. 12).

The semiconductor device 1C has a modified embodiment of the semiconductor device 1B. Specifically, in this embodiment, a plurality of gate structures 35 are arranged with a spacing in the first direction X in the plan view and each extend in a strip shape in the second direction Y. The plurality of gate structures 35 are arranged in a stripe shape extending in the second direction Y in the plan view.

In this embodiment, the plurality of gate structures 35 extend in the same direction as the extending direction of the plurality of second regions 12 and in a different direction from the extending direction of the plurality of first regions 11. The plurality of gate structures 35 intersect (specifically, orthogonally) the plurality of first regions 11. This layout is effective in increasing the channel area of the active region 30.

In this embodiment, the plurality of gate structures 35 are arranged with a spacing substantially equal to the spacing between the plurality of second regions 12 and overlap the plurality of second regions 12 in a one-to-one correspondence in the laminating direction. The plurality of gate structures 35 have bottom walls connected to the plurality of second regions 12. The spacing between the plurality of gate structures 35 may be substantially equal to the spacing between the plurality of first regions 11. The spacing between the plurality of gate structures 35 may be either greater than or less than the spacing between the plurality of first regions 11.

In this embodiment, the plurality of source regions 40 are formed with a spacing in the second direction Y following the extending direction of the plurality of gate structures 35, and are adjacent to two corresponding gate structures 35 in the first direction X. In this embodiment, the plurality of source regions 40 extend in a strip shape in the second direction Y, following the extending direction of the corresponding a plurality of gate structures 35.

The plurality of source regions 40 may intersect one or more of the second regions 12 in the laminating direction. Other descriptions of the plurality of source regions 40 can be obtained by replacing the “first direction X” with the “second direction Y” and simultaneously replacing the “second direction Y” with the “first direction X” in the above description.

In this embodiment, the plurality of contact regions 41 are formed with a spacing in the second direction Y following the extending direction of the plurality of gate structures 35, and are adjacent to two corresponding gate structures 35 in the first direction X. In this embodiment, the plurality of contact regions 41 extend in a strip shape in the second direction Y following the extending direction of the corresponding a plurality of gate structures 35.

The plurality of contact regions 41 may intersect one or more of the second regions 12 in the laminating direction. Other descriptions of the plurality of contact regions 41 can be obtained by replacing the “first direction X” with the “second direction Y” and simultaneously replacing the “second direction Y” with the “first direction X” in the above description.

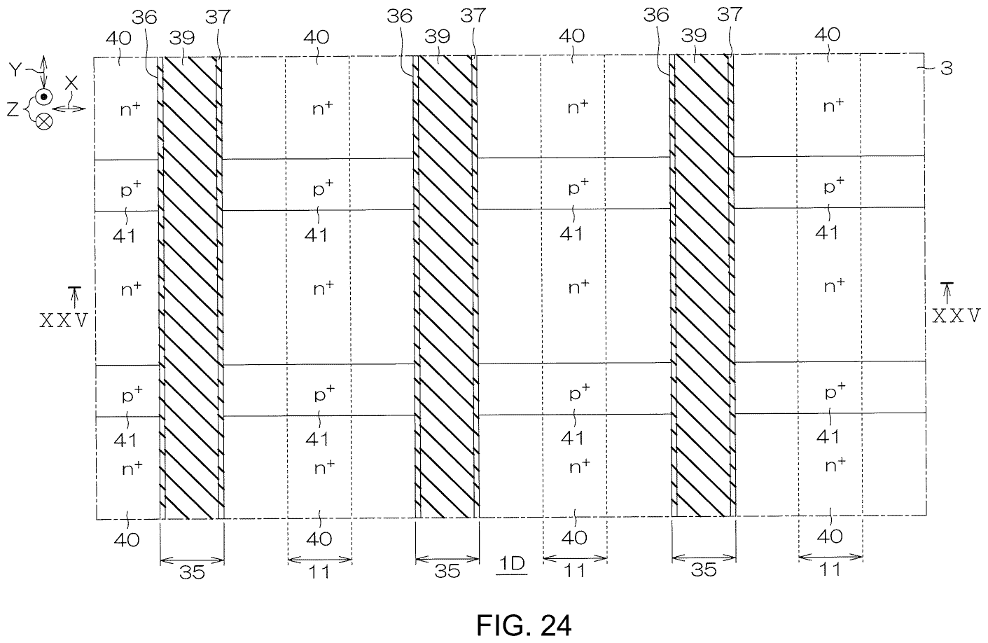

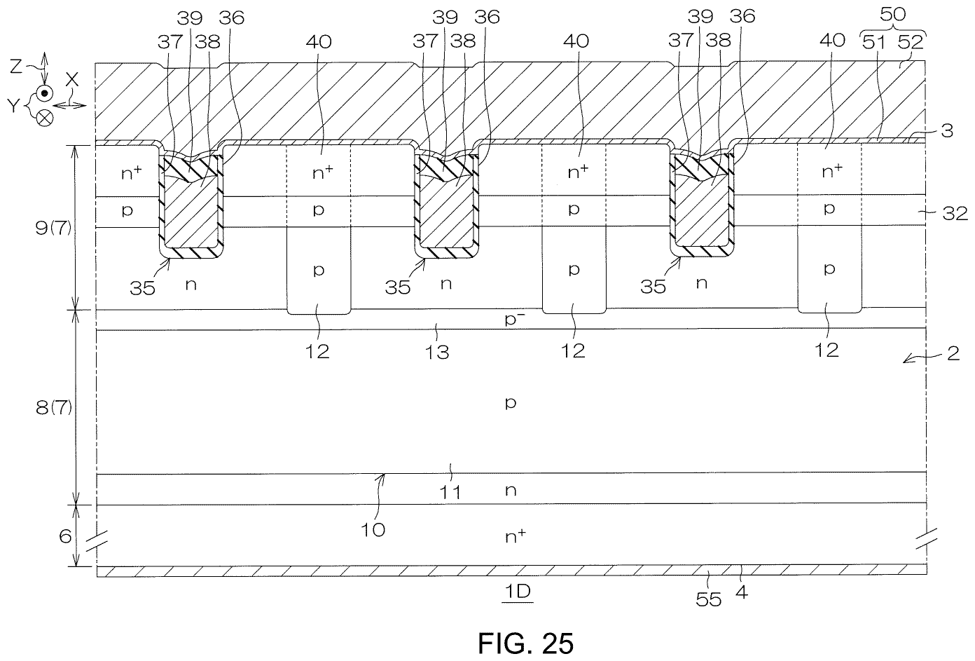

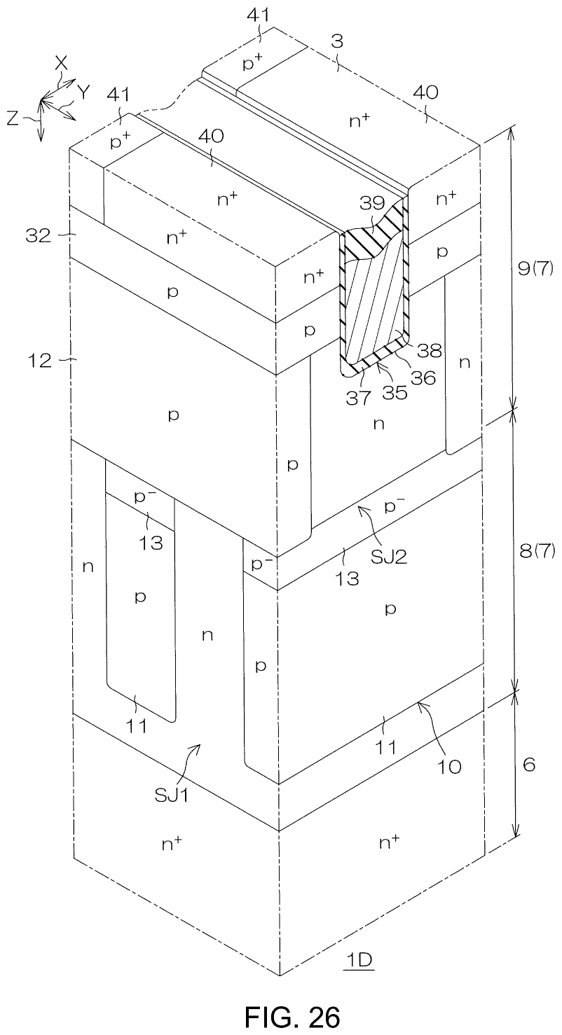

FIG. 24 is an enlarged plan view showing the active region 30 of a semiconductor device 1D according to a fourth embodiment. FIG. 25 is a cross-sectional view along a line XXV-XXV shown in FIG. 24. FIG. 26 is a cross-sectional perspective view showing a main part of an active region 30 along with a pillar region 10 according to the first example.

The semiconductor device 1D has a modified embodiment of the semiconductor device 1C. Specifically, the plurality of gate structures 35 are each disposed in a region between the plurality of second regions 12 with a spacing from the plurality of second regions 12.

In this embodiment, the plurality of gate structures 35 are each disposed in the middle portion of two adjacent second regions 12 and extend in a strip shape in the second direction Y following the extending direction of the second regions 12. The plurality of gate structures 35 each have a portion (bottom wall) that faces toward the plurality of second regions 12 in the horizontal direction with a portion of the second layer 9 in between.

The plurality of gate structures 35 are formed with a spacing from the lower end of the second layer 9 toward the first main surface 3 side and face the first layer 8 and the plurality of first regions 11 with a portion of the second layer 9 in between. This layout is effective in alleviating the restrictions of the design rules for the plurality of gate structures 35 with respect to the plurality of second regions 12 compared to the configuration of the semiconductor device 1C. Other configurations are similar to those of the semiconductor device 1C.

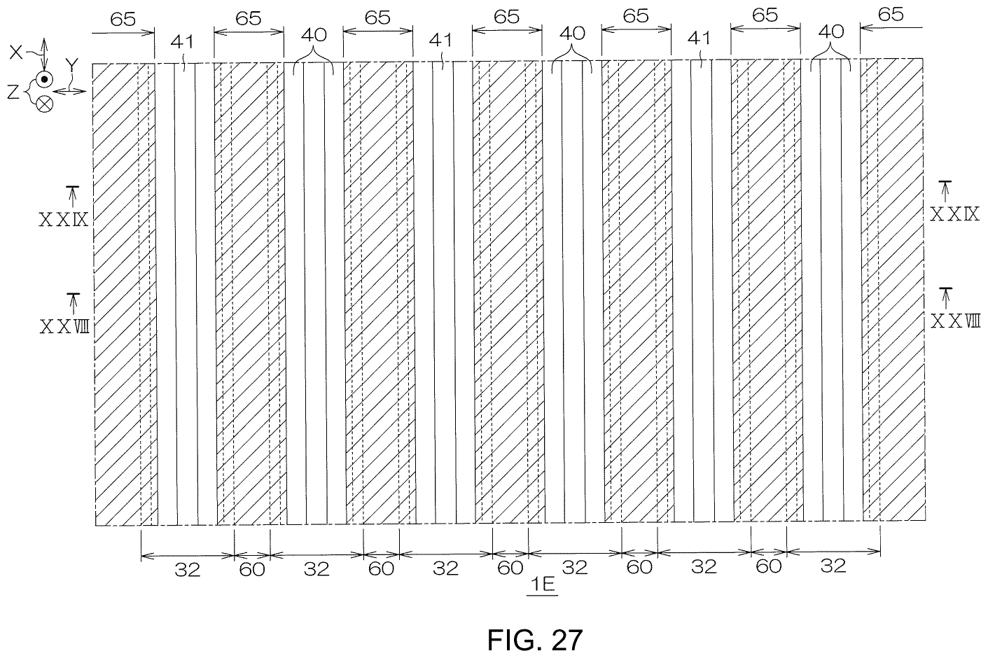

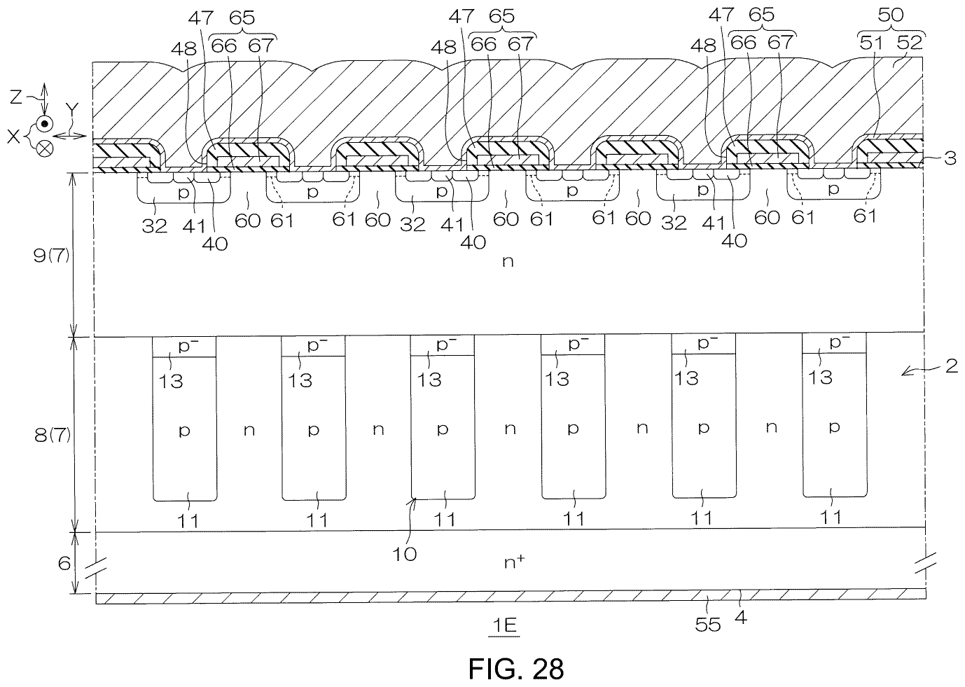

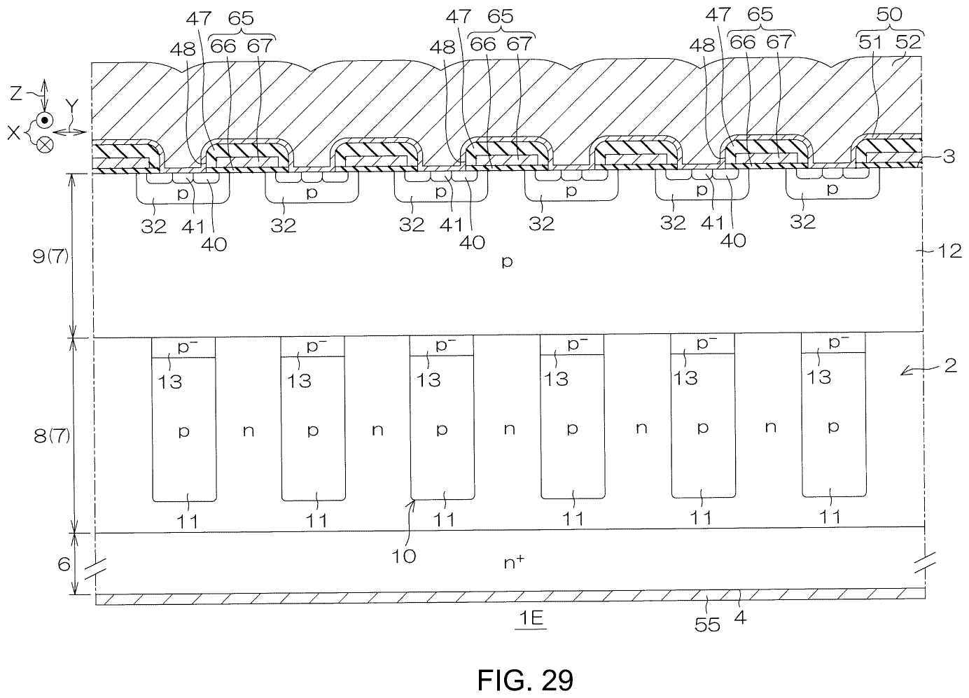

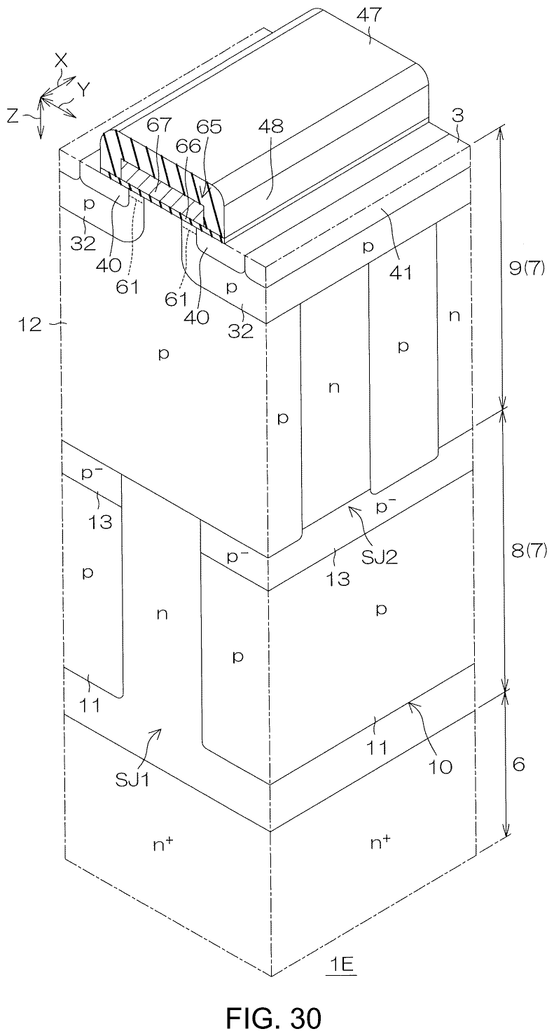

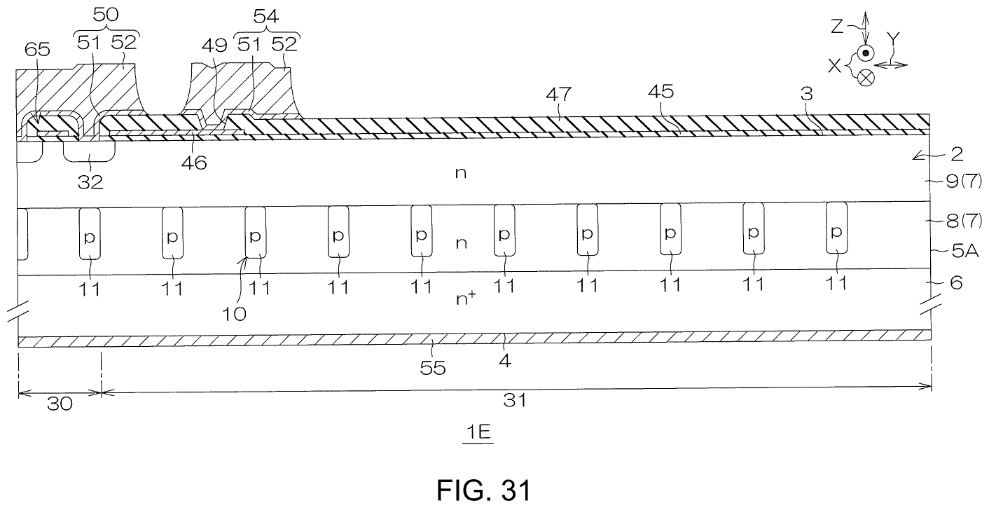

FIG. 27 is an enlarged plan view showing the active region 30 of the semiconductor device 1E according to a fifth embodiment. FIG. 28 is a cross-sectional view along a line XXVIII-XXVIII shown in FIG. 27. FIG. 29 is a cross-sectional view along a line XXIX-XXIX shown in FIG. 27. FIG. 30 is a cross-sectional perspective view showing a main part of the active region 30 along with the pillar region 10 according to the first example. FIG. 31 is a cross-sectional view showing the outer region 31 of a semiconductor device 1E shown in FIG. 27.

Referring to FIGS. 27 to 31, the semiconductor device 1E is a semiconductor switching device that has an insulated gate type transistor structure as an example of a device structure (functional device). The transistor structure has a planar gate type vertical structure.

The semiconductor device 1E has the chip 2 and the pillar region 10 according to semiconductor device 1A as its basic form. In this embodiment, the semiconductor device 1E has the pillar region 10 according to the first embodiment (refer to FIG. 3 and FIGS. 5A to 5C).

The semiconductor device 1E may have any one of the pillar regions 10 according to the second to fifth embodiments (refer to FIGS. 6 to 10). Additionally, the semiconductor device 1E may have the pillar region 10 according to the first modification (refer to FIG. 11) or the pillar region 10 according to the second modification (refer to FIG. 12).

The semiconductor device 1E includes a plurality of p-type body regions 32 formed in the surface layer portion of the first main surface 3 in the active region 30. The plurality of body regions 32 are formed in the active region 30 with a spacing from the periphery of the first main surface 3 and are not formed in the outer region 31. The plurality of body regions 32 are formed in the surface layer portion of the second layer 9 and extend in a layered form along the first main surface 3.

In this embodiment, the plurality of body regions 32 each extend in a strip shape in the first direction X and are arranged with a spacing in the second direction Y. The plurality of body regions 32 are arranged in a stripe shape extending in the first direction X. This layout is effective in alleviating the restrictions of the design rules for the plurality of body regions 32 with respect to the plurality of second regions 12.

In this embodiment, the plurality of body regions 32 extend in the same direction as the extending direction of the plurality of first regions 11 and extend in a direction different from the extending direction of the plurality of second regions 12. The plurality of body regions 32 intersect (specifically, orthogonally) the plurality of second regions 12. The plurality of body regions 32 are connected to the plurality of second regions 12. The p-type impurity concentration of the plurality of body regions 32 is increased by the plurality of second regions 12.

In this embodiment, the plurality of body regions 32 are arranged with a spacing substantially equal to the spacing of the plurality of first regions 11 and overlap the plurality of first regions 11 in a one-to-one correspondence in the laminating direction. The spacing of the plurality of body regions 32 may differ from the spacing of the plurality of first regions 11.

In this case, the plurality of body regions 32 may include body regions 32 that face the first region 11 in the laminating direction and body regions 32 that do not face the first region 11 in the laminating direction. All body regions 32 may face regions between the plurality of first regions 11 in the laminating direction.

The spacing of the body regions 32 may be greater than 0 μm and less than or equal to 10 μm. The spacing of the body regions 32 may have a value that falls within at least one of the ranges of greater than 0 μm and less than or equal to 0.5 μm, 0.5 μm or more and 1 μm or less, 1 μm or more and 2 μm or less, 2 μm or more and 3 μm or less, 3 μm or more and 4 μm or less, 4 μm or more and 5 μm or less, 5 μm or more and 6 μm or less, 6 μm or more and 7 μm or less, 7 μm or more and 8 μm or less, 8 μm or more and 9 μm or less, and 9 μm or more and 10 μm or less.

The semiconductor device 1E includes a plurality of n-type source regions 40 each formed in the surface layer portion of the plurality of body regions 32. The plurality of source regions 40 are formed with a spacing inward from both edge portions of the corresponding body regions 32 with respect to the second direction Y.

The plurality of source regions 40 extend in a strip shape in the first direction X in the surface layer portion of the corresponding body regions 32 and are formed with a spacing in the second direction Y. The plurality of source regions 40 may be formed with a spacing in the first direction X following the extending direction of the corresponding body regions 32.

The plurality of source regions 40 are formed with a spacing inward from both ends of the corresponding body regions 32 with respect to the first direction X. The plurality of source regions 40 are formed with a spacing from the bottom portion of the corresponding body regions 32 toward the first main surface 3 and face the second layer 9 with a portion of the corresponding body regions 32 in between.

The semiconductor device 1E includes a plurality of p-type contact regions 41 formed in regions different from the source regions 40 in the surface layer portion of the corresponding body region 32. The plurality of contact regions 41 are interposed in regions between the source regions 40 in the surface layer portion of the corresponding body region 32 and are electrically connected to the body region 32.

The plurality of contact regions 41 extend in a strip shape in the first direction X following the extension direction of the corresponding body region 32 (the source region 40). The plurality of contact regions 41 are formed with a spacing from both ends of the corresponding body region 32 in the first direction X. The plurality of contact regions 41 are formed with a spacing from the bottom portion of the corresponding body region 32 toward the first main surface 3 side and face the second layer 9 with a portion of the corresponding body region 32 in between.

In this embodiment, the contact regions 41 have a width that is less than the width of the plurality of source regions 40. The width of the contact regions 41 may be greater than the width of the plurality of source regions 40. In this embodiment, the plurality of contact regions 41 have a thickness greater than the thickness of the plurality of source regions 40 and have a bottom portion positioned closer to the bottom portion side of the body region 32 than the bottom portions of the plurality of source regions 40.

The semiconductor device 1E includes a plurality of n-type surface drift regions 60 formed at the surface layer portion of the first main surface 3. In this embodiment, the plurality of surface drift regions 60 are each formed of a portion of the second layer 9. The plurality of surface drift regions 60 may have an n-type impurity concentration higher than the n-type impurity concentration of the second layer 9 or an n-type impurity concentration lower than the n-type impurity concentration of the second layer 9.

The plurality of surface drift regions 60 are each partitioned in regions between adjacent body regions 32 in the surface layer portion of the second layer 9. The plurality of surface drift regions 60 each extend in a strip shape in the first direction X and are arranged with a spacing in the second direction Y. The plurality of surface drift regions 60 are formed in a stripe shape extending in the first direction X.

The semiconductor device 1E includes a plurality of p-type channel regions 61 formed in the surface layer portion of the first main surface 3. The plurality of channel regions 61 are partitioned in regions between the plurality of source regions 40 and the plurality of surface drift regions 60 (the second layer 9) in the surface layer portion of the plurality of body regions 32 and extend in a strip shape in the first direction X. The plurality of channel regions 61 form a current path extending in the horizontal direction along the first main surface 3.

The semiconductor device 1E includes a plurality of planar-type (planar electrode type) gate structures 65 disposed on the first main surface 3 in the active region 30. The plurality of gate structures 65 each extend in a strip shape in the first direction X and are arranged with a spacing in the second direction Y. The plurality of gate structures 65 are arranged in a stripe shape extending in the first direction X.

In this embodiment, the plurality of gate structures 65 extend in the same direction as the extension direction of the plurality of first regions 11 and in a different direction from the extension direction of the plurality of second regions 12. The plurality of gate structures 65 intersect (specifically, orthogonally) the plurality of second regions 12. This layout is effective in alleviating the restrictions of the design rules for the plurality of gate structures 65 with respect to the plurality of second regions 12.

In this embodiment, the plurality of gate structures 65 are arranged with a spacing substantially equal to the spacing of the plurality of first regions 11 and overlap regions between the plurality of first regions 11 in a one-to-one correspondence in the laminating direction. The spacing of the plurality of gate structures 65 may be substantially equal to the spacing of the plurality of second regions 12. The spacing of the plurality of gate structures 65 may be either greater than or less than the spacing of the plurality of second regions 12.

The spacing between the plurality of gate structures 65 may differ from the spacing of the plurality of first regions 11. In this case, the plurality of gate structures 65 may include gate structures 65 that face the first region 11 in the laminating direction and gate structures 65 that do not face the first region 11 in the laminating direction. All gate structures 65 may face the first region 11 in the laminating direction.

The plurality of gate structures 65 are each disposed on at least one channel region 61 (the peripheral portion of the body region 32) and control the inversion and non-inversion of the channel region 61. The plurality of gate structures 65 cover at least one peripheral portion of the body region 32, at least one source region 40, and one surface drift region 60, respectively.

In this embodiment, the plurality of gate structures 65 cross the peripheral portions of two adjacent body regions 32 and cover the plurality of channel regions 61. Specifically, the plurality of gate structures 65 cross one and the other body regions 32 and cover two source regions 40, one surface drift region 60, and two channel regions 61.

The plurality of gate structures 65 each have a laminated structure that includes a planar insulating film 66 and a planar electrode 67. The planar insulating film 66 is referred to as a “gate insulating film,” and the planar electrode 67 may be referred to as a “gate electrode” or “planar gate electrode.”

The planar insulating film 66 may include at least one of a silicon oxide film, a silicon nitride film, and a silicon oxynitride film. In this embodiment, the planar insulating film 66 has a single-layer structure formed of a silicon oxide film. It is preferable that the planar insulating film 66 includes a silicon oxide film including an oxide of the second layer 9.

The planar insulating film 66 covers the first main surface 3 in a film form. The planar insulating film 66 extends in a strip shape in the first direction X. The planar insulating film 66 is disposed on at least one channel region 61 (the peripheral portion of the body region 32). The planar insulating films 66 cover at least one peripheral portion of the body region 32, at least one source region 40, and one surface drift region 60, respectively.

In this embodiment, the planar insulating films 66 cross the peripheral portions of two adjacent body regions 32. Specifically, the planar insulating films 66 cross one and the other body regions 32 and cover two source regions 40, one surface drift region 60, and two channel regions 61.

The planar electrode 67 is disposed on the planar insulating film 66. A gate potential is applied to the planar electrode 67 as a control potential. The planar electrode 67 may include either or both of p-type conductive polysilicon and n-type conductive polysilicon.

The planar electrode 67 covers the first main surface 3 in a film form via the planar insulating film 66 and faces at least one channel region 61 (the peripheral portion of the body region 32). The planar electrode 67 extends in a strip shape in the first direction X. In this embodiment, the planar electrode 67 is formed with a spacing inward from the periphery of the planar insulating film 66 and exposes the peripheral portion of the planar insulating film 66.

The planar electrode 67 covers at least a peripheral portion of one body region 32, at least one source region 40, and one surface drift region 60 via the planar insulating film 66. The planar electrode 67 crosses the peripheral portions of two adjacent body regions 32. Specifically, the planar electrode 67 crosses one and the other body regions 32 and faces two source regions 40, one surface drift region 60, and two channel regions 61 via the planar insulating film 66.

The semiconductor device 1E, similar to semiconductor device 1A, includes a main surface insulating film 45 that selectively covers the first main surface 3. The main surface insulating film 45 selectively covers the first main surface 3 in the active region 30 and the outer region 31. In the active region 30, the main surface insulating film 45 covers the first main surface 3 in a film form and is connected to a plurality of planar insulating films 66. The main surface insulating film 45 is integrally formed with the plurality of planar insulating films 66 and forms a single insulating film with the plurality of planar insulating films 66.

The main surface insulating film 45 covers the first main surface 3 (the plurality of second regions 12) in the outer region 31. The main surface insulating film 45 is continuous with the first to fourth side surfaces 5A to 5D. The main surface insulating film 45 may be formed with a spacing inward from the first to fourth side surfaces 5A to 5D and may expose the peripheral portion of the first main surface 3. The main surface insulating film 45 may have a thickness substantially equal to the thickness of the plurality of insulating films 37.

Similar to the semiconductor device 1A, the semiconductor device 1E includes one or more (in this embodiment, one) gate wiring 46 that is selectively routed on the first main surface 3 in the outer region 31. The gate wiring 46 applies a gate potential to the plurality of gate structures 65.

The gate wiring 46 may include either or both of p-type conductive polysilicon and n-type conductive polysilicon. It is preferable for the gate wiring 46 to have the same conductivity type as the planar electrode 67. The gate wiring 46 has a thickness substantially equal to the thickness of the planar electrode 67. The thickness of the gate wiring 46 may be either greater than or less than the thickness of the planar electrode 67.

The gate wiring 46 is disposed on the main surface insulating film 45. The gate wiring 46 is selectively routed on the main surface insulating film 45 with a spacing from the periphery of the first main surface 3 toward the plurality of gate structures 65. The gate wiring 46 extends in a strip shape along the plurality of gate structures 65. The gate wiring 46 has a portion extending in a strip shape in the first direction X and a portion extending in a strip shape in the second direction Y.

In this embodiment, the gate wiring 46 is formed in an endless polygonal ring shape (for example, quadrilateral ring shape) having four sides parallel to the periphery of the first main surface 3 and surrounds the plurality of gate structures 65 (the active region 30). The gate wiring 46 may be formed in a strip shape including ends. The gate wiring 46 may have edge portions that connect a portion extending in a strip shape in the first direction X and a portion extending in a strip shape in the second direction Y in an arc shape (preferably a quarter-arc shape) in the plan view.

The gate wiring 46 has an inner edge on the inner side of the first main surface 3 and an outer edge on the periphery side of the first main surface 3. The inner edge of the gate wiring 46 is mechanically and electrically connected to the plurality of planar electrodes 67 (the gate structures 65) in the portion extending in the second direction Y. In this embodiment, the gate wiring 46 is integrally formed with the plurality of planar electrodes 67.

The gate wiring 46 has a width greater than the width of the planar electrode 67. The width of the gate wiring 46 may be substantially equal to the width of the planar electrode 67 or less than the width of the planar electrode 67. The ratio of the width of the gate wiring 46 to the width of the planar electrode 67 may be 1 or more and 50 or less. The width ratio may have a value that falls within at least one of the ranges of 1 or more and 10 or less, 10 or more and 20 or less, 20 or more and 30 or less, 30 or more and 40 or less, and 40 or more and 50 or less.

Similar to the semiconductor device 1A, the semiconductor device 1E includes an interlayer film 47 that selectively covers the first main surface 3 in the active region 30 and the outer region 31. The interlayer film 47 covers the plurality of gate structures 65 in the active region 30. Specifically, the interlayer film 47 covers the plurality of planar insulating films 66 and the plurality of planar electrodes 67 and electrically insulates the plurality of planar electrodes 67.

The semiconductor device 1E, similar to the semiconductor device 1A, includes a plurality of source openings 48 and a plurality of gate openings 49 formed in the interlayer film 47. The plurality of source openings 48 are formed in a one-to-one correspondence in a region between the plurality of planar electrodes 67 and each extend in a strip shape in the first direction X following the extending direction of the plurality of planar electrodes 67. The plurality of source openings 48 penetrate through the planar insulating film 66 and the interlayer film 47 and expose a plurality of source regions 40 and a plurality of contact regions 41, respectively.

The plurality of source openings 48 may be formed in a one-to-many correspondence in a region between the plurality of planar electrodes 67. In this case, the plurality of source openings 48 may be formed with a spacing following the extending direction of the plurality of planar electrodes 67. In this case, the plurality of source openings 48 may be formed in quadrilateral shape, rectangular shape (strip shaped), a circle shape, etc. in the plan view.

The semiconductor device 1E, similar to the semiconductor device 1A, includes a source electrode 50, a gate electrode 53, a gate finger electrode 54, and a drain electrode 55. In this embodiment, the source electrode 50 is disposed on the interlayer film 47 and extends from above the interlayer film 47 into the plurality of source openings 48. The source electrode 50 is electrically connected to a plurality of body regions 32, a plurality of source regions 40, and a plurality of contact regions 41 within the plurality of source openings 48.

In this embodiment, the gate electrode 53 is disposed on the interlayer film 47. The gate finger electrode 54 is disposed on the interlayer film 47 and extends from above the interlayer film 47 into the plurality of source openings 49. The gate finger electrode 54 is electrically connected to the gate wiring 46 within the plurality of gate openings 49. The drain electrode 55 is mechanically and electrically connected to the first layer 8 on the second main surface 4.

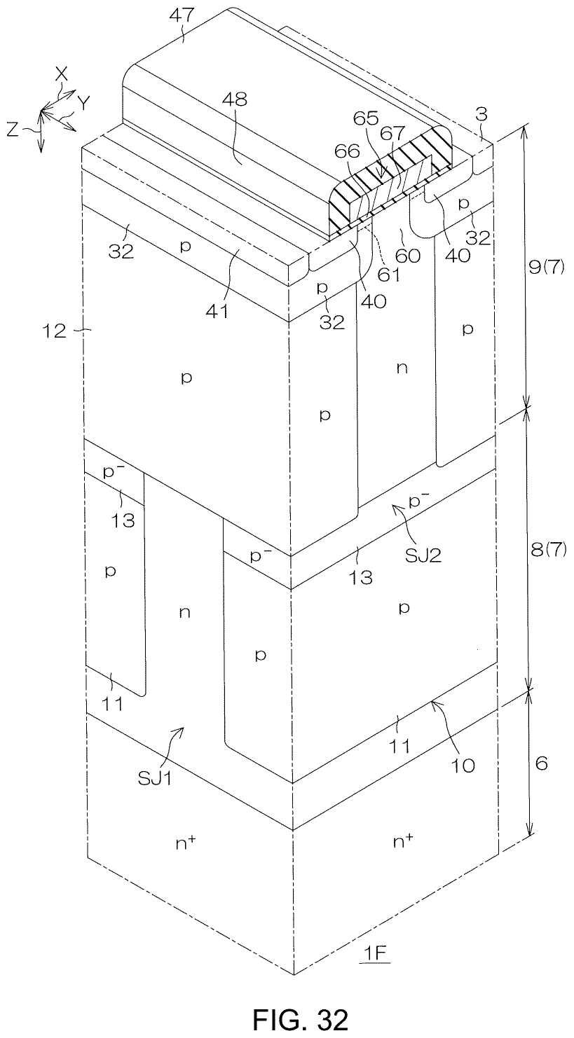

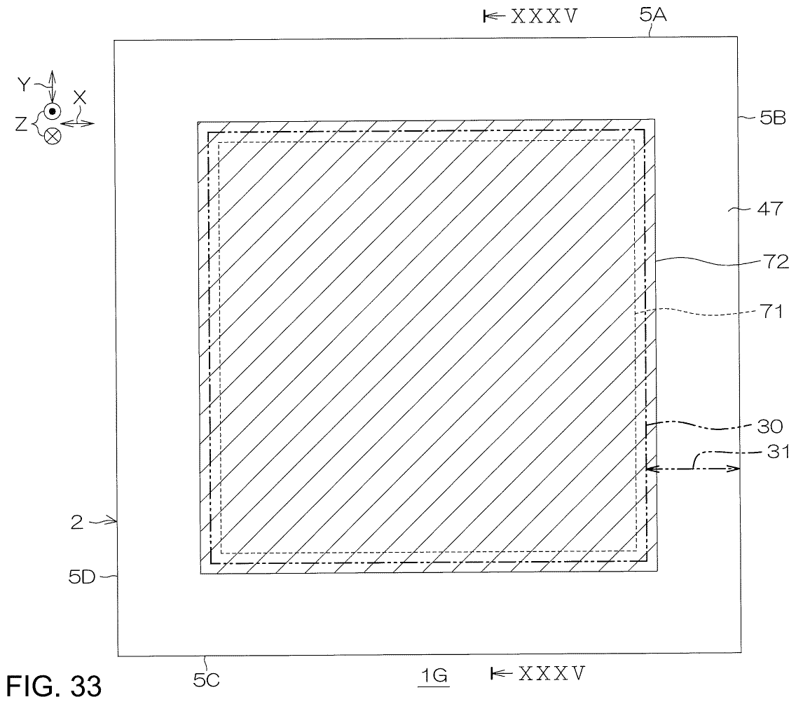

FIG. 32 is a cross-sectional perspective view showing the active region 30 of the semiconductor device 1F according to a sixth embodiment, along with the pillar region 10 according to the first example. The semiconductor device 1F has a modified embodiment of the semiconductor device 1E. Specifically, the plurality of body regions 32 are arranged with a spacing in the first direction X and extend in a strip shape in the second direction Y in the plan view. The plurality of body regions 32 are arranged in a stripe shape extending in the second direction Y in the plan view.

In this embodiment, the plurality of body regions 32 extend in the same direction as the extending direction of the plurality of second regions 12, and extend in a direction different from the extending direction of the plurality of first regions 11. The plurality of body regions 32 intersect (specifically, orthogonally) the plurality of first regions 11. This layout is effective in increasing the channel area of the active region 30.

The plurality of body regions 32 are arranged with a spacing substantially equal to the spacing of the plurality of second regions 12 and are connected in a one-to-one correspondence to the plurality of second regions 12 in the laminating direction. The p-type impurity concentration of the plurality of body regions 32 is increased by the plurality of second regions 12. The spacing of the plurality of body regions 32 may be substantially equal to the spacing of the plurality of first regions 11. The spacing of the plurality of body regions 32 may be either larger or smaller than the spacing of the plurality of first regions 11.

In this embodiment, the plurality of source regions 40 are formed with a spacing from both edge portions of the corresponding body regions 32 toward the inner portion of the corresponding body regions 32 with respect to the first direction X. The plurality of source regions 40 are formed with a spacing in the first direction X in the surface layer portion of the corresponding body regions 32 and extend in a strip shape in the second direction Y.

The plurality of source regions 40 may be formed with a spacing in the second direction Y following the extending direction of the corresponding body region 32. The plurality of source regions 40 are formed with a spacing inward from both end portions of the corresponding body region 32 with respect to the second direction Y. The plurality of source regions 40 are formed with a spacing from the bottom portion of the corresponding body region 32 toward the first main surface 3 side and face the second layer 9 with a portion of the corresponding body region 32 in between.

The plurality of contact regions 41 extend in a strip shape in the second direction Y along the extending direction of the corresponding body region 32 (the source region 40). The plurality of contact regions 41 are formed with a spacing inward from both end portions of the corresponding body region 32 with respect to the second direction Y. The plurality of contact regions 41 are formed with a spacing from the bottom portion of the corresponding body region 32 toward the first main surface 3 side and face the second layer 9 with a portion of the corresponding body region 32 in between.

A plurality of surface drift regions 60 are partitioned in regions between the plurality of body regions 32 and each extend in a strip shape along the second direction Y. The plurality of surface drift regions 60 are each formed in regions between the plurality of second regions 12 and extend in a strip shape in the second direction Y following the extending direction of the plurality of second regions 12.

A plurality of channel regions 61 are partitioned in regions between the plurality of source regions 40 and the plurality of surface drift regions 60 (the second layer 9) in the surface layer portion of the plurality of body regions 32 and extend in a strip shape in the second direction Y.

A plurality of gate structures 65 are arranged with a spacing in the first direction X in a plan view and extend in a strip shape in the second direction Y. The plurality of gate structures 65 are arranged in a stripe shape extending in the second direction Y in the plan view. This layout is effective in increasing the channel area of the active region 30.

In this embodiment, the plurality of gate structures 65 extend in the same direction as the extending direction of the plurality of second regions 12 and extend in a different direction from the extending direction of the plurality of first regions 11. The plurality of gate structures 65 intersect (specifically, orthogonally) the plurality of first regions 11. The plurality of gate structures 65 are arranged with a spacing substantially equal to the spacing of the plurality of second regions 12, and face regions between the plurality of second regions 12 (surface drift regions 60) in a one-to-one correspondence in the laminating direction.

The spacing of the plurality of gate structures 65 may be substantially equal to the spacing of the plurality of first regions 11. The spacing of the plurality of gate structures 65 may be either greater or smaller than the spacing of the plurality of first regions 11. Similar to the case of the semiconductor device 1E, the plurality of gate structures 65 are each disposed on at least one channel region 61 (the peripheral portion of the body region 32).

Additionally, the specific configuration of the semiconductor device 1E can be obtained by replacing the “first direction X” with the “second direction Y” in the configuration of the semiconductor device 1D and simultaneously replacing the “second direction Y” with the “first direction X”.

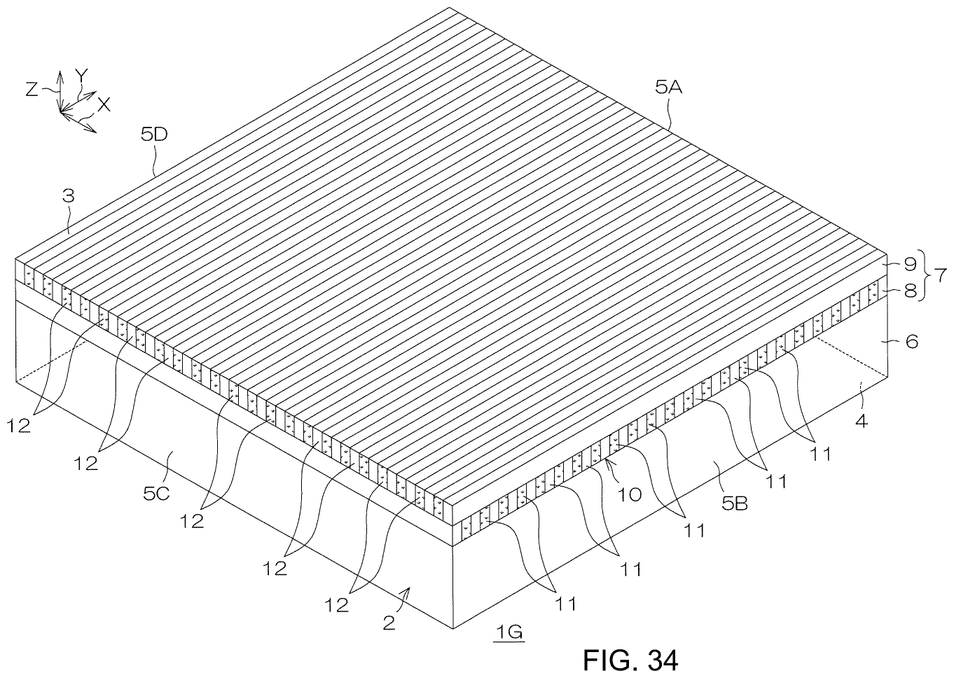

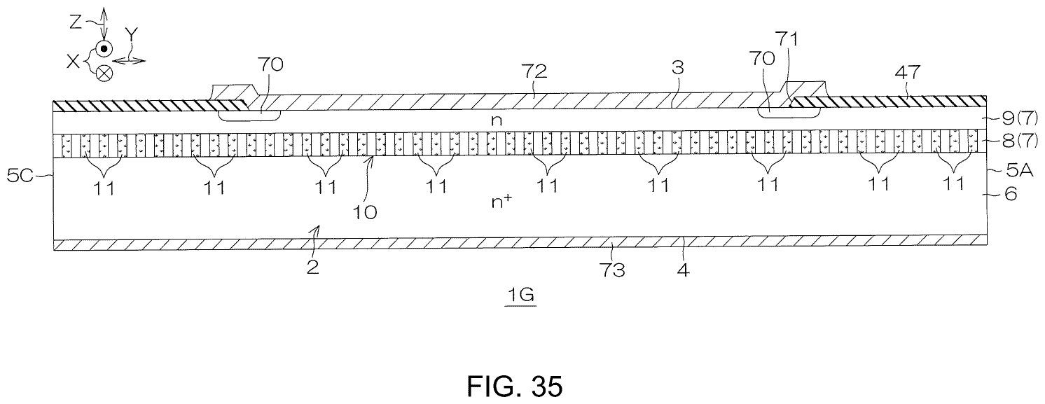

FIG. 33 is a plan view showing a semiconductor device 1G according to a seventh form. FIG. 34 is a perspective view of the chip 2 shown in FIG. 33. FIG. 35 is a cross-sectional view along a line XXXV-XXXV shown in FIG. 33. Referring to FIGS. 33 to 35, the semiconductor device 1G is a semiconductor rectifying device having a diode structure as an example of a device structure (functional device). The diode structure has a vertical structure.

The semiconductor device 1G has the chip 2 and the pillar region 10 according to the semiconductor device 1A as its basic form. In this embodiment, the semiconductor device 1G has the pillar region 10 according to the first embodiment example (refer to FIG. 3 and FIGS. 5A to 5C).

The semiconductor device 1G may have any one of the pillar regions 10 according to the second to fifth embodiment examples (refer to FIGS. 6 to 10). Additionally, the semiconductor device 1G may have the pillar region 10 according to the first modification example (refer to FIG. 11) or the pillar region 10 according to the second modification example (refer to FIG. 12).

The semiconductor device 1G includes the above-mentioned active region 30 and outer region 31. In this embodiment, the active region 30 includes the device structure (diode structure) and is a region where output current (forward current) is generated. In this embodiment, the outer region 31 is a region that does not include the device structure (diode structure).

The semiconductor device 1G includes a p-type guard region 70 formed within the surface layer portion of the first main surface 3 in the outer region 31. The guard region 70 may have a p-type impurity concentration that is higher than the n-type impurity concentration of the second layer 9. The p-type impurity concentration of the guard region 70 may be either higher or lower than the p-type impurity concentration of the second region 12 (the first region 11).

The guard region 70 is formed in the outer region 31 with a spacing from the periphery of the first main surface 3. The guard region 70 extends in a strip shape along the active region 30. The guard region 70 has a portion extending in a strip shape in the first direction X and a portion extending in a strip shape in the second direction Y.

In this embodiment, the guard region 70 is formed in an endless polygonal ring shape (for example, quadrilateral ring shape) having four sides parallel to the periphery of the first main surface 3 and surrounds the inner portion of the first main surface 3. The guard region 70 has a portion connected to the plurality of second regions 12. The inner edge of the guard region 70 partitions the boundary portion between the active region 30 and the outer region 31.

The guard region 70 is formed with a spacing from the lower end of the second layer 9 (the first layer 8) toward the first main surface 3 side and faces the first layer 8 with a portion of the second layer 9 in between. The guard region 70 is formed with a spacing from the lower end of the second region 12 toward the first main surface 3 side. The guard region 70 may be formed with a spacing from the depth position of the middle portion of the second layer 9 toward the first main surface 3 side. The guard region 70 may have a portion positioned on the first layer 8 side relative to the depth position of the middle portion of the second layer 9.

The guard region 70 may be formed using the second region 12. That is, the guard region 70 may have a depth substantially equal to the depth of the second region 12 and a p-type impurity concentration substantially equal to the p-type impurity concentration of the second region 12.

The semiconductor device 1G includes the above-mentioned interlayer film 47 that selectively covers the first main surface 3. The interlayer film 47 selectively covers the first main surface 3 in the outer region 31. The interlayer film 47 covers the outer edge of the guard region 70 in the outer region 31 and exposes the inner edge of the guard region 70. In this embodiment, the interlayer film 47 is continuous with the periphery of the first main surface 3. The interlayer film 47 may be formed with a spacing from the periphery of the first main surface 3 and may expose the second layer 9 from the periphery of the first main surface 3.

The interlayer film 47 has a contact opening 71 that exposes the first main surface 3 in the active region 30. The contact opening 71 exposes the second layer 9 and the plurality of second regions 12. In this embodiment, the contact opening 71 has an opening wall positioned on the guard region 70 and exposes the inner edge of the guard region 70.

The semiconductor device 1G includes an anode electrode 72 disposed on the first main surface 3. The anode electrode 72 may be referred to as a “first main surface 3 electrode,” “first terminal (electrode),” “first pad (electrode),” etc. The anode electrode 72 is disposed with a spacing from the periphery of the first main surface 3. The anode electrode 72 is formed in a polygonal shape (In this embodiment, a quadrilateral shape) along the periphery of the first main surface 3 in the plan view.

The anode electrode 72 extends from above the interlayer film 47 into the contact opening 71 and is mechanically and electrically connected to the first main surface 3 within the contact opening 71. Specifically, the anode electrode 72 is mechanically and electrically connected to the second layer 9, the plurality of second regions 12, and the guard region 70. The anode electrode 72 forms a Schottky junction with the second layer 9 in a region between the plurality of second regions 12.

As a result, a diode structure that includes the anode electrode 72 as the anode region and the second layer 9 as the cathode region is formed. In this embodiment, the diode structure is a Schottky barrier diode structure. The plurality of second regions 12 may form a JPS structure (Junction Barrier Schottky structure) with the second layer 9.

When the plurality of second regions 12 are formed with a spacing in the thickness direction from the first main surface 3, the anode electrode 72 may be mechanically and electrically connected to the second layer 9 and the guard region 70 within the contact opening 71.

The semiconductor device 1G includes the above-mentioned cathode electrode 73, which is disposed on the second main surface 4. In this embodiment, the cathode electrode 73 is formed as the cathode electrode 73. The cathode electrode 73 may be referred to as a “second main surface 4 electrode,” “second terminal (electrode),” “second pad (electrode),” etc. The cathode electrode 73 may cover the entire area of the second main surface 4 so as to be continuous with the periphery of the second main surface 4 (the first to fourth side surfaces 5A to 5D).

The cathode electrode 73 may cover the inner portion of the second main surface 4 with a spacing from the periphery of the second main surface 4 and may expose the peripheral portion of the second main surface 4. The cathode electrode 73 is mechanically and electrically connected to the base layer 6. The cathode electrode 73 forms an ohmic contact with the base layer 6. The cathode electrode 73 forms a current path via the chip 2 along with the anode electrode 72.

The breakdown voltage that can be applied between the anode electrode 72 and the cathode electrode 73 (between the first main surface 3 and the second main surface 4) may be 500 V or more and 3000 V or less. The breakdown voltage may have a value that falls within at least one of the ranges of 500 V or more and 750 V or less, 750 V or more and 1000 V or less, 1000 V or more and 1250 V or less, 1250 V or more and 1500 V or less, 1500 V or more and 1750 V or less, 1750 V or more and 2000 V or less, 2000 V or more and 2250 V or less, 2250 V or more and 2500 V or less, and 2500 V or more and 3000 V or less.

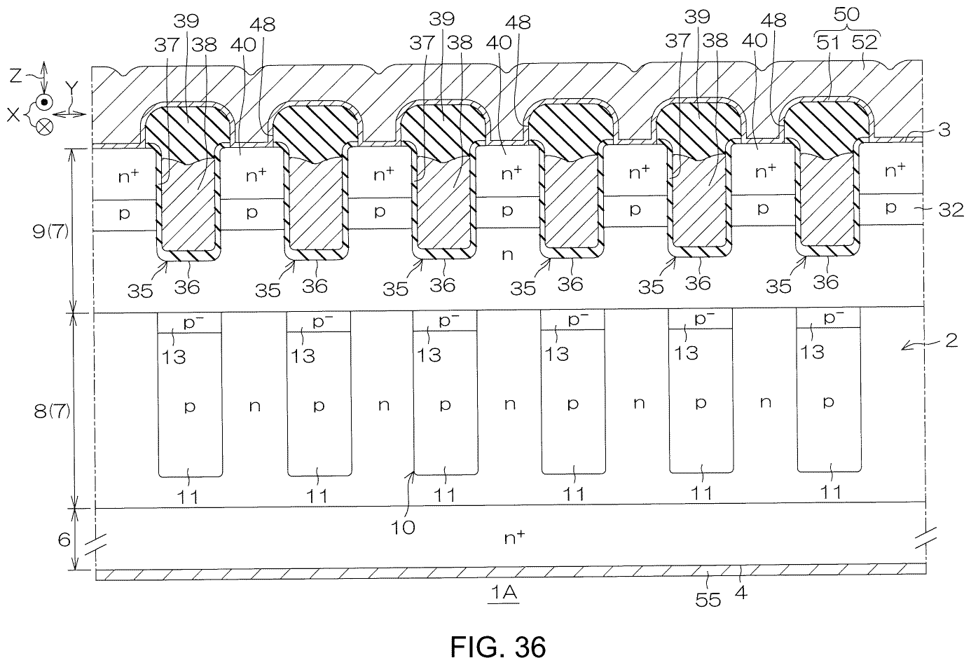

Modification examples applied to the second to sixth embodiments are described below. FIG. 36 is a cross-sectional view showing a modification example applied to any one of the semiconductor devices 1A to 1F according to the second to sixth embodiments. Referring to FIG. 36, the semiconductor devices 1A to 1F may include buried insulators 39 that protrude above the height position of the first main surface 3. The plurality of buried insulators 39 expose a plurality of source regions 40 and a plurality of contact regions 41 on the first main surface 3.

In this embodiment, a plurality of source openings 48 are each partitioned in regions between the plurality of buried insulators 39 on the first main surface 3. The source electrode 50 (the base electrode 51 and the main electrode 52) extends into the plurality of source openings 48 from above the interlayer film 47 and is electrically connected to the plurality of source regions 40 and the plurality of contact regions 41 within the plurality of source openings 48.

Each of the above-mentioned forms (including modification examples) can be implemented in further other forms. For example, the above-mentioned first region 11 may extend in a direction that intersects both the a-axis direction and the m-axis direction of the SiC single crystal. In this case, the second region 12 may be orthogonal to the first region 11. The second region 12 may extend in either the a-axis direction or the m-axis direction of the SiC single crystal. The first region 11 may extend in either the a-axis direction or the m-axis direction, and the second region 12 may extend in a direction that intersects both the a-axis direction and the m-axis direction of the SiC single crystal.

The features of the semiconductor devices 1A to 1G according to the above-mentioned first to seventh forms can be appropriately combined. Therefore, the semiconductor devices 1A to 1G may include any two features, three features, four features, five features, six features, seven features, eight features, or nine features from the features of the semiconductor devices 1A to 1G.

In the above-mentioned forms, examples where trench-type transistor structures, planar-type transistor structures, and diode structures are formed in separate chips 2 (the first main surfaces 3) are shown. However, the trench-type transistor structure, the planar-type transistor structure, and the diode structure may be fabricated in a common chip 2 (the first main surface 3).

Structures including both the trench-type transistor structures and the planar-type transistor structures may be adopted. Structures including both the trench-type transistor structures and the diode structures may be adopted. Structures including both the planar-type transistor structures and the diode structures may be adopted. Structures including all of the trench-type transistor structures, the planar-type transistor structures, and the diode structures may be adopted.

In each of the above-mentioned forms, structures where the conductivity type of an n-type semiconductor region is inverted to p-type and the conductivity type of a p-type semiconductor region is inverted to n-type may be adopted. The specific configuration in this case can be obtained by replacing n-type with p-type and simultaneously replacing p-type with n-type in the above-mentioned description and accompanying figures.

In the above-mentioned forms, an n-type base layer 6 is shown. However, the conductivity type of the base layer 6 may be p-type. In this case, an IGBT (Insulated Gate Bipolar Transistor) structure is formed instead of the MISFET structure. In this case, in the previous description, the “source” of the MISFET structure is replaced with an “emitter” of the IGBT structure, and the “drain” of the MISFET structure is replaced with a “collector” of the IGBT structure.

Hereinafter, characteristic examples extracted from this specification and figures are presented. Hereinafter, the alphanumeric characters in parentheses represent corresponding components of the above-mentioned forms, but are not intended to limit the scope of each item (Clause) to the above-mentioned forms. The “semiconductor device” related to the following items may be replaced with a “SiC semiconductor device,” “wide bandgap semiconductor device,” “semiconductor switching device,” “semiconductor rectifier device,” etc., as necessary.

[A1] A semiconductor device (1A-1G), including: a semiconductor layer (7-9) of a first conductivity type (n-type/p-type) having a main surface (3); a first region (11) of a second conductivity type (p-type/n-type) extending in a first direction (X/Y) along the main surface (3) within the semiconductor layer (7-9); a second region (12) of the second conductivity type (p-type/n-type) formed in a region on the main surface (3) side relative to the first region (11) within the semiconductor layer (7-9) and extending in a second direction (Y/X) along the main surface (3) so as to intersect the first region (11) three-dimensionally; and a low-concentration region (13) of the second conductivity type (p-type/n-type) formed at least at an intersection portion of the first region (11) and the second region (12) within the semiconductor layer (7-9) and having a concentration lower than both a maximum concentration of the first region (11) and a maximum concentration of the second region (12).

[A2] The semiconductor device (1A-1G) of A1, wherein the semiconductor layer (7-9) includes SiC.

[A3] The semiconductor device (1A-1G) of A2, wherein the SiC is hexagonal.

[A4] The semiconductor device (1A-1G) of A3, wherein the first direction (X/Y) is one of an a-axis direction and an m-axis direction of the SiC, and the second direction (Y/X) is the other of the a-axis direction and the m-axis direction of the SiC.

[A5] The semiconductor device (1A-1G) of any one of A1-A4, wherein the semiconductor layer (7-9) has an off-angle.

[A6] The semiconductor device (1A-1G) of any one of A1-A5, wherein the second direction (Y/X) is orthogonal to the first direction (X/Y).

[A7] The semiconductor device (1A-1G) of any one of A1-A6, wherein a concentration of the low-concentration region (13) is lower than both a concentration of a middle portion of the first region (11) and a concentration of a middle portion of the second region (12).

[A8] The semiconductor device (1A-1G) of any one of A1-A7, wherein the low-concentration region (13) forms a first concentration transition portion (14) where a concentration gradually decreases from the first region (11) and a second concentration transition portion (15) where a concentration gradually increases toward the second region (12) at the intersection portion.

[A9] The semiconductor device (1A-1G) of any one of A1-A8, wherein the low-concentration region (13) is also formed in a region other than the intersection portion.

[A10] The semiconductor device (1A-1G) of any one of A1-A9, wherein the low-concentration region (13) has a portion extending in the first direction (X/Y) following the first region (11).

[A11] The semiconductor device (1A-1G) of any one of A1-A10, wherein the low-concentration region (13) has a portion extending in the second direction (Y/X) following the second region (12).

[A12] The semiconductor device (1A-1G) of any one of A1-A11, wherein the first region (11) extends longitudinally in a thickness direction of the semiconductor layer (7-9), and the second region (12) extends longitudinally in the thickness direction of the semiconductor layer (7-9).

[A13] The semiconductor device (1A-1G) of any one of A1 to A12, wherein the first region (11) has a width of 10 μm or less, and the second region (12) has a width of 10 μm or less.

[A14] The semiconductor device (1A-1G) of any one of A1 to A13, wherein a plurality of the first regions (11) are formed in a stripe shape extending in the first direction (X/Y), a plurality of the second regions (12) are formed in a stripe shape extending in the second direction (Y/X) so as to intersect the plurality of the first regions (11), and a plurality of the low-concentration regions (13) are formed at a plurality of the intersection portions.

[A15] The semiconductor device (1A-1G) of A14, wherein the plurality of the first regions (11) form a first super junction structure (SJ1) with the semiconductor layer (7-9), and the plurality of the second regions (12) form a second super junction structure (SJ2) with the semiconductor layer (7-9).

[A16] The semiconductor device (1A-1G) of any one of A1-A15, further including a field-effect transistor structure formed on the main surface (3).

[A17] The semiconductor device (1A-1G) of A16, wherein the transistor structure includes a trench-type gate structure (35) formed on the main surface (3).

[A18] The semiconductor device (1A-1G) of A16, wherein the transistor structure includes a planar-type gate structure (65) formed on the main surface (3).

[A19] The semiconductor device (1A-1G) of any one of A1-A18, further including a diode structure formed on the main surface (3).

[A20] The semiconductor device (1A-1G) of any one of A1-A19, further including an electrode (50, 53, 54, 72) covering the main surface (3).

Although specific forms are described in detail above, these are merely examples that clearly show the technical content. Various technical ideas extracted from this specification can be appropriately combined without being limited by the order of description, the order of the form examples, the order of the modification examples in the specification, etc.

1. A semiconductor device, including:
a semiconductor layer of a first conductivity type having a main surface;
a first region of a second conductivity type extending in a first direction along the main surface within the semiconductor layer;
a second region of the second conductivity type formed in a region on the main surface side relative to the first region within the semiconductor layer and extending in a second direction along the main surface so as to intersect the first region three-dimensionally; and
a low-concentration region of the second conductivity type formed at least at an intersection portion of the first region and the second region within the semiconductor layer and having a concentration lower than both a maximum concentration of the first region and a maximum concentration of the second region.

2. The semiconductor device of claim 1, wherein the semiconductor layer includes SiC.

3. The semiconductor device of claim 2, wherein the SiC is hexagonal.

4. The semiconductor device of claim 3, wherein the first direction is one of an a-axis direction and an m-axis direction of the SiC, and
the second direction is the other of the a-axis direction and the m-axis direction of the SiC.

5. The semiconductor device of claim 1, wherein the semiconductor layer has an off-angle.

6. The semiconductor device of claim 1, wherein the second direction is orthogonal to the first direction.

7. The semiconductor device of claim 1, wherein a concentration of the low-concentration region is lower than both a concentration of a middle portion of the first region and a concentration of a middle portion of the second region.

8. The semiconductor device of claim 1, wherein the low-concentration region forms a first concentration transition portion where a concentration gradually decreases from the first region, and a second concentration transition portion where a concentration gradually increases toward the second region at the intersection portion.

9. The semiconductor device of claim 1, wherein the low-concentration region is also formed in a region other than the intersection portion.

10. The semiconductor device of claim 1, wherein the low-concentration region has a portion extending in the first direction following the first region.

11. The semiconductor device of claim 1, wherein the low-concentration region has a portion extending in the second direction following the second region.

12. The semiconductor device of claim 1, wherein the first region extends longitudinally in a thickness direction of the semiconductor layer, and
the second region extends longitudinally in the thickness direction of the semiconductor layer.

13. The semiconductor device of claim 1, wherein the first region has a width of 10 μm or less, and
the second region has a width of 10 μm or less.

14. The semiconductor device of claim 1, wherein a plurality of the first regions are formed in a stripe shape extending in the first direction,
a plurality of the second regions are formed in a stripe shape extending in the second direction so as to intersect the plurality of the first regions, and
a plurality of the low-concentration regions are formed at a plurality of the intersection portions.

15. The semiconductor device of claim 14, wherein the plurality of the first regions form a first super junction structure with the semiconductor layer, and
the plurality of the second regions form a second super junction structure with the semiconductor layer.

16. The semiconductor device of claim 1, further including a field-effect transistor structure formed on the main surface.

17. The semiconductor device of claim 16, wherein the transistor structure includes a trench-type gate structure formed on the main surface.

18. The semiconductor device of claim 16, wherein the transistor structure includes a planar-type gate structure formed on the main surface.

19. The semiconductor device of claim 1, further including a diode structure formed on the main surface.

20. The semiconductor device of claim 1, further including an electrode covering the main surface.
